(19) United States
(12) Patent Application Publication
(10) Pub. No.: US 2022/0013667 A1
(43) Pub. Date: Jan. 13, 2022

(54) SEMICONDUCTOR DEVICE

(71) Applicant: Semiconductor Energy Laboratory Co., Ltd., Atsugi-shi, Kanagawa-ken (JP)

(72) Inventors: Masataka NAKADA, Tochigi (JP); Takahiro IGUCHI, Nikko (JP); Yasuharu HOSAKA, Tochigi (JP); Takumi SHIGENOBU, Tochigi (JP)

(21) Appl. No.: 17/288,675

(22) PCT Filed: Oct. 21, 2019
(86) PCT No.: PCT/IB2019/058935

§ 371 Date: Apr. 26, 2021

(30) Foreign Application Priority Data
Nov. 2, 2018 (JP) 2018-207226

(51) Int. Cl. H01L 29/786; H01L 27/12; H01L 21/02; H01L 29/66

(52) U.S. Cl. CPC H01L 29/7869; H01L 27/1225; H01L 29/78618; H01L 27/3262; H01L 27/127; H01L 21/02565; H01L 29/66969; H01L 29/78696

(57) ABSTRACT

A semiconductor device with favorable electrical characteristics is provided. A highly reliable semiconductor device is provided. A semiconductor device with stable electrical characteristics is provided. The semiconductor device includes a semiconductor layer, a first insulating layer, a metal oxide layer, a conductive layer, and an insulating region. The first insulating layer covers a top surface and a side surface of the semiconductor layer, and the conductive layer is positioned over the first insulating layer. The metal oxide layer is positioned between the first insulating layer and the conductive layer, and an end portion of the metal oxide layer is positioned on an inner side than an end portion of the conductive layer. The insulating region is positioned adjacent to the metal oxide layer and positioned between the first insulating layer and the conductive layer. Furthermore, the semiconductor layer includes a first region, a pair of second regions, and a pair of third regions. The first region overlaps with the metal oxide layer and the conductive layer. The second regions are positioned to put the first region sandwiched therebetween and to overlap with the insulating region and the conductive layer. The third regions are positioned to the first region and the pair of second regions sandwiched therebetween and not to overlap with the conductive layer. The third regions preferably include a portion having lower resistance than the first region. The second regions preferably include a portion having higher resistance than the third regions.

### TECHNICAL FIELD

One embodiment of the present invention relates to a semiconductor device and a manufacturing method thereof. One embodiment of the present invention relates to a display device.

Note that one embodiment of the present invention is not limited to the above technical field. Examples of the technical field of one embodiment of the present invention disclosed in this specification and the like include a semiconductor device, a display device, a light-emitting device, a power storage device, a memory device, an electronic device, a lighting device, an input device, an input/output device, a driving method thereof, and a manufacturing method thereof. A semiconductor device generally means a device that can function by utilizing semiconductor characteristics.

### BACKGROUND ART

As a semiconductor material applicable to a transistor, an oxide semiconductor using a metal oxide has attracted attention. For example, Patent Document 1 discloses a semiconductor device that makes field-effect mobility (simply referred to as mobility or μFE in some cases) to be increased by stacking a plurality of oxide semiconductor layers in each of which the oxide semiconductor layer serving as a channel contains indium and gallium so that the proportion of indium is made higher than the proportion of gallium.

A metal oxide that can be used for a semiconductor layer can be formed by a sputtering method or the like, and thus can be used for a semiconductor layer of a transistor included in a large display device. In addition, capital investment can be reduced because part of production equipment for transistors using polycrystalline silicon or amorphous silicon can be retrofitted and utilized. Furthermore, a transistor using a metal oxide has high field-effect mobility compared to the case of using amorphous silicon; therefore, a high-performance display device provided with a driver circuit can be achieved.

### REFERENCE

### Patent Document

### [Patent Document 1] Japanese Published Patent Application No. 2014-7399

### SUMMARY OF THE INVENTION

### Problems to be Solved by the Invention

An object of one embodiment of the present invention is to provide a semiconductor device with favorable electrical characteristics. An object of one embodiment of the present invention is to provide a highly reliable semiconductor device. An object of one embodiment of the present invention is to provide a semiconductor device which has stable electrical characteristics. An object of one embodiment of the present invention is to provide a novel semiconductor device. An object of one embodiment of the present invention is to provide a highly reliable display device. An object of one embodiment of the present invention is to provide a novel display device.

Note that the description of these objects does not preclude the existence of other objects. One embodiment of the present invention does not have to achieve all these objects. Note that objects other than these can be derived from the description of the specification, the drawings, the claims, and the like.

### Means for Solving the Problems

One embodiment of the present invention is a semiconductor device including a semiconductor layer, a first insulating layer, a metal oxide layer, a conductive layer, and an insulating region. The first insulating layer covers a top surface and a side surface of the semiconductor layer, and the conductive layer is positioned over the first insulating layer. The metal oxide layer is positioned between the first insulating layer and the conductive layer, and an end portion of the metal oxide layer is positioned on an inner side than an end portion of the conductive layer. The insulating region is adjacent to the metal oxide layer and is positioned between the first insulating layer and the conductive layer. In addition, the semiconductor layer includes a first region, a pair of second regions, and a pair of third regions. The first region overlaps with the metal oxide layer and the conductive layer. The second regions are positioned to put the first region sandwiched therebetween and to overlap with the insulating region and the conductive layer. The third regions are positioned to put the first region and the pair of second regions sandwiched therebetween and not to overlap with the conductive layer. The third regions preferably include a portion having lower resistance than the first region. The second regions preferably include a portion having higher resistance than the third regions.

In the above semiconductor device, the insulating region preferably has a relative dielectric constant different from a relative dielectric constant of the first insulating layer.

In the above semiconductor device, the insulating region preferably has a gap.

It is preferable that the above semiconductor device further include a second insulating layer, that the second insulating layer be in contact with a top surface of the first insulating layer, and that the insulating region include the second insulating layer.

In the above semiconductor device, the first insulating layer preferably contains an oxide or a nitride, and the second insulating layer preferably contains an oxide or a nitride.

In the above semiconductor device, the first insulating layer preferably contains silicon and oxygen, and the second insulating layer preferably contains silicon and oxygen.

In the above semiconductor device, the first insulating layer preferably contains silicon and oxygen, and the second insulating layer preferably contains silicon and nitrogen.

It is preferable that the above semiconductor device further include a third insulating layer, that the third insulating layer be in contact with a top surface of the second insulating layer, and that the third insulating layer contain a nitride.

In the above semiconductor device, the third insulating layer preferably contains silicon and nitrogen.

In the above semiconductor device, the third region preferably contains a first element, and the first element is preferably one or more elements selected from boron, phosphorus, aluminum, and magnesium.

In the above semiconductor device, each of the semiconductor layer and the metal oxide layer preferably contains indium, and the semiconductor layer preferably has an indium content percentage that is substantially equal to an indium content percentage of the metal oxide layer.

### Effect of the Invention

According to one embodiment of the present invention, a semiconductor device with favorable electrical characteristics can be provided. Alternatively, a highly reliable semiconductor device can be provided. Alternatively, a semiconductor device with stable electrical characteristics can be provided. Alternatively, a novel semiconductor device can be provided. Alternatively, a highly reliable display device can be provided. Alternatively, a novel display device can be provided.

Note that the description of the effects does not preclude the existence of other effects. Note that one embodiment of the present invention does not need to have all these effects. Note that effects other than these can be derived from the description of the specification, the drawings, the claims, and the like.

### BRIEF DESCRIPTION OF THE DRAWINGS

FIG. 1A is a top view illustrating a structure example of a transistor. FIG. 1B and FIG. 1C are cross-sectional views each illustrating the structure example of the transistor.

FIG. 2A and FIG. 2B are cross-sectional views each illustrating a structure example of a transistor.

FIG. 3A and FIG. 3B are cross-sectional views each illustrating a structure example of a transistor.

FIG. 4A and FIG. 4B are cross-sectional views each illustrating a structure example of a transistor.

FIG. 5A is a top view illustrating a structure example of a transistor. FIG. 5B and FIG. 5C are cross-sectional views each illustrating the structure example of the transistor.

FIG. 6A and FIG. 6B are cross-sectional views each illustrating a structure example of a transistor.

FIG. 7A and FIG. 7B are cross-sectional views each illustrating a structure example of a transistor.

FIG. 8A FIG. 8B, FIG. 8C, FIG. 8D, and FIG. 8E are cross-sectional views illustrating a method for manufacturing a transistor.

FIG. 9A, FIG. 9B, and FIG. 9C are cross-sectional views illustrating a method for manufacturing a transistor.

FIG. 10A, FIG. 10B, and FIG. 10C are cross-sectional views illustrating a method for manufacturing a transistor.

FIG. 11A, FIG. 11B, and FIG. 11C are cross-sectional views illustrating a method for manufacturing a transistor.

FIG. 12A, FIG. 12B, and FIG. 12C are top views of display devices.

FIG. 13 is a cross-sectional view of a display device.

FIG. 14 is a cross-sectional view of a display device.

FIG. 15 is a cross-sectional view of a display device.

FIG. 16 is a cross-sectional view of a display device.

FIG. 17A is a block diagram of a display device. FIG. 17B and FIG. 17C are circuit diagrams of the display device.

FIG. 18A, FIG. 18C, and FIG. 18D are circuit diagrams of a display device. FIG. 18B is a timing chart of the display device.

FIG. 19A and FIG. 19B illustrate a structure example of a display module.

FIG. 20A and FIG. 20B illustrate a structure example of an electronic device.

FIG. 21A, FIG. 21B, FIG. 21C, FIG. 21D, and FIG. 21E illustrate structure examples of electronic devices.

FIG. 22A, FIG. 22B, FIG. 22C, FIG. 22D, FIG. 22E, FIG. 22F, and FIG. 22G illustrate structural examples of electronic devices.

FIG. 23A, FIG. 23B, FIG. 23C, and FIG. 23D illustrate structure examples of electronic devices.

FIG. 24 shows cross-sectional STEM images.

FIG. 25 shows I_{d}-V_{g} characteristics and a cross-sectional STEM image of a transistor.

FIG. 26 shows I_{d}-V_{g} characteristics and a cross-sectional STEM image of a transistor.

FIG. 27 shows I_{d}-V_{g} characteristics and a cross-sectional STEM image of a transistor.

FIG. 28 shows results of reliability tests of transistors.

FIG. 29 illustrates a cross-sectional structure of a sample.

FIG. 30 shows sheet resistance of a sample.

FIG. 31 shows cross-sectional STEM images.

### MODE FOR CARRYING OUT THE INVENTION

Hereinafter, embodiments are described with reference to the drawings. Note that the embodiments can be implemented with many different modes, and it will be readily understood by those skilled in the art that modes and details thereof can be changed in various ways without departing from the spirit and scope thereof. Thus, the present invention should not be construed as being limited to the following description of the embodiments.

In each drawing described in this specification, the size, the layer thickness, or the region of each component is exaggerated for clarity in some cases.

Ordinal numbers such as “first,” “second,” and “third” used in this specification and the like are used in order to avoid confusion among components, and the terms do not limit the components numerically.

In this specification and the like, terms for describing arrangement, such as “over” and “under”, are used for convenience to describe the positional relationship between components with reference to drawings. The positional relation between components is changed as appropriate in accordance with a direction in which each component is described. Thus, terms for the description are not limited to terms used in the specification, and description can be made appropriately depending on the situation.

Furthermore, in this specification and the like, functions of a source and a drain of a transistor are sometimes switched from each other depending on the polarity of the transistor, the case where the direction of current flow is changed in circuit operation, or the like. Therefore, the terms “source” and “drain” can be used interchangeably.

Note that in this specification and the like, a channel length direction of a transistor refers to one of the directions parallel to a straight line that connects a source region and a drain region in the shortest distance. In other words, a channel length direction corresponds to one of the directions of current flowing through a semiconductor layer when a transistor is in an on state. In addition, a channel width direction refers to a direction orthogonal to the channel length direction. Note that each of the channel length direction and the channel width direction is not fixed to one direction in some cases depending on the structure and the shape of a transistor.

In this specification and the like, “electrically connected” includes the case where connection is made through an “object having any electric function”. There is no particular limitation on the “object having any electric function” as long as electric signals can be transmitted and received between components that are connected through the object. Examples of the “object having any electric action” include a switching element such as a transistor, a resistor, an inductor, a capacitor, and other elements with a variety of functions as well as an electrode and a wiring.

In this specification and the like, the term “film” and the term “layer” can be interchanged with each other. For example, in some cases, the term “conductive layer” and the term “insulating layer” can be interchanged with the term “conductive film” and the term “insulating film,” respectively.

Note that in this specification and the like, the expression “having substantially the same top surface shapes” means that at least outlines of stacked layers partly overlap with each other. For example, the case of processing an upper layer and a lower layer with the use of the same mask pattern or mask patterns that are partly the same is included. However, in some cases, the outlines do not completely overlap with each other and the upper layer is positioned on an inner side of the lower layer or the upper layer is positioned on an outer side of the lower layer; such a case is also represented by the expression “the top-view shapes are substantially the same.”

Unless otherwise specified, off-state current in this specification and the like refers to drain current of a transistor in an off state (also referred to as a non-conducting state or a cutoff state). Unless otherwise specified, an off state refers to, in an n-channel transistor, a state where voltage V_{gs} between its gate and source is lower than the threshold voltage Vₜₕ (in a p-channel transistor, higher than Vₜₕ).

In this specification and the like, a display panel that is one embodiment of a display device has a function of displaying (outputting) an image or the like on (to) a display surface. Thus, the display panel is one embodiment of an output device.

In this specification and the like, a substrate of a display panel to which a connector such as an FPC (Flexible Printed Circuit) or a TCP (Tape Carrier Package) is attached, or a substrate on which an IC is mounted by a COG (Chip On Glass) method or the like is referred to as a display panel module, a display module, or simply a display panel or the like in some cases.

Note that in this specification and the like, a touch panel that is one embodiment of a display device has a function of displaying an image or the like on a display surface and a function of a touch sensor capable of sensing the contact, press, approach, or the like of a sensing target such as a finger or a stylus with or to the display surface. Therefore, the touch panel is one embodiment of an input/output device.

A touch panel can also be referred to as, for example, a display panel (or a display device) with a touch sensor or a display panel (or a display device) having a touch sensor function. A touch panel can include a display panel and a touch sensor panel. Alternatively, a touch panel can have a function of a touch sensor inside a display panel or on a surface thereof.

In this specification and the like, a substrate of a touch panel to which a connector or an IC is attached is referred to as a touch panel module, a display module, or simply a touch panel or the like in some cases.

### Embodiment 1

In this embodiment, a semiconductor device of one embodiment of the present invention and a manufacturing method thereof will be described. In particular, in this embodiment, as an example of the semiconductor device, a transistor using an oxide semiconductor for a semiconductor layer in which a channel is formed will be described.

An embodiment of the present invention is a transistor including, over a formation surface, a semiconductor layer in which a channel is formed, an insulating layer over the semiconductor layer, and a metal oxide layer and a conductive layer over the insulating layer. The transistor of one embodiment of the present invention preferably includes an insulating region adjacent to the metal oxide layer. The insulating region is positioned between a gate insulating layer and the conductive layer. The semiconductor layer preferably contains a metal oxide exhibiting semiconductor characteristics (hereinafter, also referred to as an oxide semiconductor).

An end portion of the metal oxide layer is preferably provided on an inner side than an end portion of the conductive layer. In other words, the conductive layer preferably has a portion protruding beyond the end portion of the metal oxide layer. Parts of the metal oxide layer and the conductive layer function as a gate electrode.

The insulating region preferably has a relative dielectric constant different from that of the insulating layer. For example, the insulating region may include a gap. Furthermore, the insulating layer is preferably provided to cover a top surface and a side surface of the semiconductor layer. Parts of the insulating layer and the insulating region function as a gate insulating layer.

The semiconductor layer includes a first region overlapping with the metal oxide layer and the conductive layer, a second region overlapping with the insulating region and the conductive layer, and a third region not overlapping with the conductive layer. The first region is a region functioning as a channel formation region. The third region is a region having lower resistance than the first region and a region functioning as a source region or a drain region. The second region is a region having higher resistance than the third region.

The second region overlaps with the conductive layer functioning as a gate electrode with the insulating region sandwiched therebetween and thus can be called an overlap region (Lov region). The second region also functions as a buffer region to which an electric field of a gate is not applied or to which the electric field is less likely to applied than the first region. The transistor of one embodiment of the present invention includes the second region between the first region that is a channel formation region in the semiconductor layer and the third region that functions as a source region or a drain region. With the second region, a source-drain withstand voltage of the transistor can be improved, whereby a highly reliable transistor can be achieved even when being driven with high voltages.

More specific examples will be described below with reference to drawings.

### Structure Example 1

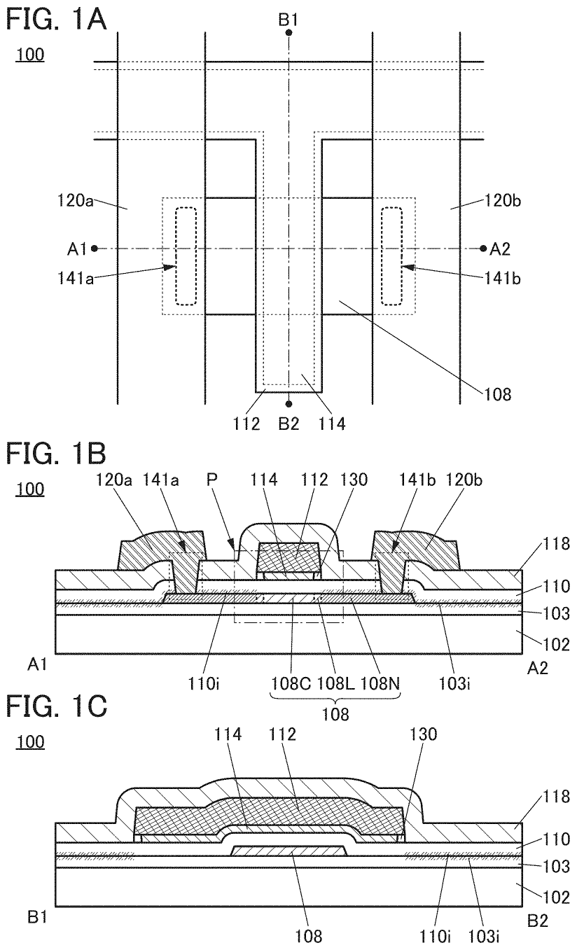

FIG. 1A is a top view of a transistor 100, FIG. 1B corresponds to a cross-sectional view of a cut plane along the dashed-dotted line A1-A2 shown in FIG. 1A, and FIG. 1C corresponds to a cross-sectional view of a cut plane along the dashed-dotted line B1-B2 shown in FIG. 1A. Note that in FIG. 1A, some components (e.g., a gate insulating layer) of the transistor 100 are not illustrated. In addition, the direction of the dashed-dotted line A1-A2 corresponds to a channel length direction, and the direction of the dashed-dotted line B1-B2 corresponds to a channel width direction. Furthermore, some components are not illustrated in top views of transistors in the following drawings, as in FIG. 1A.

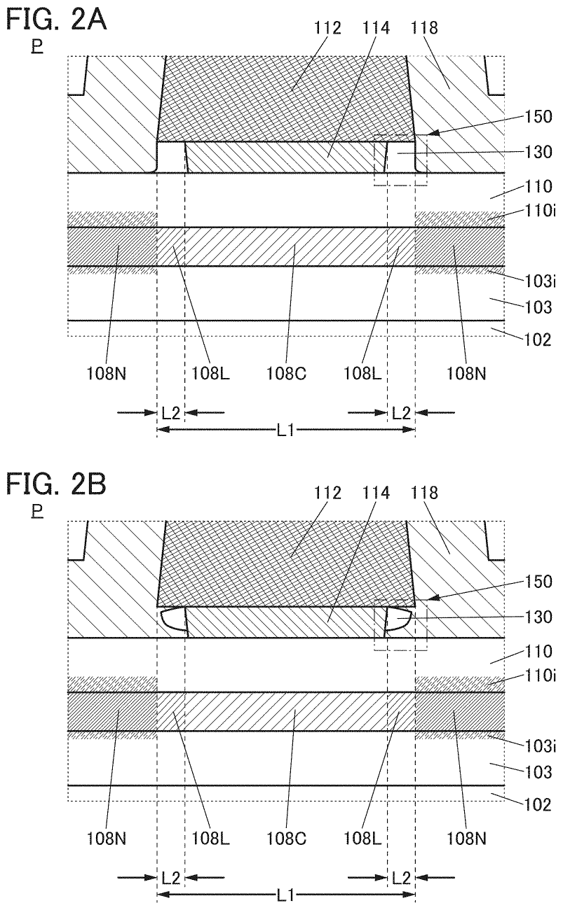

The transistor 100 is provided over a substrate 102 and includes an insulating layer 103, a semiconductor layer 108, an insulating layer 110, a metal oxide layer 114, a conductive layer 112, an insulating layer 118, and the like. The semiconductor layer 108 having an island shape is provided over the insulating layer 103. The insulating layer 110 is provided in contact with a top surface of the insulating layer 103 and a top surface and a side surface of the semiconductor layer 108. The metal oxide layer 114 and the conductive layer 112 are provided to be stacked in this order over the insulating layer 110 and each include a portion overlapping with the semiconductor layer 108. The insulating layer 118 is provided to cover a top surface of the gate insulating layer 110 and a top surface and a side surface of the conductive layer 112. An enlarged view of a region P surrounded by a dashed-dotted line in FIG. 1B is shown in FIG. 2A.

As illustrated in FIG. 2A, the transistor 100 includes an insulating region 150 adjacent to the metal oxide layer 114. The insulating region 150 is positioned between the insulating layer 110 and the conductive layer 112.

For the metal oxide layer 114, a conductive material can be used. Parts of the conductive layer 112 and the metal oxide layer 114 function as a gate electrode. Parts of the insulating layer 110 and the insulating region 150 function as a gate insulating layer. The transistor 100 is what is called a top-gate transistor, in which the gate electrode is provided over the semiconductor layer 108.

An end portion of the metal oxide layer 114 is positioned on an inner side than an end portion of the conductive layer 112 over the insulating layer 110. In other words, the conductive layer 112 includes a portion protruding beyond the end portion of the metal oxide layer 114 over the insulating layer 110.

The semiconductor layer 108 contains a metal oxide exhibiting semiconductor characteristics (hereinafter also referred to as an oxide semiconductor). The semiconductor layer 108 preferably contains at least indium and oxygen. When the semiconductor layer 108 contains an oxide of indium, the carrier mobility can be increased; accordingly, for example, a transistor enabling higher current flow than a transistor containing amorphous silicon can be obtained. Moreover, the semiconductor layer 108 may contain zinc additionally. The semiconductor layer 108 may contain gallium.

Typically, an indium oxide, an indium zinc oxide (In—Zn oxide), an indium gallium zinc oxide (also denoted as In-Ga—Zn oxide or IGZO), or the like can be used for the semiconductor layer 108. Alternatively, an indium tin oxide (In—Sn oxide), an indium tin oxide containing silicon, or the like can be used. The material that can be used for the semiconductor layer 108 is described in detail later.

Here, the composition of the semiconductor layer 108 greatly affects the electrical characteristics and reliability of the transistor 100. For example, an increase in the indium content in the semiconductor layer 108 can increase the carrier mobility and achieve a transistor with high field-effect mobility.

The semiconductor layer 108 includes a region 108C, a pair of regions 108L between which the region 108C is sandwiched, and a pair of regions 108N on outer sides of the regions 108L.

The region 108C overlaps with the conductive layer 112 and the metal oxide layer 114 and functions as a channel formation region.

Each of the regions 108L overlaps with the conductive layer 112 and the insulating region 150. The region 108L can also be referred to as a region that overlaps with the conductive layer 112 but does not overlap with the metal oxide layer 114. The region 108L is a region where a channel can be formed when a gate voltage is applied to the conductive layer 112. However, since the region 108L overlaps with the conductive layer 112 with the insulating region 150 interposed therebetween, the electric field applied to the regions 108L is lower than the electric field applied to the region 108C. As a result, the region 108L is a region having a higher resistance than the region 108C and thus functions as a buffer region for relieving a drain electric field. Furthermore, for example, even when the region 108L extremely has low carrier concentration that is substantially equal to that in the region 108C, a channel can be formed by the electric field of the conductive layer 112.

In this manner, the region 108L is provided between the region 108C that is the channel formation region and the region 108N that is a source region or a drain region, whereby a highly reliable transistor having both a high drain withstand voltage and a high on-state current can be provided.

The region 108N does not overlap either the conductive layer 112 or the metal oxide layer 114 and functions as a source region or a drain region.

In FIG. 2A, the width of the conductive layer 112 in the channel length direction of the transistor 100, that is, the sum of widths of the region 108C and the regions 108L, is denoted by L1. In addition, the width of the insulating region in the channel length direction of the transistor 100, that is the width of each region 108L is denoted by L2.

Each of the low-resistance regions 108N has higher carrier concentration than the region 108C and function as a source region or a drain region. The region 108N can also be referred to as a region having lower resistance than the region 108C, a region having higher carrier concentration than the region 108C, a region having a larger amount of oxygen vacancies than the region 108C, a region having higher hydrogen concentration than the region 108C, or a region having higher impurity concentration than the region 108C.

The electric resistance of the region 108N is preferably as low as possible. For example, the sheet resistance of the region 108N is preferably higher than or equal to 1 Ω/square and low than 1×10³ Ω/square, further preferably higher than or equal to 1 Ω/square and lower than or equal to 8×10² Ω/square. The electric resistance of the region 108C in a state where a channel is not formed is preferably as high as possible, and, for example, the sheet resistance of the region 108C is higher than or equal to 1×10⁹ Ω/square, preferably higher than or equal to 5×10⁹ Ω/square, further preferably higher than or equal to 1×10¹⁰ Ω/square.

Each of the regions 108L can be referred to as a region whose resistance is substantially equal to or lower than that of the region 108C, a region whose carrier concentration is substantially equal to or higher than that of the region 108C, a region whose oxygen vacancy density is substantially equal to or higher than that of the region 108C, or a region whose impurity concentration is substantially equal to or higher than that of the region 108C.

The region 108L can also be referred to as a region whose resistance is substantially equal to or higher than that of the region 108N, a region whose carrier concentration is substantially equal to or lower than that of the region 108N, a region whose oxygen vacancy density is substantially equal to or lower than that of the region 108N, or a region whose impurity concentration is substantially equal to or lower than that of the region 108N.

The sheet resistance of the region 108L is preferably higher than or equal to 1×10³ Ω/square and lower than or equal to 1×10⁹ Ω/square, further preferably higher than or equal to 1×10³ Ω/square and lower than or equal to 1×10⁸ Ω/square, still further preferably higher than or equal to 1×10³ Ω/square and lower than or equal to 1×10⁷ Ω/square. When the resistance is within the above range, a transistor that has favorable electrical characteristics and high reliability can be provided. Note that the sheet resistance can be calculated from a resistance value. Providing such a region 108L between the region 108N and the region 108C can increase the source-drain withstand voltage of the transistor 100.

Note that the carrier concentration is not necessarily uniform in the region 108L; in some cases, the carrier concentration has a falling gradient from the region 108N side toward the region 108C side. For example, one or both of the hydrogen concentration and the oxygen vacancy concentration in the region 108L may have a falling gradient from the region 108N side toward the region 108C side.

The regions 108L can be formed in a self-aligned manner as described later; thus, a photomask for forming the region 108L is not needed and manufacturing cost can be reduced. In addition, forming the regions 108L in a self-aligned manner does not cause relative misalignment between the region 108L and the conductive layer 112; hence, the widths of the regions 108L in the semiconductor layer 108 can be substantially the same.

The region 108L, which functions as an offset region that suffers no electric field of a gate or is less likely to suffer an electric field than the region 108C, can be stably formed without variations between the region 108C and the region 108N in the semiconductor layer 108. As a result, the source-drain withstand voltage of the transistor can be improved, so that the transistor can have high reliability.

The width L2 of each region 108L is preferably greater than or equal to 5 nm and less than or equal to 2 μm, further preferably greater than or equal to 10 nm and less than or equal to 1 μm, still further preferably greater than or equal to 15 nm and less than or equal to 500 nm. Providing the region 108L reduces the concentration of the electric field in the vicinity of the drain, which can inhibit the deterioration of the transistor especially in a high drain voltage state. In particular, when the width L2 of the region 108L is made larger, the concentration of the electric field in the vicinity of the drain can be effectively reduced. However, when the width L2 is greater than 500 nm, the source-drain resistance is increased and the driving speed of the transistor is lowered in some cases. The width L2 in the above range allows a transistor and a semiconductor device to have high reliability and high driving speed. Note that the width L2 of the region 108L can be determined depending on the thickness of the semiconductor layer 108, the thickness of the insulating layer 110, and the level of a voltage applied between the source and the drain in driving the transistor 100.

Providing the region 108L between the region 108C and the region 108N can reduce the current density at a boundary between the region 108C and the region 108N and can suppress heat generation at a boundary between the channel and the source or the drain, which enables a transistor and a semiconductor device to have high reliability.

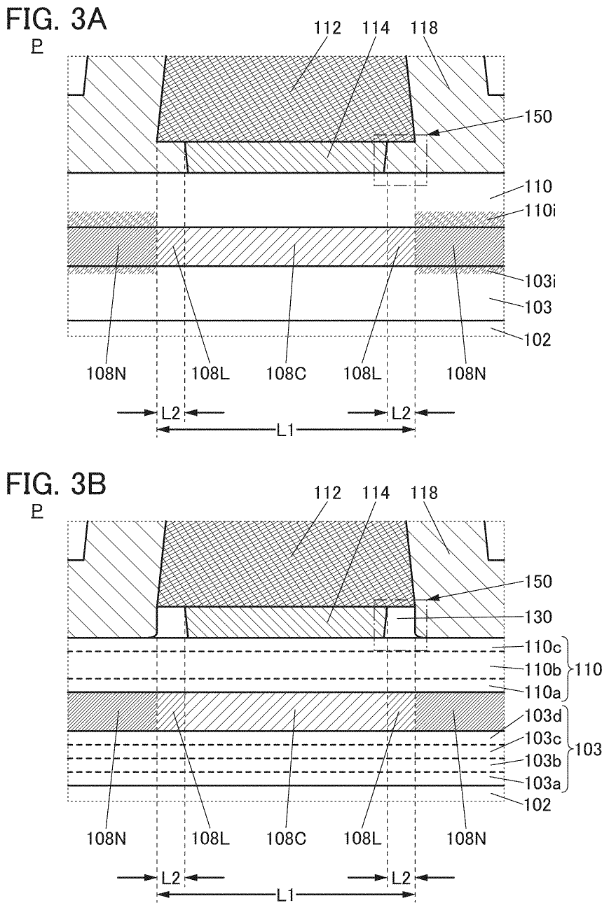

In the transistor 100, the insulating region 150 may include a gap 130. Alternatively, the insulating region 150 may include one or more of the gap 130 and the insulating layer 118. FIG. 2A illustrates an example in which the insulating region 150 includes the gap 130 and does not include the insulating layer 118. FIG. 2A also illustrates an example in which the insulating layer 118 is provided not to be in contact with a side surface of the metal oxide layer 114. FIG. 2B illustrates an example in which the insulating region 150 includes the gap 130 and the insulating layer 118. FIG. 2B also illustrates an example in which the insulating layer 118 is provided in contact with part of the side surface of the metal oxide layer 114. FIG. 3A illustrates an example in which the insulating region 150 includes the insulating layer 118 and does not include the gap 130. FIG. 3A also illustrates an example in which the insulating layer 118 is provided in contact with the side surface of the metal oxide layer 114.

Note that in the case where the insulating region 150 includes the gap 130 and does not include the insulating layer 118 as illustrated in FIG. 2A, the insulating region 150 contains air, and the relative dielectric constant εy of the insulating region 150 is approximately 1 equal to that of the air. Meanwhile, for example, the relative dielectric constants εy of silicon oxide and silicon nitride, which can be used for the insulating layer 110, are approximately 4.0 to 4.5, and 7.0, respectively, and accordingly the relative dielectric constant εy of the insulating layer 110 is greater than 1. In the case where the insulating region 150 includes the gap 130 and the insulating layer 118 as illustrated in FIG. 2B, the relative dielectric constant εy of the insulating region 150 can be calculated from the area ratio of the insulating layer 118 to the gap 130 in the cross section, and the relative dielectric constant εy of the insulating region 150 is greater than 1. Thus, in the case where the insulating region 150 includes the gap 130, the relative dielectric constants of the insulating region 150 and the insulating layer 110 are different from each other.

Note that in this specification and the like, “relative dielectric constants are different” means that, in two relative dielectric constants, a ratio of one that is higher dielectric constant with respect to the other that is lower dielectric constant is greater than or equal to 2.0.

As illustrated in FIG. 1A and FIG. 1B, the transistor 100 may include a conductive layer 120a and a conductive layer 120b over the insulating layer 118. The conductive layer 120a and the conductive layer 120b function as a source electrode or a drain electrode. The conductive layer 120a and the conductive layer 120b are electrically connected to the regions 108N through an opening 141a and an opening 141b, respectively, which are provided in the insulating layer 118 and the insulating layer 110.

The conductive layer 112 is preferably formed using a conductive film containing a metal or an alloy, in which case electric resistance can be reduced. Note that a conductive film containing an oxide may be used as the conductive layer 112.

The metal oxide layer 114 has a function of supplying oxygen to the insulating layer 110. The metal oxide layer 114 positioned between the insulating layer 110 and the conductive layer 112 functions as a barrier film that prevents diffusion of oxygen contained in the insulating layer 110 into a conductive layer 112 side. Furthermore, the metal oxide layer 114 also functions as a barrier film that prevents diffusion of hydrogen and water contained in the conductive layer 112 to the insulating layer 110 side. The metal oxide layer 114 is preferably formed using, for example, a material that is less likely to transmit oxygen and hydrogen than at least the insulating layer 110.

Even in the case where a metal material that is likely to absorb oxygen, such as aluminum or copper, is used for the conductive layer 112, the metal oxide layer 114 can prevent diffusion of oxygen from the insulating layer 110 into the conductive layer 112. Furthermore, even in the case where the conductive layer 112 contains hydrogen, diffusion of hydrogen from the conductive layer 112 into the semiconductor layer 108 through the insulating layer 110 can be prevented. Consequently, carrier density in a channel formation region of the semiconductor layer 108 can be extremely low.

A metal oxide can be used for the metal oxide layer 114. For example, an oxide containing indium, such as indium oxide, indium zinc oxide, indium tin oxide (ITO), or indium tin oxide containing silicon (ITSO), can be used. A conductive oxide containing indium is preferable because of its high conductivity. ITSO is not easily crystallized owing to silicon contained therein, has high planarity, and thus is highly adhesive to a film formed over the ITSO. A metal oxide such as zinc oxide or zinc oxide containing gallium can also be used as the metal oxide layer 114. The metal oxide layer 114 may have a structure in which any of these materials are stacked.

For the metal oxide layer 114, it is preferable to use an oxide material containing one or more elements that are the same as those of the semiconductor layer 108. It is particularly preferable to use an oxide semiconductor material that can be used for the semiconductor layer 108. Here, a metal oxide film formed using the same sputtering target as that for the semiconductor layer 108 is preferably used for the metal oxide layer 114 because an apparatus can be shared.

The metal oxide layer 114 is preferably formed using a sputtering apparatus. For example, in the case where an oxide film is formed using a sputtering apparatus, forming the oxide film in an atmosphere containing an oxygen gas can suitably supply oxygen into the insulating layer 110 or the semiconductor layer 108.

The region 108N of the semiconductor layer 108 is a region containing an impurity element. Examples of the impurity element are hydrogen, boron, carbon, nitrogen, fluorine, phosphorus, sulfur, arsenic, aluminum, a rare gas, or the like. Note that typical examples of a rare gas include helium, neon, argon, krypton, and xenon. In particular, boron or phosphorus is preferably included. Alternatively, two or more of these impurity elements may be contained.

As described later, treatment for adding the impurity to the region 108N can be performed through the insulating layer 110 using the conductive layer 112 as a mask.

The region 108N preferably includes a region where the impurity concentration is higher than or equal to 1×10¹⁹ atoms/cm³ and lower than or equal to 1×10²³ atoms/cm³, preferably higher than or equal to 5×10¹⁹ atoms/cm³ and lower than or equal to 5×10²² atoms/cm³, further preferably higher than or equal to 1×10²⁰ atoms/cm³ and lower than or equal to 1×10²² atoms/cm³.

The concentrations of the impurities included in the region 108N can be analyzed by an analysis method such as secondary ion mass spectrometry (SIMS) or X-ray photoelectron spectroscopy (XPS), for example. In the case of using XPS analysis, it is possible to find out the concentration distribution in the depth direction by combination of XPS analysis and ion sputtering from a front surface side or a rear surface side.

In addition, the impurity element preferably exists in an oxidized state in the region 108N. For example, it is preferable to use an element that is easily oxidized, such as boron, phosphorus, magnesium, aluminum, or silicon, as the impurity element. Since such an element that is easily oxidized can exist stably in a state of being bonded to oxygen in the semiconductor layer 108 to be oxidized, the element can be inhibited from being released even when a high temperature (e.g., higher than or equal to 400° C., higher than or equal to 600° C., or higher than or equal to 800° C.) is applied in a later step. Furthermore, the impurity element takes oxygen in the semiconductor layer 108 away, and many oxygen vacancies are generated in the region 108N. The oxygen vacancies are bonded to hydrogen in a film to serve as carrier supply sources; thus, the regions 108N are in an extremely low-resistance state.

For example, in the case where boron is used as the impurity element, boron contained in the region 108N can exist in a state of being bonded to oxygen. This can be confirmed when a spectrum peak attributed to a B₂O₃ bond is observed in XPS analysis. Furthermore, in XPS analysis, the intensity of a spectrum peak attributed to a state where a boron element exists alone is so low that the spectrum peak is not observed or is buried in background noise detected around the lower measurement limit.

Note that the above impurity element contained in the region 108N sometimes partly diffuses to the region 108L and the region 108C owing to the influence of heat applied during the manufacturing process or the like. Each of the concentrations of the impurity element in the region 108L and the region 108C is preferably lower than or equal to one tenth, further preferably lower than or equal to one hundredth of that of the impurity element in the region 108N.

For each of the insulating layer 103 and the insulating layer 110 that are in contact with the channel formation region of the semiconductor layer 108, an oxide film is preferably used. For example, an oxide film such as a silicon oxide film, a silicon oxynitride film, or an aluminum oxide film can be used. Accordingly, oxygen released from the insulating layer 103 and the insulating layer 110 can be supplied to the channel formation region of the semiconductor layer 108 by heat treatment or the like in the manufacturing process of the transistor 100 to reduce oxygen vacancies in the semiconductor layer 108.

Note that in this specification and the like, oxynitride refers to a substance that contains more oxygen than nitrogen in its composition, and oxynitride is included in oxide. Nitride oxide refers to a substance that contains more nitrogen than oxygen in its composition, and nitride oxide is included in nitride.

The insulating layer 110 that is in contact with the semiconductor layer 108 preferably includes a region containing oxygen in excess of that in the stoichiometric composition. In other words, the insulating layer 110 is an insulating film capable of releasing oxygen. It is also possible to supply oxygen into the insulating layer 110 by forming the insulating layer 110 in an oxygen atmosphere, performing heat treatment, plasma treatment, or the like on the deposited insulating layer 110 in an oxygen atmosphere, or depositing an oxide film over the insulating layer 110 in an oxygen atmosphere, for example.

For example, the insulating layer 110 can be formed by a sputtering method, a chemical vapor deposition (CVD) method, a vacuum evaporation method, a pulsed laser deposition (PLD) method, an atomic layer deposition (ALD) method, or the like. Examples of the CVD method include a plasma-enhanced chemical vapor deposition (PECVD) method and a thermal CVD method.

In particular, the insulating layer 110 is preferably formed by a plasma CVD method.

The insulating layer 110 is formed over the semiconductor layer 108, and thus is preferably formed under conditions where the semiconductor layer 108 is damaged as little as possible. For example, the insulating layer 110 can be formed under conditions where the deposition rate is sufficiently low.

For example, a source gas that contains a silicon-containing deposition gas such as silane or disilane and an oxidizing gas such as oxygen, ozone, dinitrogen monoxide, or nitrogen dioxide can be used as a deposition gas for depositing a silicon oxynitride film. A dilution gas such as argon, helium, or nitrogen may be contained in addition to the source gas.

The insulating layer 110 includes a region in contact with the region 108C of the semiconductor layer 108, i.e., a region overlapping with the conductive layer 112 and the metal oxide layer 114. The insulating layer 110 further includes a region that is in contact with the region 108L of the semiconductor layer 108 and does not overlap with the metal oxide layer 114. The insulating layer 110 further includes a region that is in contact with the region 108N of the semiconductor layer 108 and does not overlap with the conductive layer 112.

In some cases, a region 110i of the insulating layer 110, which overlaps with the region 108N, contains the above impurity element. In this case, as in the region 108N, the impurity element in the insulating layer 110 preferably exists in a state of being bonded to oxygen. Since such an element that is easily oxidized can exist stably in a state of being bonded to oxygen in the insulating layer 110 to be oxidized, the element can be inhibited from being released even when a high temperature is applied in a later step. Furthermore, particularly in the case where oxygen (also referred to as excess oxygen) that might be released by heating is included in the insulating layer 110, excess oxygen and the impurity element are bonded to each other and stabilized, so that oxygen can be inhibited from being supplied from the insulating layer 110 to the region 108N. Furthermore, since oxygen is less likely to be diffused into part of the insulating layer 110 containing the oxidized impurity element, supply of oxygen to the region 108N from layers above the insulating layer 110 therethrough is suppressed and an increase in the resistance of the region 108N can also be prevented.

The insulating layer 103 includes, at the interface in contact with the insulating layer 110 or in the vicinity of the interface, a region 103i containing the above impurity element as illustrated in FIG. 1B and FIG. 1C. As illustrated in FIG. 2A, the region 103i may be provided at the interface in contact with the region 108N or in the vicinity of the interface. In that case, a portion overlapping with the region 108N has a lower impurity concentration than a portion in contact with the insulating layer 110.

The insulating layer 110 and the insulating layer 103 may each have a stacked-layer structure. An example in which each of the insulating layer 110 and the insulating layer 103 has a stacked-layer structure is illustrated in FIG. 3B. The insulating layer 110 has the stacked-layer structure in which an insulating layer 110a, an insulating layer 110b, and an insulating layer 110c are stacked from the semiconductor layer 108 side. The insulating layer 103 has the stacked-layer structure in which an insulating layer 103a, an insulating layer 103b, an insulating layer 103c, and an insulating layer 103d are stacked from the substrate 102 side. Note that in FIG. 3B, the region 110i and the region 103i are not illustrated for clarity.

An example of the insulating layer 110 having a stacked-layer structure is described.

The insulating layer 110a includes a region in contact with the semiconductor layer 108. The insulating layer 110c includes a region in contact with the metal oxide layer 114. The insulating layer 110b is positioned between the insulating layer 110a and the insulating layer 110c.

It is preferable that the insulating layer 110a, the insulating layer 110b, and the insulating layer 110c be each an insulating film containing an oxide. In that case, the insulating layer 110a, the insulating layer 110b, and the insulating layer 110c are preferably formed successively with the same film formation apparatus.

As each of the insulating layer 110a, the insulating layer 110b, and the insulating layer 110c, for example, an insulating layer including one or more kinds of a silicon oxide film, a silicon oxynitride film, a silicon nitride oxide film, an aluminum oxide film, a hafnium oxide film, an yttrium oxide film, a zirconium oxide film, a gallium oxide film, a tantalum oxide film, a magnesium oxide film, a lanthanum oxide film, a cerium oxide film, and a neodymium oxide film can be used.

The insulating layer 110 that is in contact with the semiconductor layer 108 preferably has a stacked structure of oxide insulating films and further preferably includes a region containing oxygen in excess of that in the stoichiometric composition. In other words, the insulating layer 110 is an insulating film capable of releasing oxygen. It is also possible to supply oxygen into the insulating layer 110 by forming the insulating layer 110 in an oxygen atmosphere, performing heat treatment, plasma treatment, or the like on the deposited insulating layer 110 in an oxygen atmosphere, or depositing an oxide film over the insulating layer 110 in an oxygen atmosphere, for example.

For example, the insulating layer 110a, the insulating layer 110b, and the insulating layer 110c can be formed by a sputtering method, a chemical vapor deposition (CVD) method, a vacuum evaporation method, a pulsed laser deposition (PLD) method, an atomic layer deposition (ALD) method, or the like. Examples of the CVD method include a plasma-enhanced chemical vapor deposition (PECVD) method and a thermal CVD method.

In particular, the insulating layer 110a, the insulating layer 110b, and the insulating layer 110c are preferably formed by a PECVD method.

The insulating layer 110a is formed over the semiconductor layer 108, and thus is preferably formed under conditions where the semiconductor layer 108 is damaged as little as possible. For example, the insulating layer 110a can be formed under conditions where the deposition rate is sufficiently low.

For example, when a silicon oxynitride film is formed as the insulating layer 110a by a plasma CVD method, damage to the semiconductor layer 108 can be extremely small by low-power film formation. In the transistor 100 of one embodiment of the present invention, a film formed by a deposition method in which damage to the semiconductor layer 108 is reduced is used as the insulating layer 110a in contact with the top surface of the semiconductor layer 108. Therefore, the density of defect states at the interface between the semiconductor layer 108 and the insulating layer 110 is reduced and the transistor 100 can thus have high reliability.

For example, a source gas that contains a silicon-containing deposition gas such as silane or disilane and an oxidizing gas such as oxygen, ozone, dinitrogen monoxide, or nitrogen dioxide can be used as a deposition gas for deposition of a silicon oxynitride film. A dilution gas such as argon, helium, or nitrogen may be contained in addition to the source gas.

When the proportion of the flow rate of the deposition gas in the total flow rate of the film formation gas (hereinafter also simply referred to as a flow rate ratio) is low, for example, the film formation speed can be made low, which allows formation of a dense film with few defects.

The insulating layer 110b is preferably formed under conditions where the deposition rate is higher than that of the insulating layer 110a. Thus, the productivity can be improved.

For example, the insulating layer 110b can be formed at an increased deposition rate by setting the flow rate ratio of the deposition gas to be higher than that of the insulating layer 110a.

The insulating layer 110c is preferably an extremely dense film whose surface has few defects and on the surface of which an impurity contained in the air such as water is not easily adsorbed. For example, like the insulating layer 110a, the insulating layer 110c can be formed at a sufficiently low deposition rate.

Since the insulating layer 110c is formed over the insulating layer 110b, the formation of the insulating layer 110c affects the semiconductor layer 108 less than the formation of the insulating layer 110a. Thus, the insulating layer 110c can be formed under conditions where the power is higher than that for the insulating layer 110a. The reduced flow rate ratio of the deposition gas and the relatively high-power film formation enable formation of a dense film in which defects in its surface are reduced.

That is, the insulating layer 110 can be formed using a stacked-layer film formed under such conditions that the deposition rate of the insulating layer 110b is the highest, that of the insulating layer 110a is the second highest, and that of the insulating layer 110c is the lowest. In the insulating layer 110, the etching rate of the insulating layer 110b is the highest, that of the insulating layer 110a is the second highest, and that of the insulating layer 110c is the lowest when wet etching or dry etching is performed under the same condition.

The insulating layer 110b is preferably formed to be thicker than the insulating layer 110a and the insulating layer 110c. The time taken for forming the insulating layer 110 can be shortened by forming the insulating layer 110b, which is formed at the highest deposition rate, to be thick.

Here, the boundary between the insulating layer 110a and the insulating layer 110b and the boundary between the insulating layer 110b and the insulating layer 110c are sometimes unclear and thus are clearly shown by dashed lines in FIG. 3B. Note that since the insulating layer 110a and the insulating layer 110b have different film densities, the boundary therebetween can be observed as a difference in contrast in a transmission electron microscopy (TEM) image or the like of a cross section of the insulating layer 110 in some cases. Similarly, the boundary between the insulating layer 110b and the insulating layer 110c can be observed in some cases.

An example of the insulating layer 103 having a stacked-layer structure is described.

The insulating layer 103 has the stacked-layer structure in which the insulating layer 103a, the insulating layer 103b, the insulating layer 103c, and the insulating layer 103d are stacked from the substrate 102 side. The insulating layer 103a is in contact with the substrate 102. The insulating layer 103d is in contact with the semiconductor layer 108.

The insulating layer 103 functioning as the second gate insulating layer preferably satisfies at least one of the following characteristics, further preferably satisfies all of the following characteristics: high withstand voltage, low stress, unlikeliness of releasing hydrogen and water, a small number of defects, and prevention of diffusion of impurities contained in the substrate 102.

Among the four insulating films included in the insulating layer 103, the insulating layer 103a, the insulating layer 103b, and the insulating layer 103c positioned on the substrate 102 side are each preferably formed using an insulating film containing nitrogen. In contrast, the insulating layer 103d in contact with the semiconductor layer 108 is preferably formed using an insulating film containing oxygen. The four insulating films included in the insulating layer 103 are preferably formed successively without exposure to the air with a plasma CVD apparatus.

As each of the insulating layer 103a, the insulating layer 103b, and the insulating layer 103c, an insulating film containing nitrogen such as a silicon nitride film, a silicon nitride oxide film, an aluminum nitride film, or a hafnium nitride film can be used. Furthermore, as the insulating layer 103c, an insulating film that can be used as the insulating layer 110 can also be used.

It is preferable that the insulating layer 103a and the insulating layer 103c be each a dense film that can prevent diffusion of an impurity from the lower side. It is preferable that the insulating layer 103a be able to block an impurity contained in the substrate 102 and that the insulating layer 103c be able to block hydrogen and water contained in the insulating layer 103b. Thus, an insulating film that is formed at a lower deposition rate than the insulating layer 103b can be used as each of the insulating layer 103a and the insulating layer 103c.

In contrast, it is preferable that the insulating layer 103b be formed using an insulating film having low stress and being formed at a high deposition rate. The insulating layer 103b is preferably formed to be thicker than each of the insulating layer 103a and the insulating layer 103c.

For example, even in the case where silicon nitride films formed by a plasma CVD method are used as the insulating layer 103a, the insulating layer 103b, and the insulating layer 103c, the film density of the insulating layer 103b is smaller than the film densities of the other two insulating layers. Thus, in a transmission electron microscope image of a cross section of the insulating layer 103, a difference in contrast can be observed in some cases. Note that the boundary between the insulating layer 103a and the insulating layer 103b and the boundary between the insulating layer 103b and the insulating layer 103c are sometimes unclear and thus are clearly shown by dashed lines in FIG. 3B.

As the insulating layer 103d in contact with the semiconductor layer 108, it is preferable to use a dense insulating film on a surface of which an impurity such as water is less likely to be adsorbed. In addition, it is preferable to use an insulating film which includes as few defects as possible and in which impurities such as water or hydrogen are reduced. For example, an insulating film similar to the insulating layer 110c included in the insulating layer 110 can be used as the insulating layer 103d.

With the insulating layer 103 having such a stacked-layer structure, the transistor can have extremely high reliability.

The insulating layer 118 functions as a protective layer protecting the transistor 100. For example, an inorganic insulating material such as an oxide or a nitride can be used for the insulating layer 110. More specifically, for example, an inorganic insulating material such as silicon oxide, silicon oxynitride, silicon nitride, silicon nitride oxide, aluminum oxide, aluminum oxynitride, aluminum nitride, hafnium oxide, or hafnium aluminate can be used.

As the insulating layer 118, a material providing high step coverage is preferably used. Alternatively, the insulating layer 118 is preferably formed by a film-formation method providing high step coverage. For formation of the insulating layer 118, a PECVD method can be favorably used, for example. Note that, in some cases, a step between the conductive layer 112 and the insulating layer 110 causes a lowering of coverage with the insulating layer 118, which is provided over the layers, thereby generating disconnection or a low-density region (also referred to as void) in the insulating layer 118. When the disconnection or the low-density region (also referred to as a void) is generated in the insulating layer 118, entry of impurities such as water or hydrogen is caused, leading to a possibility of a reduction in reliability of the transistor. With the insulating layer 118 with high step coverage, a highly reliable transistor can be obtained.

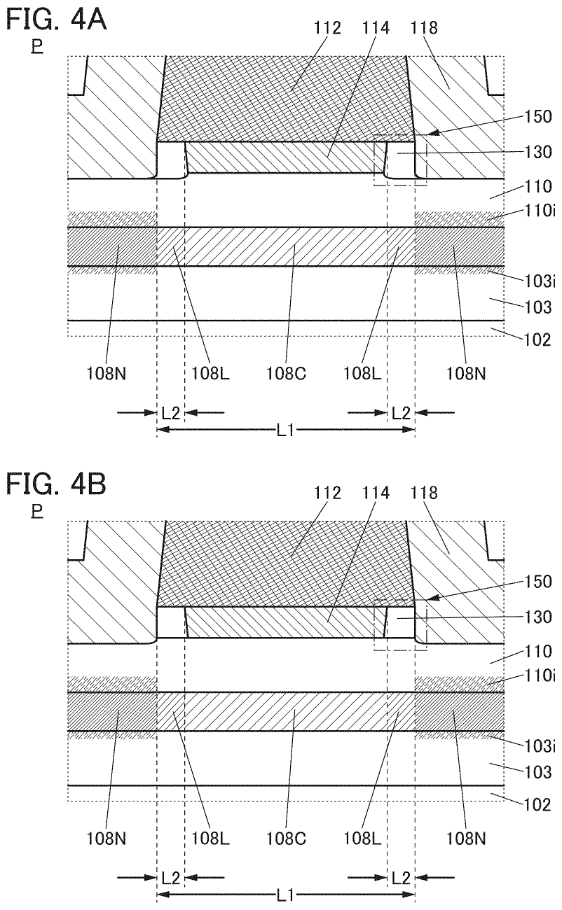

At the time of formation of the conductive layer 112 and the metal oxide layer 114, the thickness of the insulating layer 110 might be partly reduced in some cases. FIG. 4A illustrates an example in which the thickness of the insulating layer 110 in a region not overlapping with the metal oxide layer 114 is smaller than that of the insulating layer 110 in a region overlapping with the metal oxide layer 114. Furthermore, FIG. 4B illustrates an example in which the thickness of the insulating layer 110 in a region not overlapping with the conductive layer 112 is smaller than that of the insulating layer 110 in a region overlapping with the conductive layer 112. Note that in the case where the insulating layer 110 has a stacked-layer structure as illustrated in FIG. 3B, the insulating layer 110c preferably remains in a region not overlapping with the metal oxide layer 114. With a structure in which the insulating layer 110c remains in the region not overlapping with the metal oxide layer 114, water adsorption on the insulating layer 110 can be inhibited efficiently. The thickness of the insulating layer 110c in the region overlapping with the conductive layer 112 is greater than or equal to 1 nm and less than or equal to 50 nm, preferably greater than or equal to 2 nm and less than or equal to 40 nm, further preferably greater than or equal to 3 nm and less than or equal to 30 nm.

### Structure Example 2

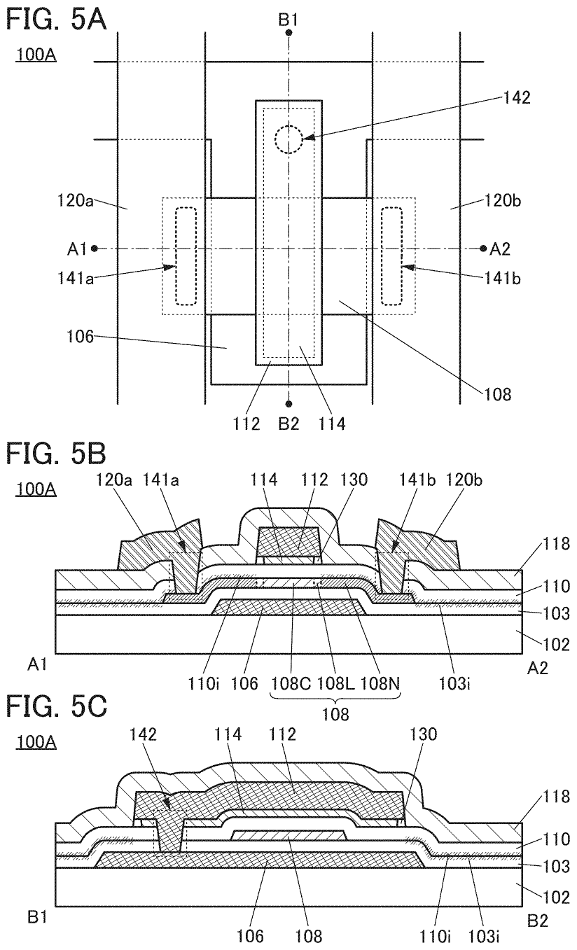

FIG. 5A is a top view of a transistor 100A, FIG. 5B is a cross-sectional view of the transistor 100A in a channel length direction, and FIG. 5C is a cross-sectional view of the transistor 100A in a channel width direction.

The transistor 100A is different from Structure Example 1 mainly in including a conductive layer 106 between the substrate 102 and the insulating layer 103. The conductive layer 106 includes a region overlapping with the semiconductor layer 108 and the conductive layer 112.

In the transistor 100A, the conductive layer 112 has a function of a second gate electrode (also referred to as a top gate electrode), and the conductive layer 106 has a function of a first gate electrode (also referred to as a bottom gate electrode). In addition, part of the insulating layer 110 functions as a second gate insulating layer, and part of the insulating layer 103 functions as a first gate insulating layer.

A portion of the semiconductor layer 108 that overlaps with at least one of the conductive layer 112 and the conductive layer 106 functions as a channel formation region. Note that for easy explanation, a portion of the semiconductor layer 108 that overlaps with the conductive layer 112 is sometimes referred to as a channel formation region; however, a channel can also be actually formed in a portion not overlapping with the conductive layer 112 and overlapping with the conductive layer 106 (a portion including the regions 108N).

As illustrated in FIG. 5C, the conductive layer 106 may be electrically connected to the conductive layer 112 through an opening 142 provided in the metal oxide layer 114, the insulating layer 110, and the insulating layer 103. In that case, the same potential can be supplied to the conductive layer 106 and the conductive layer 112.

For the conductive layer 106, a material similar to that for the conductive layer 112, the conductive layer 120a, or the conductive layer 120b can be used. In particular, a material containing copper is preferably used for the conductive layer 106, in which case wiring resistance can be reduced.

As illustrated in FIG. 5A and FIG. 5C, the conductive layer 112 and the conductive layer 106 preferably extend beyond an end portion of the semiconductor layer 108 in the channel width direction. In that case, as illustrated in FIG. 5C, a structure is employed in which the semiconductor layer 108 in the channel width direction is entirely covered with the conductive layer 112 and the conductive layer 106 with the insulating layer 110 and the insulating layer 103 therebetween.

With such a structure, the semiconductor layer 108 can be electrically surrounded by electric fields generated by a pair of gate electrodes. At this time, it is particularly preferable that the same potential be applied to the conductive layer 106 and the conductive layer 112. In that case, electric fields for inducing a channel can be effectively applied to the semiconductor layer 108, whereby the on-state current of the transistor 100A can be increased. Thus, the transistor 100A can also be miniaturized.

Note that a structure in which the conductive layer 112 and the conductive layer 106 are not connected to each other may be employed. In that case, a constant potential may be supplied to one of the pair of gate electrodes, and a signal for driving the transistor 100A may be supplied to the other. In this case, the potential supplied to one of the gate electrodes enables control of the threshold voltage at the time of driving the transistor 100A with the other gate electrode.

The insulating layer 103 preferably has a stacked-layer structure. For example, the insulating layer 103 can have a stacked-layer structure in which the insulating layer 103a, the insulating layer 103b, the insulating layer 103c, and the insulating layer 103d are stacked in this order from the conductive layer 106 side (see FIG. 3B). The insulating layer 103a in contact with the conductive layer 106 is preferably a film capable of blocking the metal element contained in the conductive layer 106. The above description can be referred to for the insulating layer 103a, the insulating layer 103b, the insulating layer 103c, and the insulating layer 103d; detailed description thereof is omitted.

When the conductive layer 106 is formed using a metal film or an alloy film whose constituent element is less likely to be diffused into the insulating layer 103, a structure in which three insulating films of the insulating layer 103b, the insulating layer 103c, and the insulating layer 103d are stacked without providing the insulating layer 103a may be employed.

With the insulating layer 103 having such a stacked-layer structure, a transistor having extremely high reliability can be provided.

### Structure Example 3

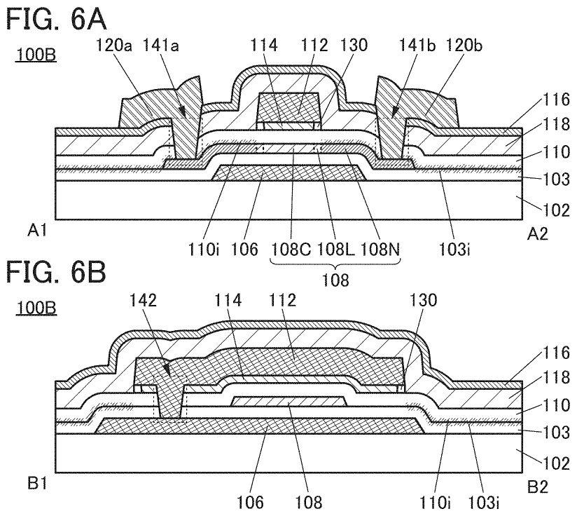

FIG. 6A is a cross-sectional view of a transistor 100B in the channel length direction, and FIG. 6B is a cross-sectional view of the transistor 100B in the channel width direction. Since FIG. 5A can be referred to for a top view of the transistor 100B; therefore, the description thereof is omitted.

The transistor 100B is different from the transistor 100A described in Structure Example 2 mainly in that an insulating layer 116 is provided over the insulating layer 118.

The insulating layer 116 is provided to cover a top surface of the insulating layer 110. The insulating layer 116 has a function of inhibiting diffusion of impurities into the semiconductor layer 108 from above the insulating layer 116. The conductive layer 120a and the conductive layer 120b are electrically connected to the regions 108N through the opening 141a and the opening 141b, respectively, which are provided in the insulating layer 116, the insulating layer 118, and the insulating layer 110.

For the insulating layer 116, for example, an insulating film containing a nitride, such as silicon nitride, silicon nitride oxide, silicon oxynitride, aluminum nitride, or aluminum nitride oxide can be favorably used. In particular, because of having a blocking property against hydrogen and oxygen, silicon nitride can prevent both a diffusion of hydrogen from the outside into the semiconductor layer and a release of oxygen from the semiconductor layer to the outside, and thus a highly reliable transistor can be achieved.

When the insulating layer 116 is formed using a metal nitride, it is preferable to use a nitride of aluminum, titanium, tantalum, tungsten, chromium, or ruthenium. In particular, aluminum or titanium is preferably included. For example, an aluminum nitride film formed by a reactive sputtering method using aluminum as a sputtering target and a nitrogen-including gas as a deposition gas can be a film having both an extremely high insulating property and an extremely high blocking property against hydrogen and oxygen when the flow rate of a nitrogen gas to the total flow rate of the deposition gas is appropriately controlled. Thus, when such an insulating film including a metal nitride is provided in contact with the semiconductor layer 108, the resistance of the semiconductor layer 108 can be lowered, and a release of oxygen from the semiconductor layer 108 and a diffusion of hydrogen into the semiconductor layer 108 can be favorably prevented.

In the case where aluminum nitride is used as the metal nitride, the thickness of the insulating layer including aluminum nitride is preferably 5 nm or more. A film with such a small thickness can have both a high blocking property against hydrogen and oxygen and a function of lowering the resistance of the semiconductor layer. Note that there is no upper limit of the thickness of the insulating layer; however, the thickness is preferably less than or equal to 500 nm, further preferably less than or equal to 200 nm, still further preferably less than or equal to 50 nm in consideration of productivity.

In the case of using an aluminum nitride film as the insulating layer 116, it is preferable to use a film that satisfies the composition formula AlNₓ (x is a real number greater than 0 and less than or equal to 2, and preferably, x is a real number greater than 0.5 and less than or equal to 1.5). In that case, a film having an excellent insulating property and high thermal conductivity can be obtained, and thus dissipation of heat generated in driving the transistor 100B can be increased.

Alternatively, an aluminum titanium nitride film, a titanium nitride film, or the like can be used as the insulating layer 116.

The insulating layer 116 is provided over the insulating layer 118, so that a transistor having a high on-state current can be obtained. Alternatively, a transistor whose threshold voltage is controllable can be provided. In addition, the transistor having high reliability can be achieved.

### Structure Example 4

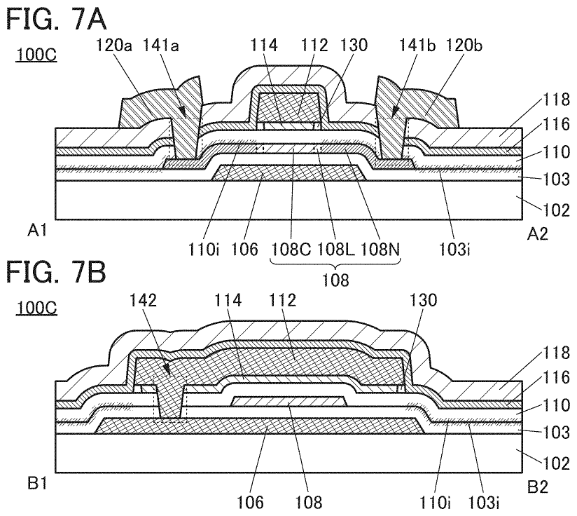

FIG. 7A is a cross-sectional view of a transistor 100C in the channel length direction, and FIG. 7B is a cross-sectional view of the transistor 100C in the channel width direction. Since FIG. 5A can be referred to for a top view of the transistor 100C; therefore, the description thereof is omitted.

The transistor 100C is different from the transistor 100A of Structure Example 2 mainly in that the insulating layer 116 is provided between the insulating layer 118 and the insulating layer 110.

The insulating layer 116 is provided to cover a top surface of the insulating layer 118 and a top surface and a side surface of the conductive layer. The insulating layer 116 may be in contact with a side surface of the metal oxide layer 114. The insulating layer 116 may be in contact with part of the side surface of the metal oxide layer 114. The insulating layer 116 has a function of inhibiting diffusion of impurities into the semiconductor layer 108 from above the insulating layer 116.

With the insulating layer 116 provided between the insulating layer 118 and the insulating layer 110, a transistor with high on-state current can be obtained. Alternatively, a transistor whose threshold voltage is controllable can be provided. In addition, the transistor having high reliability can be achieved.

### <Manufacturing Method Example>

A manufacturing method example of a transistor of one embodiment of the present invention will be described below. Here, description will be made giving, as an example, the transistor 100A illustrated in Structure Example 2.

Note that thin films forming the semiconductor device (insulating films, semiconductor films, conductive films, and the like) can be formed by any of a sputtering method, a chemical vapor deposition (CVD) method, a vacuum evaporation method, a pulsed laser deposition (PLD) method, and an atomic layer deposition (ALD) method. As the CVD method, a plasma-enhanced chemical vapor deposition (PECVD) method, a thermal CVD method, or the like may be used. In addition, as an example of the thermal CVD method, a metal organic chemical vapor deposition (MOCVD) method can be given.

The thin films that form the semiconductor device (insulating films, semiconductor films, conductive films, and the like) can be formed by a method such as spin coating, dipping, spray coating, ink jetting, dispensing, screen printing, offset printing, a doctor knife, slit coating, roll coating, curtain coating, or knife coating.

When the thin films that form the semiconductor device are processed, a photolithography method or the like can be used for the processing. Besides, a nanoimprinting method, a sandblasting method, a lift-off method, or the like may be used for the processing of the thin films. Island-shaped thin films may be directly formed by a deposition method using a blocking mask such as a metal mask.

There are two typical examples of a photolithography method. In one of the methods, a resist mask is formed over a thin film that is to be processed, the thin film is processed by etching or the like, and then the resist mask is removed. In the other method, after a photosensitive thin film is deposited, exposure and development are performed, so that the thin film is processed into a desired shape.

For light used for exposure in a photolithography method, for example, an i-line (with a wavelength of 365 nm), a g-line (with a wavelength of 436 nm), an h-line (with a wavelength of 405 nm), or combined light of any of them can be used. Besides, ultraviolet light, KrF laser light, ArF laser light, or the like can be used. Furthermore, exposure may be performed by liquid immersion light exposure technique. Furthermore, as the light used for the exposure, extreme ultra-violet (EUV) light or X-rays may be used. Furthermore, instead of the light used for the exposure, an electron beam can also be used. It is preferable to use extreme ultra-violet light, X-rays, or an electron beam because extremely minute processing can be performed. Note that in the case of performing exposure by scanning of a beam such as an electron beam, a photomask is not needed.

For etching of the thin film, a dry etching method, a wet etching method, a sandblasting method, or the like can be used.

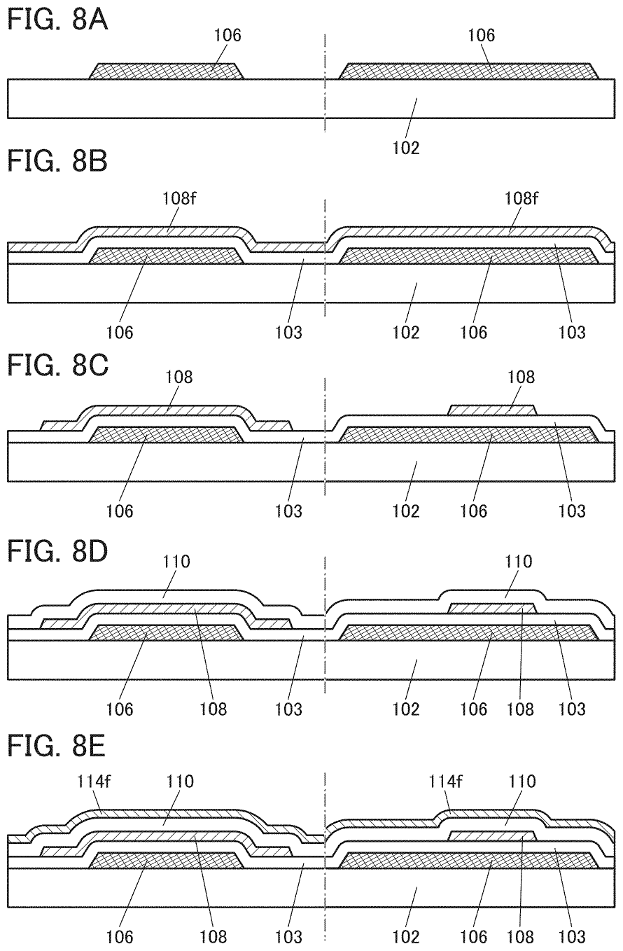

FIG. 8A to FIG. 11C are cross-sectional views in the channel length direction and the channel width direction, arranged side by side, of the transistor 100A at each stage in the manufacturing process.

### [Formation of Conductive Layer 106]

A conductive film is deposited over the substrate 102 and processed by etching, whereby the conductive layer 106 functioning as a gate electrode is formed (FIG. 8A).

At this time, as illustrated in FIG. 8A, the conductive layer 106 is preferably processed so as to have an end portion with a tapered shape. In that case, the step coverage of the insulating layer 103 formed in the next step can be improved.

When a conductive film containing copper is used as the conductive film to be the conductive layer 106, wiring resistance can be reduced. For example, a conductive film containing copper is preferably used in the case of a large display device or a display device with a high resolution. Even in the case where a conductive film containing copper is used as the conductive layer 106, diffusion of copper to the semiconductor layer 108 side can be suppressed by the insulating layer 103, whereby a highly reliable transistor can be obtained.

### [Formation of Insulating Layer 103]

Next, the insulating layer 103 is formed to cover the substrate 102 and the conductive layer 106. The insulating layer 103 can be formed by a PECVD method, an ALD method, a sputtering method, or the like.

Here, the insulating layer 103 is formed by stacking the insulating layer 103a, the insulating layer 103b, the insulating layer 103c, and the insulating layer 103d.

In particular, each of the insulating layers included in the insulating layer 103 is preferably formed by a PECVD method. For the method for forming the insulating layer 103, the description in Structure Example 1 can be referred to.

After the insulating layer 103 is formed, treatment for supplying oxygen to the insulating layer 103 may be performed. For example, plasma treatment, heat treatment, or the like in an oxygen atmosphere can be performed. Alternatively, oxygen may be supplied to the insulating layer 103 by a plasma ion doping method or an ion implantation method.

### [Formation of Semiconductor Layer 108]

Next, a metal oxide film 108f is formed over the insulating layer 103 (FIG. 8B).

The metal oxide film 108f is preferably formed by a sputtering method using a metal oxide target.

The metal oxide film 108f is preferably a dense film with as few defects as possible. The metal oxide film 108f is preferably a highly purified film in which impurities such as hydrogen and water are reduced as much as possible. It is particularly preferable to use a metal oxide film having crystallinity as the metal oxide film 108f.

In forming the metal oxide film 108f, an inert gas (e.g., a helium gas, an argon gas, or a xenon gas) may be mixed in addition to the oxygen gas. Note that when the proportion of an oxygen gas in the whole deposition gas (hereinafter also referred to as an oxygen flow rate ratio) at the time of forming the metal oxide film 108f is higher, the crystallinity of the metal oxide film 108f can be higher and a transistor with higher reliability can be obtained. By contrast, when the oxygen flow rate ratio is lower, the crystallinity of the metal oxide film 108f is lower and a transistor with a high on-state current can be obtained.

In forming the metal oxide film 108f, as the substrate temperature becomes higher, a denser metal oxide film having higher crystallinity can be formed. On the other hand, as the substrate temperature becomes lower, a metal oxide film having lower crystallinity and higher electric conductivity can be formed.

The metal oxide film 108f is formed under the film formation conditions where a substrate temperature is higher than or equal to room temperature and lower than or equal to 250° C., preferably higher than or equal to room temperature and lower than or equal to 200° C., further preferably higher than or equal to room temperature and lower than or equal to 140° C. For example, when the substrate temperature is higher than or equal to room temperature and lower than 140° C., high productivity is achieved, which is preferable. Furthermore, when the metal oxide film 108f is deposited with the substrate temperature set at room temperature or without heating the substrate, the crystallinity can be made low.

It is preferable to perform any one or more of treatment for desorbing water, hydrogen, an organic substance, or the like adsorbed onto a surface of the insulating layer 103 and treatment for supplying oxygen into the insulating layer 103 before deposition of the metal oxide film 108f For example, heat treatment can be performed at a temperature higher than or equal to 70° C. and lower than or equal to 200° C. in a reduced-pressure atmosphere. Alternatively, plasma treatment may be performed in an oxygen-containing atmosphere. Alternatively, oxygen may be supplied to the insulating layer 103 by plasma treatment in an atmosphere containing an oxidizing gas such as dinitrogen monoxide (N₂O). When plasma treatment containing a dinitrogen monoxide gas is performed, an organic substance on the surface of the insulating layer 103 can be favorably removed. It is preferable that the metal oxide film 108f be deposited successively after such treatment, without exposure of the surface of the insulating layer 103 to the air.

Note that in the case where the semiconductor layer 108 has a stacked-layer structure in which a plurality of semiconductor layers are stacked, an upper metal oxide film is preferably formed successively after formation of a lower metal oxide film without exposure of the surface of the lower metal oxide layer to the air.

Next, the metal oxide film 108f is partly etched, so that the island-shaped semiconductor layer 108 is formed (FIG. 8C).

For processing of the metal oxide film 108f, either one or both of a wet etching method and a dry etching method are used. At this time, part of the insulating layer 103 that does not overlap with the semiconductor layer 108 is etched and thinned in some cases. For example, in some cases, the insulating layer 103d of the insulating layer 103 is removed by etching and the surface of the insulating layer 103c is exposed.

Here, it is preferable that heat treatment be performed after the metal oxide film 108f is formed or processed into the semiconductor layer 108. By the heat treatment, hydrogen or water contained in the metal oxide film 108f or the semiconductor layer 108 or adsorbed on the surface of the metal oxide film 108f or the semiconductor layer 108 can be removed. Furthermore, the film quality of the metal oxide film 108f or the semiconductor layer 108 is improved (e.g., the number of defects is reduced or crystallinity is increased) by the heat treatment in some cases.

Furthermore, oxygen can be supplied from the insulating layer 103 to the metal oxide film 108f or the semiconductor layer 108 by heat treatment. At this time, it is further preferable that the heat treatment be performed before the semiconductor film 108f is processed into the semiconductor layer 108.

The temperature of the heat treatment can be typically higher than or equal to 150° C. and lower than the strain point of the substrate, higher than or equal to 200° C. and lower than or equal to 500° C., higher than or equal to 250° C. and lower than or equal to 450° C., or higher than or equal to 300° C. and lower than or equal to 450° C.

The heat treatment can be performed in an atmosphere containing a rare gas or nitrogen. Alternatively, the heat treatment may be performed in the atmosphere, and then the heat treatment may be performed in an oxygen-containing atmosphere. Alternatively, the heat treatment may be performed in a dry air atmosphere. It is preferable that the atmosphere of the above heat treatment contain hydrogen, water, or the like as little as possible. An electric furnace, an RTA (Rapid Thermal Anneal) apparatus, or the like can be used for the heat treatment. The use of the RTA apparatus can shorten the heat treatment time.

Note that the heat treatment is not necessarily performed. The heat treatment is not performed in this step, and instead heat treatment performed in a later step may also serve as the heat treatment in this step. In some cases, treatment at a high temperature (e.g., film formation step) or the like in a later step can serve as the heat treatment in this step.

### [Formation of Insulating Layer 110]

Next, the insulating layer 110 is formed to cover the insulating layer 103 and the semiconductor layer 108 (FIG. 8D).

In particular, each of the insulating layers included in the insulating layer 110 is preferably formed by a PECVD method. For the method for forming each of the insulating layers included in the insulating layer 110, the description in Structure Example 1 can be referred to.

It is preferable to perform plasma treatment on a surface of the semiconductor layer 108 before formation of the gate insulating layer 110. By the plasma treatment, an impurity adsorbed onto the surface of the semiconductor layer 108, such as water, can be removed. Therefore, impurities at the interface between the semiconductor layer 108 and the insulating layer 110 can be reduced, enabling the transistor to have high reliability. Performing the plasma treatment in this manner is particularly favorable in the case where the surface of the semiconductor layer 108 is exposed to the air after the formation of the semiconductor layer 108 and before the formation of the gate insulating layer 110. For example, plasma treatment can be performed in an atmosphere containing oxygen, ozone, nitrogen, dinitrogen monoxide, argon, or the like. The plasma treatment and the formation of the insulating layer 110 are preferably performed successively without exposure to the air.

After the insulating layer 110 is formed, heat treatment is preferably performed. By the heat treatment, hydrogen or water contained in the insulating layer 110 or adsorbed on its surface can be removed. At the same time, the number of defects in the insulating layer 110 can be reduced.

The above description can be referred to for the conditions of the heat treatment.

Note that the heat treatment is not necessarily performed. The heat treatment is not performed in this step, and instead heat treatment performed in a later step may also serve as the heat treatment in this step. In some cases, treatment at a high temperature (e.g., film formation step) or the like in a later step can serve as the heat treatment in this step.

[Formation of Metal Oxide Film 114f]

Next, a metal oxide film 114f is formed over the insulating layer 110 (FIG. 8E).

The metal oxide film 114f is preferably formed in an oxygen-containing atmosphere, for example. It is particularly preferable that the metal oxide film 114f be deposited by a sputtering method in an oxygen-containing atmosphere. In that case, oxygen can be supplied to the insulating layer 110 at the time of forming the metal oxide film 114f.

In the case where the metal oxide film 114f is deposited by a sputtering method using an oxide target including a metal oxide similar to that in the case of the semiconductor layer 108, reference can be made to the above description.

For example, as deposition conditions of the metal oxide film 114f, a metal oxide film may be formed by a reactive sputtering method with a metal target using oxygen as a deposition gas. When aluminum is used for the metal target, for example, an aluminum oxide film can be deposited.

The larger the thickness of the metal oxide film 114f is, the smaller the width L2 of the region 108L can be when the metal oxide layer 114 is formed in a later step. The smaller the thickness of the metal oxide film 114f is, the larger the width L2 of the region 108L can be when the metal oxide layer 114 is formed in a later step. Accordingly, by adjusting the thickness of the metal oxide film 114f, the width L2 of the region 108L can be controlled.

By adjusting the deposition conditions of the metal oxide film 114f, the width L2 of the region 108L can be controlled. For example, as the pressure in a deposition chamber of a deposition apparatus at the time of depositing the metal oxide film 114f is set to low, the crystallinity of the metal oxide film 114f is increased, and the width L2 of the region 108L can be reduced when the metal oxide layer 114 is formed in a later step. As the pressure in the deposition chamber is set to high, the crystallinity of the metal oxide film 114f is reduced, and the width L2 of the region 108L can be increased when the metal oxide layer 114 is formed in a later step. As described above, the pressure in the deposition chamber at the time of depositing the metal oxide film 114f is adjusted, whereby the width L2 of the region 108L can be controlled.

As the power supply at the time of depositing the metal oxide film 114f is set to high, the crystallinity of the metal oxide film 114f is increased, and the width L2 of the region 108L can be reduced when the metal oxide layer 114 is formed in a later step. As the power supply is set to low, the crystallinity of the metal oxide film 114f is reduced, and the width L2 of the region 108L can be increased when the metal oxide layer 114 is formed in a later step. By adjusting the power supply at the time of depositing the metal oxide film 114f as described above, the width L2 of the region 108L can be controlled.

As the substrate temperature at the time of depositing the metal oxide film 114f is set to high, the crystallinity of the metal oxide film 114f is increased, and the width L2 of the region 108L can be reduced when the metal oxide layer 114 is formed in a later step. As the substrate temperature is set to low, the crystallinity of the metal oxide film 114f is reduced, and the width L2 of the region 108L can be increased when the metal oxide layer 114 is formed in a later step. By adjusting the substrate temperature at the time of depositing the metal oxide film 114f as described above, the width L2 of the region 108L can be controlled.

When an oxide material containing one or more elements that are also contained in the oxide film 108 is used as the metal oxide layer 114, it is preferable that the substrate temperature at the time of depositing the metal oxide film 108f be equal to the substrate temperature at the time of depositing the metal oxide film 114f In this case, the metal oxide film 114f is preferably a metal oxide film formed using the same sputtering target and at the same substrate temperature as those for the metal oxide film 108f because the same apparatus can be used.

As the proportion of the oxygen flow rate with respect to the total flow rate of the deposition gas (oxygen flow rate ratio) introduced into the deposition chamber of the deposition apparatus or the oxygen partial pressure in the deposition chamber is set to high at the time of depositing the metal oxide film 114f, the crystallinity of the metal oxide film 114f is increased, and the width L2 of the region 108L can be reduced when the metal oxide layer 114 is formed in a later step. As the oxygen flow rate ratio in the deposition chamber or the oxygen partial pressure in the deposition chamber is set to low, the crystallinity of the metal oxide film 114f is reduced, and the width L2 of the region 108L can be increased when the metal oxide layer 114 is formed in a later step. By adjusting the oxygen flow rate ratio in the deposition chamber or the oxygen partial pressure in the deposition chamber at the time of depositing the metal oxide film 114f as described above, the width L2 of the region 108L can be controlled.

Note that a higher proportion of the oxygen flow rate to the total flow rate of the deposition gas (oxygen flow rate ratio) introduced into the deposition chamber of the deposition apparatus or a higher oxygen partial pressure in the deposition chamber is preferable because the amount of oxygen supplied into the insulating layer 110 can be increased at the time of depositing the metal oxide film 114f The oxygen flow rate ratio or the oxygen partial pressure is, for example, higher than 0% and lower than or equal to 100%, preferably higher than or equal to 10% and lower than or equal to 100%, further preferably higher than or equal to 20% and lower than or equal to 100%, still further preferably higher than or equal to 30% and lower than or equal to 100%, and still further preferably higher than or equal to 40% and lower than or equal to 100%. It is particularly preferable that the oxygen flow rate ratio be 100% and the oxygen partial pressure be as close to 100% as possible.

When the metal oxide film 114f is deposited by a sputtering method in an oxygen-containing atmosphere in the above manner, oxygen can be supplied to the insulating layer 110 and release of oxygen from the insulating layer 110 can be prevented during the deposition of the metal oxide film 114f As a result, an extremely large amount of oxygen can be enclosed in the insulating layer 110.

It is preferable to control the width L2 of the region 108L by combining the above-described thickness of the metal oxide film 114f, deposition conditions (such as a pressure), and the like as appropriate.

After the deposition of the metal oxide film 114f, heat treatment is preferably performed. By the heat treatment, oxygen contained in the insulating layer 110 can be supplied to the semiconductor layer 108. When the heat treatment is performed while the metal oxide film 114f covers the insulating layer 110, oxygen can be prevented from being released from the insulating layer 110 to the outside, and a large amount of oxygen can be supplied to the semiconductor layer 108. Thus, the amount of oxygen vacancies in the semiconductor layer 108 can be reduced, leading to a highly reliable transistor.

The above description can be referred to for the conditions of the heat treatment.

Note that the heat treatment is not necessarily performed. The heat treatment is not performed in this step, and instead heat treatment performed in a later step may also serve as the heat treatment in this step. In some cases, treatment at a high temperature (e.g., film formation Step) or the Like in a Later Step can Serve as the Heat Treatment in this Step.

[Formation of Opening 142 and Conductive Film 112f]

Next, parts of the metal oxide film 114f, the insulating layer 110, and the insulating layer 103 are etched to form the opening 142 reaching the conductive layer 106. Accordingly, the conductive layer 112 to be formed later can be electrically connected to the conductive layer 106 through the opening 142.

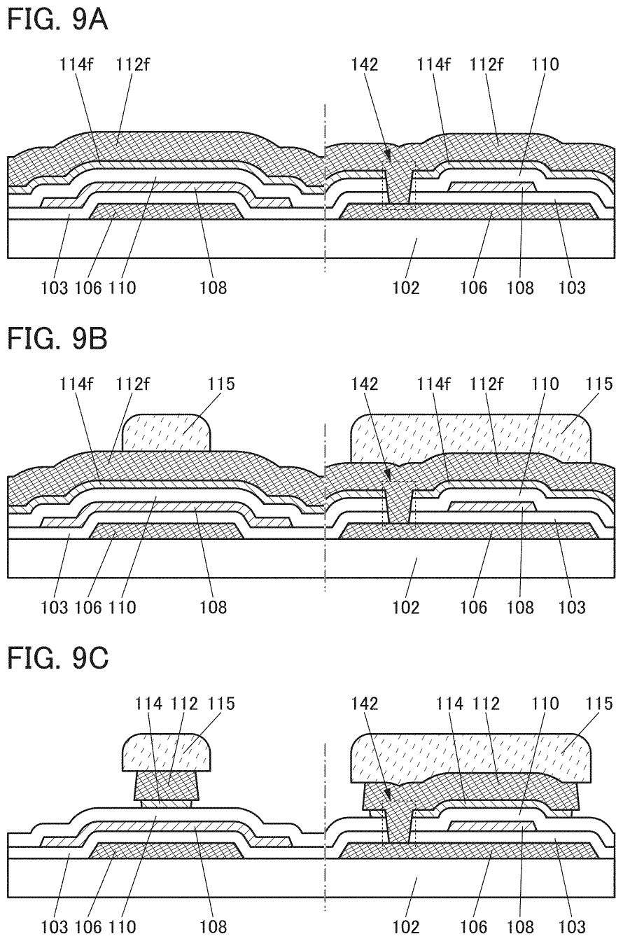

Next, a conductive film 112f that is to be the conductive layer 112 is formed over the metal oxide film 114f (FIG. 9A).

A low-resistance metal or alloy material is preferably used for the conductive film 112f. It is preferable that the conductive film 112f be formed using a material from which hydrogen is less likely to be released and in which hydrogen is less likely to be diffused. Furthermore, a material that is less likely to be oxidized is preferably used for the conductive film 112f

For example, the conductive film 112f is preferably deposited by a sputtering method using a sputtering target containing a metal or an alloy.

For example, the conductive film 112f is preferably a stacked-layer film including a low-resistance conductive film and a conductive film which is less likely to be oxidized and in which hydrogen is less likely to be diffused.

### [Formation of Conductive Layer 112 and Metal Oxide Layer 114: 1]

Next, a resist mask 115 is formed over the conductive film 112f (FIG. 9B). After that, the conductive film 112f and the metal oxide film 114f that are in a region not covered with the resist mask 115 are removed, so that the conductive layer 112 and the metal oxide layer 114 are formed (FIG. 9C).

A wet etching method can be suitably used for formation of the conductive layer 112 and the metal oxide layer 114. For example, an etchant containing one or more of oxalic acid, phosphoric acid, acetic acid, nitric acid, hydrochloric acid, and sulfuric acid can be used for the wet etching method. In particular, in the case where a material containing copper is used for the conductive layer 112, an etchant containing phosphoric acid, acetic acid, and nitric acid can be suitably used.

The etching rate of the metal oxide layer 114 is higher than that of the conductive layer 112, so that the metal oxide layer 114 and the conductive layer 112 can be formed in the same step. Furthermore, the end portion of the metal oxide layer 114 can be located on the inner side than the end portion of the conductive layer 112. The width L2 of the regions 108L can be controlled by adjustment of the etching time. In addition, the formation in the same step can simplify the process and increase the productivity.

When a wet etching method is used for formation of the conductive layer 112 and the metal oxide layer 114, the end portions of the conductive layer 112 and the metal oxide layer 114 are positioned on the inner side of the outline of the resist mask 115 in some cases as illustrated in FIG. 9C. In that case, the width L1 of the conductive layer 112 is smaller than the width of the resist mask 115; accordingly, it is preferable to increase the width of the resist mask 115 so as to obtain the desired width L1 of the conductive layer 112.

Next, the resist mask 115 is removed.

As described above, the insulating layer 110 is not etched to make such a structure that the top surface and the side surface of the semiconductor layer 108 and the insulating layer 103 are covered, which prevents the semiconductor layer 108 and the insulating layer 103 from being partly etched and thinned in forming the conductive layer 112 or the like.

### [Formation of Conductive Layer 112 and Metal Oxide Layer 114: 2]

A formation method of the conductive layer 112 and the metal oxide layer 114, which is different from that shown in FIG. 9B and FIG. 9C, is described.

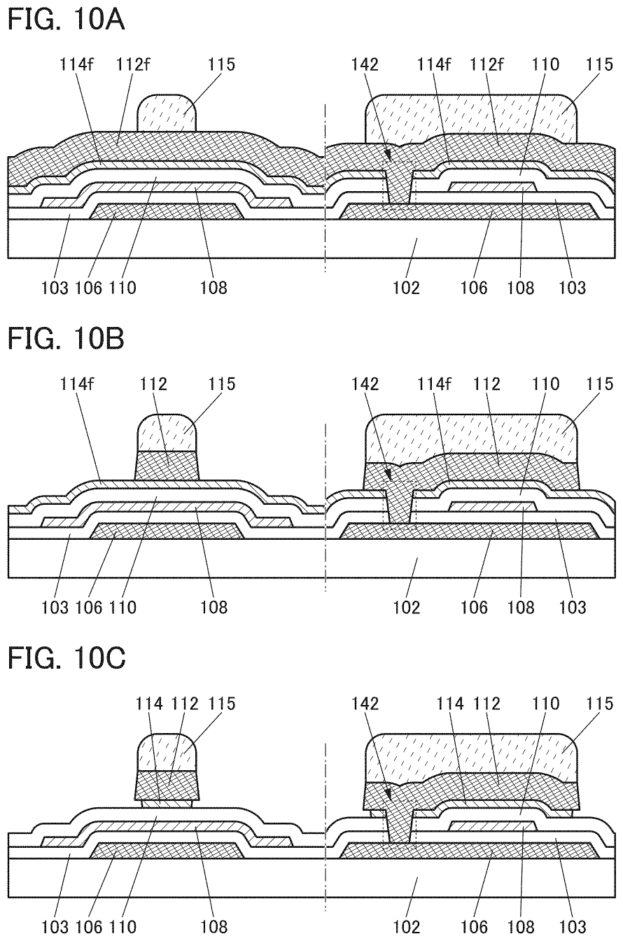

A resist mask 115 is formed over the conductive film 112f (FIG. 10A).

Then, the conductive film 112f is etched by anisotropic etching to form the conductive layer 112 (FIG. 10B). For the anisotropic etching, a dry etching method can be suitably used.

Next, the metal oxide film 114f is etched by wet etching to form the metal oxide layer 114 (FIG. 10C). At this time, the etching time is adjusted so that the end portion of the metal oxide layer 114 is positioned on the inner side than the end portion of the metal oxide layer 112. The width L2 of the regions 108L can be controlled by adjustment of the etching time.

The conductive layer 112 and the metal oxide layer 114 may be formed in the following manner: the conductive film 112f and the metal oxide film 114f are etched by an anisotropic etching method, and then side surfaces of the conductive film 112f and the metal oxide film 114f are etched by an isotropic etching method to make the end surfaces recede (also referred to as side etching). Thus, the metal oxide layer 114 positioned on the inner side than that of the conductive layer 112 in a plan view.

Note that for the formation of the conductive layer 112 and the metal oxide layer 114, etching may be performed at least twice using different etching conditions or methods. For example, the conductive film 112f may be etched first, and then the metal oxide film 114f may be etched under different etching conditions.

In the formation of the conductive layer 112 and the metal oxide layer 114, the thickness of the insulating layer 110 in a region not in contact with the metal oxide layer 114 is reduced in some cases (see FIG. 2A, FIG. 2B, FIG. 3A, and FIG. 3B).

After that, the resist mask 115 is removed.

### [Treatment for Supplying Impurity Element]

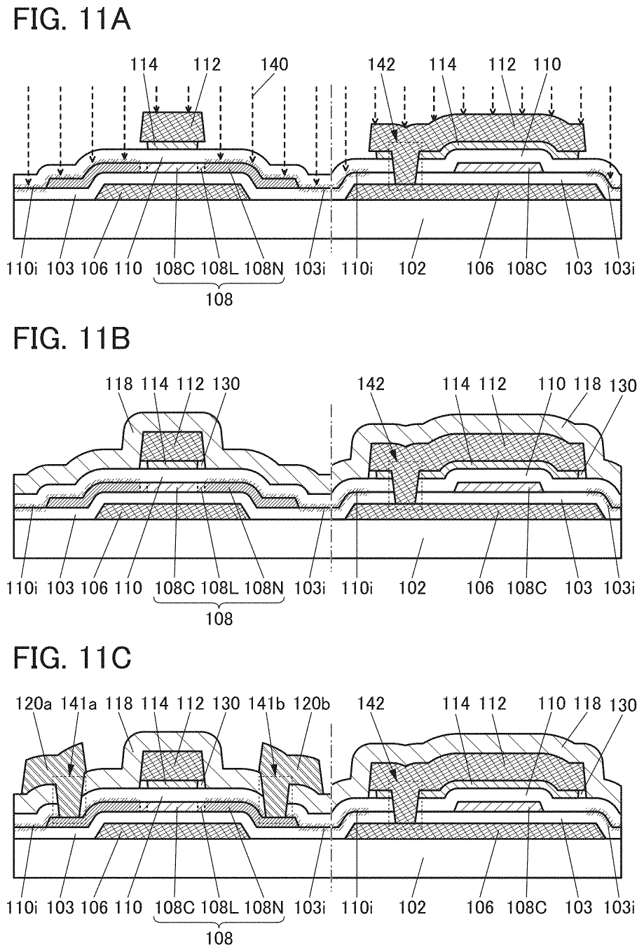

Next, treatment for supplying (adding or injecting) an impurity element 140 to the semiconductor layer 108 through the insulating layer 110 is performed with the use of conductive layer 112 as a mask (FIG. 11A). Thus, the region 108N can be formed in a region of the semiconductor layer 108 that is not covered with the conductive layer 112. At this time, the region of the semiconductor layer 108 overlapping with the conductive layer 112 is not supplied with the impurity element 140 owing to the conductive layer 112 serving as the mask.

A plasma ion doping method or an ion implantation method can be suitably used for the supply of the impurity element 140. In these methods, the concentration profile in the depth direction can be controlled with high accuracy by the acceleration voltage and the dosage of ions, or the like. The use of a plasma ion doping method can increase productivity. In addition, the use of an ion implantation method with mass separation can increase the purity of an impurity element to be supplied.

In the treatment for supplying the impurity element 140, treatment conditions are preferably controlled such that the concentration is the highest at an interface between the semiconductor layer 108 and the insulating layer 110, a portion in the semiconductor layer 108 near the interface, or a portion in the insulating layer 110 near the interface. Accordingly, the impurity element 140 at an optimal concentration can be supplied to both the semiconductor layer 108 and the insulating layer 110 in one treatment.

Examples of the impurity element 140 include hydrogen, boron, carbon, nitrogen, fluorine, phosphorus, sulfur, arsenic, aluminum, magnesium, silicon, and a rare gas. Note that typical examples of a rare gas include helium, neon, argon, krypton, and xenon. It is particularly preferable to use boron, phosphorus, aluminum, magnesium, or silicon.

As a source gas of the impurity element 140, a gas containing any of the above impurity elements can be used. In the case where boron is supplied, typically, a B₂H₆ gas, a BF₃ gas, or the like can be used. In the case where phosphorus is supplied, typically, a PH₃ gas can be used. A mixed gas in which any of these source gases is diluted with a rare gas may be used.

Besides, any of CH₄, N₂, NH₃, AlH₃, AlC₁₃, SiH₄, Si₂H₆, F₂, HF, H₂, (C₅H₅)₂Mg, a rare gas, and the like can be used as the source gas. An ion source is not limited to a gas, and a solid or a liquid that is vaporized by heating may be used.

Addition of the impurity element 140 can be controlled by setting the conditions such as the acceleration voltage and the dosage in consideration of the compositions, densities, thicknesses, and the like of the insulating layer 110 and the semiconductor layer 108.

For example, in the case where boron is added by an ion implantation method or a plasma ion doping method, the acceleration voltage can be, for example, higher than or equal to 5 kV and lower than or equal to 100 kV, preferably higher than or equal to 7 kV and lower than or equal to 70 kV, further preferably higher than or equal to 10 kV and lower than or equal to 50 kV. The dosage can be, for example, greater than or equal to 1×10¹³ ions/cm² and less than or equal to 1×10¹⁷ ions/cm², preferably greater than or equal to 1×10¹⁴ ions/cm² and less than or equal to 5×10¹⁶ ions/cm², further preferably greater than or equal to 1×10¹⁵ ions/cm² and less than or equal to 3×10¹⁶ ions/cm².

In the case where phosphorus ions are added by an ion implantation method or a plasma ion doping method, the acceleration voltage can be, for example, higher than or equal to 10 kV and lower than or equal to 100 kV, preferably higher than or equal to 30 kV and lower than or equal to 90 kV, further preferably higher than or equal to 40 kV and lower than or equal to 80 kV. The dosage can be, for example, greater than or equal to 1×10¹³ ions/cm² and less than or equal to 1×10¹⁷ ions/cm², preferably greater than or equal to 1×10¹⁴ ions/cm² and less than or equal to 5×10¹⁶ ions/cm², further preferably greater than or equal to 1×10¹⁵ ions/cm² and less than or equal to 3×10¹⁶ ions/cm².

Note that a method for supplying the impurity element 140 is not limited thereto; plasma treatment, treatment using thermal diffusion by heating, or the like may be used, for example. In a plasma treatment method, plasma is generated in a gas atmosphere containing an impurity element to be added and plasma treatment is performed, so that the impurity element can be added. A dry etching apparatus, an ashing apparatus, a plasma CVD apparatus, a high-density plasma CVD apparatus, or the like can be used as an apparatus for generating the plasma.

In one embodiment of the present invention, the impurity element 140 can be supplied to the semiconductor layer 108 through the insulating layer 110. Thus, even in the case where the semiconductor layer 108 has crystallinity, damage on the semiconductor layer 108 is reduced at the time of supplying the impurity element 140, and degradation of crystallinity can be inhibited. Therefore, this is suitable for the case where a reduction in crystallinity increases electrical resistance.

### [Formation of Insulating Layer 118]

Next, the insulating layer 118 is formed to cover the insulating layer 110, the metal oxide layer 114, and the conductive layer 112 (FIG. 11B).

In the case where the insulating layer 118 is formed by a plasma CVD method at a deposition temperature too high, the impurity included in the region 108N and the like might diffuse into a peripheral portion including the channel formation region of the semiconductor layer 108 or might increase the electrical resistance of the region 108N. Thus, the film formation temperature of the insulating layer 118 may be determined in consideration of these.

The film formation temperature of the insulating layer 118 is preferably higher than or equal to 150° C. and lower than or equal to 400° C., further preferably higher than or equal to 180° C. and lower than or equal to 360° C., still further preferably higher than or equal to 200° C. and lower than or equal to 250° C., for example. Formation of the insulating layer 118 at low temperatures enables the transistor to have favorable electrical characteristics even when it has a short channel length.

Heat treatment may be performed after the formation of the insulating layer 118. The region 108N that has low resistance more stably can be formed by the heat treatment, in some times. For example, by the heat treatment, the impurity element 140 diffuses moderately and homogenized locally, so that the region 108N having an ideal concentration gradient of the impurity element can be formed. Note that when the temperature of the heat treatment is too high (e.g., higher than or equal to 500° C.), the impurity element 140 is also diffused into the channel formation region, so that the electrical characteristics or reliability of the transistor might be degraded.

The above description can be referred to for the conditions of the heat treatment.

Note that the heat treatment is not necessarily performed. The heat treatment is not necessarily performed in this step, and heat treatment performed in a later step may also serve as the heat treatment in this step. In the case where treatment at a high temperature is performed in a later step (e.g., film formation step), such treatment can serve as the heat treatment in this step in some cases.

[Formation of Opening 141a and Opening 141b]

Next, the insulating layer 118 and the insulating layer 110 are partly etched, whereby the opening 141a and the opening 141b that reach the regions 108N are formed.

[Formation of Conductive Layer 120a and Conductive Layer 120b]

Next, a conductive film is formed over the insulating layer 118 to cover the opening 141a and the opening 141b, and the conductive film is processed into a desired shape, so that the conductive layer 120a and the conductive layer 120b are formed (FIG. 11C).

Through the above process, the transistor 100A can be manufactured. In the case where the transistor 100A is used in a pixel of a display device, for example, this process may be followed by a step of forming one or more of a protective insulating layer, a planarization layer, a pixel electrode, and a wiring.

The above is the description of the manufacturing method example 1.

Note that in the case of manufacturing the transistor 100 shown in Structure Example 1, the step of forming the conductive layer 106 and the step of forming the opening 142 in the above manufacturing method example are omitted. The transistor 100 and the transistor 100A can be formed over one substrate through the same process.

### <Components of Semiconductor Device>

Components included in the semiconductor device of this embodiment will be described below in detail.

### [Substrate]

Although there is no particular limitation on a material and the like of the substrate 102, it is necessary that the substrate have heat resistance high enough to withstand at least heat treatment performed later. For example, a single crystal semiconductor substrate or a polycrystalline semiconductor substrate containing silicon or silicon carbide as a material, a compound semiconductor substrate of silicon germanium or the like, an SOI substrate, a glass substrate, a ceramic substrate, a quartz substrate, a sapphire substrate, or the like may be used as the substrate 102. Alternatively, any of these substrates over which a semiconductor element is provided may be used as the substrate 102.

A flexible substrate may be used as the substrate 102, and the semiconductor device may be formed directly on the flexible substrate. A separation layer may be provided between the substrate 102 and the semiconductor device. The separation layer can be used when part or the whole of a semiconductor device completed thereover is separated from the substrate 102 and transferred onto another substrate. In that case, the semiconductor device can be transferred to even a substrate having low heat resistance or a flexible substrate.

### [Conductive Film]

The conductive layer 112 and the conductive layer 106 functioning as gate electrodes, the conductive layer 120a functioning as one of a source electrode and a drain electrode, and the conductive layer 120b functioning as the other electrode can each be formed using a metal element selected from chromium, copper, aluminum, gold, silver, zinc, molybdenum, tantalum, titanium, tungsten, manganese, nickel, iron, and cobalt; an alloy containing any of these metal elements as its component; an alloy including a combination of any of these metal elements; or the like.

An oxide conductor or a metal oxide film such as an In—Sn oxide, an In—W oxide, an In—W—Zn oxide, an In—Ti oxide, an In—Ti—Sn oxide, an In—Zn oxide, an In—Sn—Si oxide, or an In-Ga—Zn oxide can also be applied to each of the conductive layer 112, the conductive layer 106, the conductive layer 120a, and the conductive layer 120b.

Here, an oxide conductor (OC) is described. For example, when oxygen vacancies are formed in a metal oxide having semiconductor characteristics and hydrogen is added to the oxygen vacancies, a donor level is formed in the vicinity of the conduction band. As a result, the conductivity of the metal oxide is increased, so that the metal oxide becomes a conductor. The metal oxide having become a conductor can be referred to as an oxide conductor.

In addition, the conductive layer 112 or the like may have a stacked-layer structure of a conductive film containing the oxide conductor (the metal oxide) and a conductive film containing a metal or an alloy. The use of the conductive film containing a metal or an alloy can reduce the wiring resistance. At this time, a conductive film containing an oxide conductor is preferably used as a conductive film on the side in contact with an insulating layer functioning as a gate insulating film.

Furthermore, among the above metal elements, it is particularly preferable that any one or more metal elements selected from titanium, tungsten, tantalum, and molybdenum be included in the conductive layer 112, the conductive layer 106, the conductive layer 120a, and the conductive layer 120b. It is particularly preferable to use a tantalum nitride film. The tantalum nitride film has conductivity and a high barrier property against copper, oxygen, or hydrogen and releases little hydrogen from itself; thus, the tantalum nitride film can be suitably used as a conductive film in contact with the semiconductor layer 108 or a conductive film near the semiconductor layer 108.

### [Semiconductor Layer]

The semiconductor layer 108 preferably includes a metal oxide.

The semiconductor layer 108 preferably contains indium, M (M is one kind or a plurality of kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. In particular, M is preferably one kind or a plurality of kinds selected from aluminum, gallium, yttrium, and tin.

In the case where the semiconductor layer 108 is an In—M-Zn oxide, examples of the atomic ratio of metal elements of a sputtering target for forming a film of an In-M-Zn oxide are In:M:Zn=1:1:1, InM:Zn=1:1:1.2, In:M:Zn=1:3:2, In:M:Zn=1:3:4, In:M:Zn=1:3:6, In:M:Zn=2:2:1, In:M:Zn=2:1:3, In:M:Zn=3:1:2, In:M:Zn=4:2:3, In:M:Zn=4:2:4.1, In:M:Zn=5:1:6, In:M:Zn=5:1:7, In:M:Zn=5:1:8, In:M:Zn=6:1:6, In:M:Zn=5:2:5, and the like.

A target containing a polycrystalline oxide is preferably used as the sputtering target, in which case the semiconductor layer 108 having crystallinity is easily formed. Note that the atomic ratio in the semiconductor layer 108 to be deposited varies in the range of ±40% from any of the above atomic ratios of the metal elements contained in the sputtering target. For example, in the case where the composition of a sputtering target used for the semiconductor layer 108 is In:Ga:Zn=4:2:4.1 [atomic ratio], the composition of the semiconductor layer 108 to be deposited is sometimes in the neighborhood of In:Ga:Zn=4:2:3 [atomic ratio].

Note that when the atomic ratio is described as In:Ga:Zn=4:2:3 or as being in the neighborhood thereof, the case is included where Ga is greater than or equal to 1 and less than or equal to 3 and Zn is greater than or equal to 2 and less than or equal to 4 with In being 4. In addition, when the atomic ratio is described as In:Ga:Zn=5:1:6 or as being in the neighborhood thereof, the case is included where Ga is greater than 0.1 and less than or equal to 2 and Zn is greater than or equal to 5 and less than or equal to 7 with In being 5. Furthermore, when the atomic ratio is described as In:Ga:Zn=1:1:1 or as being in the neighborhood thereof, the case is included where Ga is greater than 0.1 and less than or equal to 2 and Zn is greater than 0.1 and less than or equal to 2 with In being 1.

The energy gap of the semiconductor layer 108 is greater than or equal to 2 eV, preferably greater than or equal to 2.5 eV. With use of such a metal oxide having a wider energy gap than silicon, the off-state current of the transistor can be reduced.

A metal oxide with a low carrier concentration is preferably used for the semiconductor layer 108. In order to reduce the carrier concentration of the metal oxide, the concentration of impurities in the metal oxide is reduced so that the density of defect states can be reduced. In this specification and the like, a state with a low impurity concentration and a low density of defect states is referred to as a highly purified intrinsic or substantially highly purified intrinsic state. Examples of impurities in the metal oxide include hydrogen, nitrogen, alkali metal, alkaline earth metal, iron, nickel, and silicon.

In particular, hydrogen contained in the metal oxide reacts with oxygen bonded to a metal atom to be water, and thus forms oxygen vacancies in the metal oxide in some cases. If the channel formation region in the metal oxide includes oxygen vacancies, the transistor sometimes has normally-on characteristics. In some cases, a defect that is an oxygen vacancy into which hydrogen enters functions as a donor and generates an electron serving as a carrier. In other cases, bonding of part of hydrogen to oxygen bonded to a metal atom generates electrons serving as carriers. Thus, a transistor using a metal oxide containing a large amount of hydrogen is likely to have normally-on characteristics.

A defect in which hydrogen has entered an oxygen vacancy can function as a donor of the metal oxide. However, it is difficult to evaluate the defects quantitatively. Thus, the metal oxide is sometimes evaluated by not its donor concentration but its carrier concentration. Therefore, in this specification and the like, the carrier concentration assuming the state where an electric field is not applied is sometimes used, instead of the donor concentration, as the parameter of the metal oxide. That is, “carrier concentration” in this specification and the like can be replaced with “donor concentration” in some cases.

Therefore, hydrogen in the metal oxide is preferably reduced as much as possible. Specifically, the hydrogen concentration of the metal oxide, which is measured by secondary ion mass spectrometry (SIMS), is lower than 1×10²⁰ atoms/cm³, preferably lower than 1×10¹⁹ atoms/cm³, further preferably lower than 5×10¹⁸ atoms/cm³, still further preferably lower than 1×10¹⁸ atoms/cm³. When a metal oxide with a sufficiently low concentration of impurities such as hydrogen is used for a channel formation region of a transistor, the transistor can have stable electrical characteristics.

The carrier concentration of the metal oxide in the channel formation region is preferably lower than or equal to 1×10¹⁸ cm⁻³, further preferably lower than 1×10¹⁷ cm⁻³, still further preferably lower than 1×10¹⁶ cm⁻³, yet further preferably lower than 1×10¹³ cm⁻³, yet still further preferably lower than 1×10¹² cm⁻³. Note that the lower limit of the carrier concentration of the metal oxide in the channel formation region is not particularly limited and can be, for example, 1×10⁻⁹ cm⁻³.

The semiconductor layer 108 preferably has a non-single-crystal structure. Examples of the non-single-crystal structure include a CAAC structure to be described later, a polycrystalline structure, a microcrystalline structure, and an amorphous structure. Among the non-single-crystal structures, the amorphous structure has the highest density of defect states, whereas the CAAC structure has the lowest density of defect states.

A CAAC (c-axis aligned crystal) will be described below. A CAAC refers to an example of a crystal structure.

The CAAC structure is a crystal structure of a thin film or the like that has a plurality of nanocrystals (crystal regions having a maximum diameter of less than 10 nm), characterized in that the nanocrystals have c-axis alignment in a particular direction and are not aligned but continuously connected in the a-axis and b-axis directions without forming a grain boundary. In particular, a thin film having the CAAC structure is characterized in that the c-axes of nanocrystals are likely to be aligned in a film thickness direction, a normal direction of a surface where the thin film is formed, or a normal direction of a surface of the thin film.

A CAAC-OS (Oxide Semiconductor) is an oxide semiconductor with high crystallinity. By contrast, in the CAAC-OS, it can be said that a reduction in electron mobility due to the crystal grain boundary is less likely to occur because a clear crystal grain boundary cannot be observed. Moreover, since the crystallinity of an oxide semiconductor might be decreased by entry of impurities, formation of defects, or the like, the CAAC-OS can be regarded as an oxide semiconductor that has small amounts of impurities and defects (oxygen vacancies or the like). Thus, an oxide semiconductor including a CAAC-OS is physically stable. Therefore, the oxide semiconductor including the CAAC-OS is resistant to heat and has high reliability.

Here, in crystallography, in a unit cell formed with three axes (crystal axes) of the a-axis, the b-axis, and the c-axis, a specific axis is generally taken as the c-axis. In particular, in the case of a crystal having a layered structure, two axes parallel to the plane direction of a layer are regarded as the a-axis and the b-axis and an axis intersecting with the layer is regarded as the c-axis in general. Typical examples of such a crystal having a layered structure include graphite, which is classified as a hexagonal system. In a unit cell of graphite, the a-axis and the b-axis are parallel to a cleavage plane and the c-axis is orthogonal to the cleavage plane. For example, an InGaZnO₄ crystal having a YbFe₂O₄ type crystal structure, which is a layered structure, can be classified as a hexagonal system, and in a unit cell thereof, the a-axis and the b-axis are parallel to the plane direction of a layer and the c-axis is orthogonal to the layer (i.e., the a-axis and the b-axis).

In an image observed with a TEM, crystal parts cannot be found clearly in an oxide semiconductor film having a microcrystalline structure (a microcrystalline oxide semiconductor film) in some cases. In most cases, the size of a crystal part included in the microcrystalline oxide semiconductor film is greater than or equal to 1 nm and less than or equal to 100 nm, or greater than or equal to 1 nm and less than or equal to 10 nm. In particular, an oxide semiconductor film including a nanocrystal (nc) that is a microcrystal with a size greater than or equal to 1 nm and less than or equal to 10 nm, or greater than or equal to 1 nm and less than or equal to 3 nm is referred to as an nc-OS (nanocrystalline Oxide Semiconductor) film. In an image observed with a TEM, for example, a crystal grain boundary cannot be found clearly in the nc-OS film in some cases.

In the nc-OS film, a microscopic region (for example, a region with a size greater than or equal to 1 nm and less than or equal to 10 nm, in particular, a region with a size greater than or equal to 1 nm and less than or equal to 3 nm) has a periodic atomic arrangement. Furthermore, there is no regularity of crystal orientation between different crystal parts in the nc-OS film. Thus, the orientation in the whole film is not observed. Accordingly, in some cases, the nc-OS film cannot be distinguished from an amorphous oxide semiconductor film depending on an analysis method. For example, when the nc-OS film is subjected to structural analysis by an out-of-plane method with an XRD apparatus using an X-ray having a diameter larger than the size of a crystal part, a peak that shows a crystal plane does not appear. Furthermore, a diffraction pattern like a halo pattern is observed when the nc-OS film is subjected to electron diffraction (also referred to as selected-area electron diffraction) using an electron beam with a probe diameter (e.g., 50 nm or larger) that is larger than the size of a crystal part. Meanwhile, in some cases, a circular (ring-like) region with high luminance is observed in an electron diffraction pattern (also referred to as nanobeam electron diffraction pattern) of the nc-OS film, which is obtained using an electron beam with a probe diameter close to or smaller than the diameter of a crystal part (e.g., 1 nm or larger and 30 nm or smaller), and spots are observed in the ring-like region.

The nc-OS film has a lower density of defect states than an amorphous oxide semiconductor film. Note that there is no regularity of crystal orientation between different crystal parts in the nc-OS film. Thus, the nc-OS film has a higher density of defect states than the CAAC-OS film. Thus, the nc-OS film has a higher carrier density and higher electron mobility than the CAAC-OS film in some cases. Therefore, a transistor using the nc-OS film may have high field-effect mobility.

The nc-OS film can be formed at a smaller oxygen flow rate ratio in formation than the CAAC-OS film. The nc-OS film can also be formed at a lower substrate temperature in formation than the CAAC-OS film. For example, the nc-OS film can be formed at a relatively low substrate temperature (e.g., a temperature of 130° C. or lower) or without heating of the substrate and thus is suitable for the case of using a large glass substrate, a resin substrate, or the like, and productivity can be increased.

An example of a crystal structure of a metal oxide is described. A metal oxide that is formed by a sputtering method using an In-Ga—Zn oxide target (In:Ga:Zn=4:2:4.1 [atomic ratio]) at a substrate temperature higher than or equal to 100° C. and lower than or equal to 130° C. is likely to have either the nc (nano crystal) structure or the CAAC structure, or a structure in which both structures are mixed. By contrast, a metal oxide formed at a substrate temperature set at room temperature (R.T.) is likely to have the nc structure. Note that room temperature (R.T.) here also includes a temperature in the case where a substrate is not heated.

### [Composition of Metal Oxide]

The composition of a CAC (Cloud-Aligned Composite)-OS that can be used in a transistor disclosed in one embodiment of the present invention will be described below.

Note that a CAAC (c-axis aligned crystal) refers to an example of a crystal structure, and a CAC (Cloud-Aligned Composite) refers to an example of a function or a material composition.

A CAC-OS or a CAC-metal oxide has a conducting function in a part of the material and an insulating function in another part of the material, and has a function of a semiconductor as the whole material. Note that in the case where the CAC-OS or the CAC-metal oxide is used in an active layer of a transistor, the conducting function is a function that allows electrons (or holes) serving as carriers to flow, and the insulating function is a function that does not allow electrons serving as carriers to flow. By the complementary action of the conducting function and the insulating function, a switching function (On/Off function) can be given to the CAC-OS or the CAC-metal oxide. In the CAC-OS or the CAC-metal oxide, separation of the functions can maximize each function.

The CAC-OS or the CAC-metal oxide includes conductive regions and insulating regions. The conductive regions have the above-described conducting function, and the insulating regions have the above-described insulating function. Furthermore, in some cases, the conductive regions and the insulating regions in the material are separated at the nanoparticle level. Furthermore, in some cases, the conductive regions and the insulating regions are unevenly distributed in the material. Furthermore, in some cases, the conductive regions are observed to be coupled in a cloud-like manner with their boundaries blurred.

In the CAC-OS or the CAC-metal oxide, the conductive regions and the insulating regions each have a size greater than or equal to 0.5 nm and less than or equal to 10 nm, preferably greater than or equal to 0.5 nm and less than or equal to 3 nm, and are dispersed in the material, in some cases.

The CAC-OS or the CAC-metal oxide includes components having different band gaps. For example, the CAC-OS or the CAC-metal oxide is composed of a component having a wide gap due to the insulating region and a component having a narrow gap due to the conductive region. In the case of the structure, when carriers flow, carriers mainly flow in the component having a narrow gap. Furthermore, the component having a narrow gap complements the component having a wide gap, and carriers also flow in the component having a wide gap in conjunction with the component having a narrow gap. Therefore, in the case where the above-described CAC-OS or CAC-metal oxide is used in a channel formation region of a transistor, the transistor in an on state can achieve high current driving capability, that is, high on-state current and high field-effect mobility.

In other words, the CAC-OS or the CAC-metal oxide can also be referred to as a matrix composite or a metal matrix composite.

The above is the description of the metal oxide structure.

At least part of the structure examples, the drawings corresponding thereto, and the like exemplified in this embodiment can be implemented in combination with the other structure examples, the other drawings, and the like as appropriate.

At least part of this embodiment can be implemented in combination with the other embodiments described in this specification as appropriate.

### Embodiment 2

In this embodiment, an example of a display device that includes the transistor described in the above embodiment will be described.

### <Structure Example>

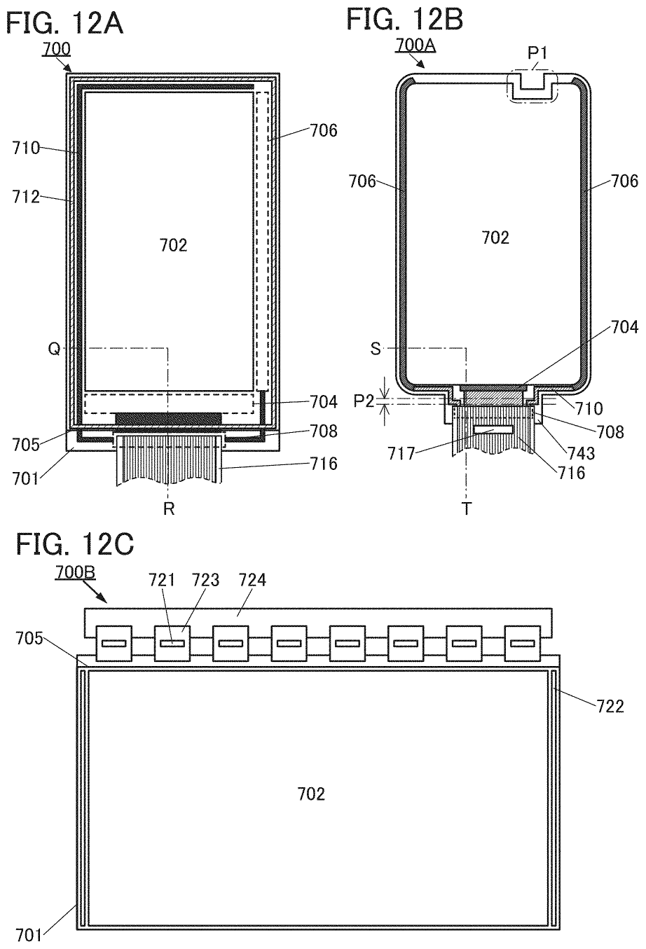

FIG. 12A is a top view of a display device 700. The display device 700 includes a first substrate 701 and a second substrate 705 that are attached to each other with a sealant 712. In a region sealed with the first substrate 701, the second substrate 705, and the sealant 712, a pixel portion 702, a source driver circuit portion 704, and a gate driver circuit portion 706 are provided over the first substrate 701. In the pixel portion 702, a plurality of display elements are provided.

An FPC terminal portion 708 to which an FPC 716 (FPC: Flexible printed circuit) is connected is provided in a portion of the first substrate 701 that does not overlap with the second substrate 705. The pixel portion 702, the source driver circuit portion 704, and the gate driver circuit portion 706 are each supplied with a variety of signals and the like from the FPC 716 through the FPC terminal portion 708 and a signal line 710.

A plurality of gate driver circuit portions 706 may be provided. The gate driver circuit portion 706 and the source driver circuit portion 704 may be formed separately on semiconductor substrates or the like to obtain packaged IC chips. The IC chip can be mounted over the first substrate 701 or on the FPC 716.

The transistor that is the semiconductor device of one embodiment of the present invention can be used as transistors included in the pixel portion 702, the source driver circuit portion 704, and the gate driver circuit portion 706.

Examples of the display element provided in the pixel portion 702 include a liquid crystal element and a light-emitting element. As the liquid crystal element, a transmissive liquid crystal element, a reflective liquid crystal element, a transflective liquid crystal element, or the like can be used. As the light-emitting element, a self-luminous light-emitting element such as an LED (Light Emitting Diode), an OLED (Organic LED), a QLED (Quantum-dot LED), or a semiconductor laser can be used. It is also possible to use a MEMS (Micro Electro Mechanical Systems) shutter element, an optical interference type MEMS element, or a display element using a microcapsule method, an electrophoretic method, an electrowetting method, an Electronic Liquid Powder (registered trademark) method, or the like, for instance.

A display device 700A illustrated in FIG. 12B is an example of a display device which includes a flexible resin layer 743 instead of the first substrate 701 and can be used as a flexible display.

In the display device 700A, the pixel portion 702 has not a rectangular shape but a shape with rounded corners. The display device 700A includes a notch portion in which part of the pixel portion 702 and part of the resin layer 743 are cut as illustrated in a region P1 in FIG. 12B. A pair of gate driver circuit portions 706 is provided on the opposite sides with the pixel portion 702 therebetween. The gate driver circuit portions 706 are provided along a curved outline at the corners of the pixel portion 702.

The resin layer 743 has a shape with a sticking-out portion where the FPC terminal portion 708 is provided. Furthermore, part of the resin layer 743 that includes the FPC terminal portion 708 can be bent backward in a region P2 in FIG. 12B. When part of the resin layer 743 is bent backward, the display device 700A can be implemented on an electronic device while the FPC 716 overlaps with the back side of the pixel portion 702; thus, the electronic device can be downsized.

The FPC 716 connected to the display device 700A is mounted with an IC 717. The IC 717 functions as a source driver circuit, for example. In this case, the source driver circuit portion 704 in the display device 700A can include at least one of a protection circuit, a buffer circuit, a demultiplexer circuit, and the like.

A display device 700B illustrated in FIG. 12C is a display device that can be suitably used for an electronic device with a large screen. For example, the display device 700B can be suitably used for a television device, a monitor device, a personal computer (including a laptop type and a desktop type), a tablet terminal, digital signage, or the like.

The display device 700B includes a plurality of source driver ICs 721 and a pair of gate driver circuit portions 722.

The plurality of source driver ICs 721 are attached to respective FPCs 723. In each of the plurality of FPCs 723, one of terminals is connected to the first substrate 701, and the other terminal is connected to a printed circuit board 724. By bending the FPCs 723, the printed circuit board 724 can be placed on the back side of the pixel portion 702 so that the display device 700B can be implemented on an electronic device; thus, the electronic device can be downsized.

By contrast, the gate driver circuit portions 722 are provided over the first substrate 701. Thus, an electronic device with a narrow bezel can be provided.

With such a structure, a large-size and high-resolution display device can be provided. For example, a display device with a diagonal screen size of 30 inches or more, 40 inches or more, 50 inches or more, or 60 inches or more can be obtained. Furthermore, a display device with extremely high resolution such as 4K2K or 8K4K can be provided.

### <Cross-Sectional Structure Example>

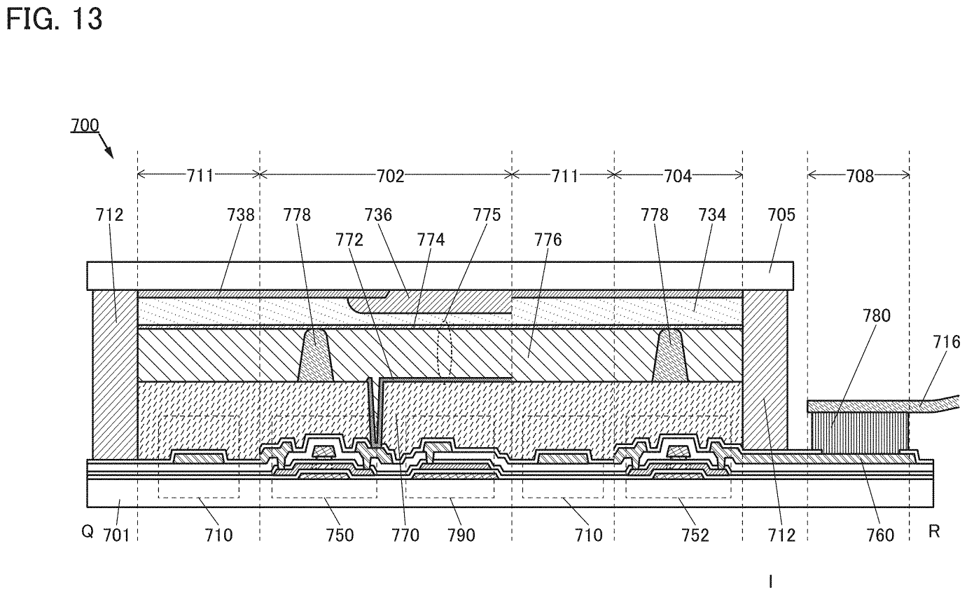

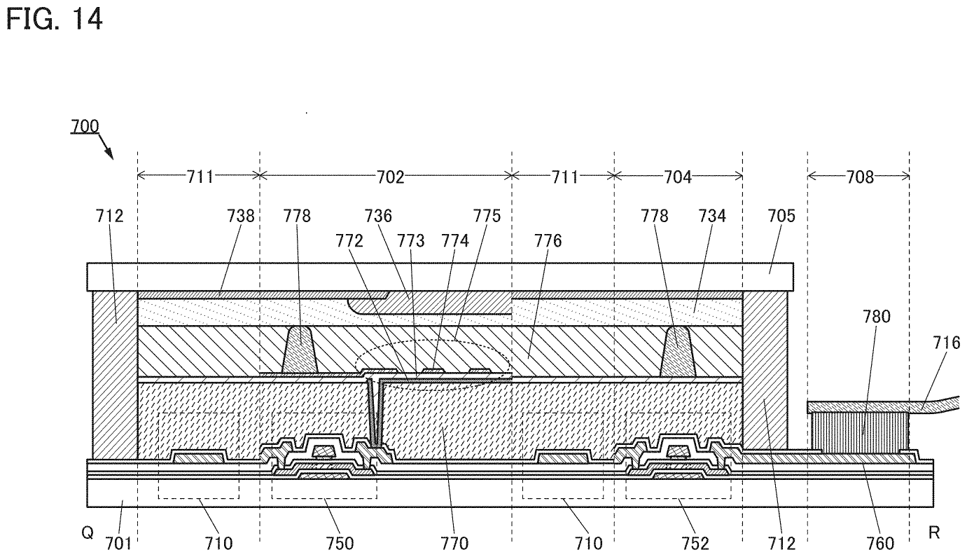

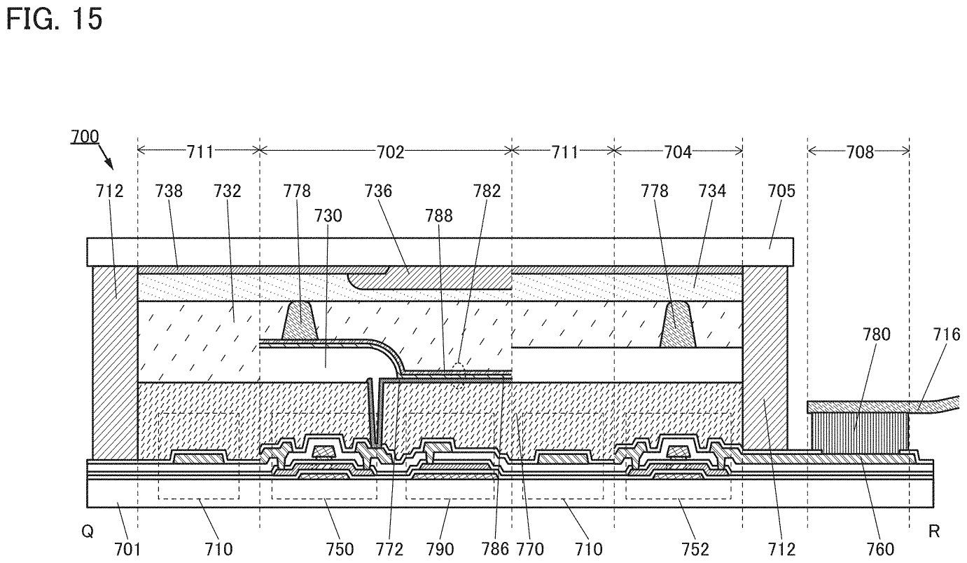

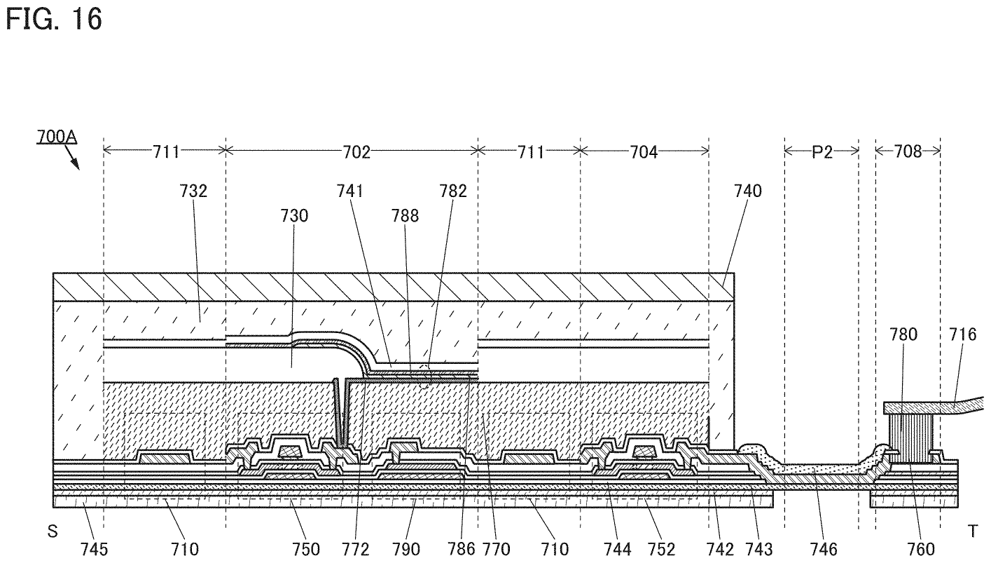

Structures using a liquid crystal element as a display element and structures using an EL element will be described below with reference to FIG. 13 to FIG. 16. Note that FIG. 13 to FIG. 15 are cross-sectional views taken along the dashed-dotted line Q-R in FIG. 12A. FIG. 16 is a cross-sectional view taken along the dashed-dotted line S-T in the display device 700A in FIG. 12B. FIG. 13 and FIG. 14 are each a structure using a liquid crystal element as a display element, and FIG. 15 and FIG. 16 are each a structure using an EL element.

### <Description of Common Portion in Display Device>

Display devices in FIG. 13 to FIG. 16 each include a lead wiring portion 711, the pixel portion 702, the source driver circuit portion 704, and the FPC terminal portion 708. The lead wiring portion 711 includes the signal line 710. The pixel portion 702 includes a transistor 750 and a capacitor 790. The source driver circuit portion 704 includes a transistor 752. FIG. 14 illustrates a case where the capacitor 790 is not provided.

As the transistor 750 and the transistor 752, any of the transistors described in Embodiment 1 can be used.

The transistor used in this embodiment includes a highly purified oxide semiconductor film in which formation of oxygen vacancies is suppressed. The transistor can have low off-state current. Accordingly, an electrical signal such as an image signal can be held for a longer period, and the interval between writes of an image signal or the like can be set longer. Thus, frequency of refresh operation can be reduced, which leads to lower power consumption.

The transistor used in this embodiment can have relatively high field-effect mobility and thus is capable of high-speed operation. For example, with use of such a transistor capable of high-speed operation for a display device, a switching transistor in a pixel portion and a driver transistor used in a driver circuit portion can be formed over one substrate. That is, a structure in which a driver circuit formed using a silicon wafer or the like is not used is possible, in which case the number of components of the display device can be reduced. Moreover, the use of the transistor capable of high-speed operation also in the pixel portion can provide a high-quality image.

The capacitor 790 illustrated in FIG. 13, FIG. 15, and FIG. 16 includes a lower electrode formed by processing the same film as a first gate electrode included in the transistor 750 and an upper electrode formed by processing the same metal oxide as the semiconductor layer. The upper electrode has reduced resistance like a source region and a drain region of the transistor 750. Part of an insulating film functioning as a first gate insulating layer of the transistor 750 is provided between the lower electrode and the upper electrode. That is, the capacitor 790 has a stacked-layer structure in which the insulating films functioning as dielectric films are positioned between a pair of electrodes. A wiring obtained by processing the same film as a source electrode and a drain electrode of the transistor is connected to the upper electrode.

A planarization insulating film 770 is provided over the transistor 750, the transistor 752, and the capacitor 790.

The transistor 750 in the pixel portion 702 and the transistor 752 in the source driver circuit portion 704 may have different structures. For example, a top-gate transistor may be used as one of the transistors 750 and 752, and a bottom-gate transistor may be used as the other. Note that like in the source driver circuit portion 704, a transistor having the same structure as or a different structure from the transistor 750 may be used in the gate driver circuit portion 706.

The signal line 710 is formed using the same conductive film as the source electrodes, the drain electrodes, and the like of the transistor 750 and the transistor 752. In this case, a low-resistance material such as a material containing a copper element is preferably used because signal delay or the like due to the wiring resistance can be reduced and display on a large screen is possible.

The FPC terminal portion 708 includes a wiring 760 part of which functions as a connection electrode, an anisotropic conductive film 780, and the FPC 716. The wiring 760 is electrically connected to a terminal included in the FPC 716 through the anisotropic conductive film 780. Here, the wiring 760 is formed using the same conductive film as the source electrodes, the drain electrodes, and the like of the transistor 750 and the transistor 752.

As the first substrate 701 and the second substrate 705, a glass substrate or a flexible substrate such as a plastic substrate can be used, for example. In the case where a flexible substrate is used as the first substrate 701, an insulating layer having a barrier property against water or hydrogen is preferably provided between the first substrate 701 and the transistor 750, for example.

A light-blocking film 738, a coloring film 736, and an insulating film 734 in contact with these films are provided on the second substrate 705 side.

### <Structure Example of Display Device Using Liquid Crystal Element>

The display device 700 illustrated in FIG. 13 includes a liquid crystal element 775 and a spacer 778. The liquid crystal element 775 includes a conductive layer 772, a conductive layer 774, and a liquid crystal layer 776 therebetween. The conductive layer 774 is provided on the second substrate 705 side and has a function of a common electrode. The conductive layer 772 is electrically connected to the source electrode or the drain electrode of the transistor 750. The conductive layer 772 is formed over the planarization insulating film 770 and functions as a pixel electrode.

A material that transmits visible light or a material that reflects visible light can be used for the conductive layer 772. As a light-transmitting material, for example, an oxide material containing indium, zinc, tin, or the like is preferably used. As a reflective material, for example, a material containing aluminum, silver, or the like is preferably used.

When a reflective material is used for the conductive layer 772, the display device 700 is a reflective liquid crystal display device. When a light-transmitting material is used for the conductive layer 772, a transmissive liquid crystal display device is obtained. For a reflective liquid crystal display device, a polarizing plate is provided on the viewer side. By contrast, for a transmissive liquid crystal display device, a pair of polarizing plates is provided so that the liquid crystal element is placed therebetween.

The display device 700 in FIG. 14 is an example of employing the liquid crystal element 775 of a horizontal electric field mode (e.g., an FFS mode). The conductive layer 774 functioning as a common electrode is provided over the conductive layer 772 with an insulating layer 773 therebetween. The alignment state of the liquid crystal layer 776 can be controlled by the electric field generated between the conductive layer 772 and the conductive layer 774.

In FIG. 14, a storage capacitor can be formed with a stacked-layer structure including the conductive layer 774, the insulating layer 773, and the conductive layer 772. Thus, another capacitor need not be provided, and thus the aperture ratio can be increased.

Although not illustrated in FIG. 13 and FIG. 14, a structure in which an alignment film in contact with the liquid crystal layer 776 is provided may be employed. Furthermore, an optical member (an optical substrate) such as a polarizing member, a retardation member, or an anti-reflection member, and a light source such as a backlight or a sidelight can be provided as appropriate.

For the liquid crystal layer 776, a thermotropic liquid crystal, a low-molecular liquid crystal, a high-molecular liquid crystal, a polymer dispersed liquid crystal (PDLC), a polymer network liquid crystal (PNLC), a ferroelectric liquid crystal, an anti-ferroelectric liquid crystal, or the like can be used. In the case where a horizontal electric field mode is employed, a liquid crystal exhibiting a blue phase for which an alignment film is not used may be used.

The following can be used as a mode of the liquid crystal element: a TN (Twisted Nematic) mode, a VA (Vertical Alignment) mode, an IPS (In-Plane-Switching) mode, an FFS (Fringe Field Switching) mode, an ASM (Axially Symmetric aligned Micro-cell) mode, an OCB (Optically Compensated Birefringence) mode, an ECB (Electrically Controlled Birefringence) mode, a guest-host mode, or the like.

A scattering liquid crystal employing a polymer dispersed liquid crystal, a polymer network liquid crystal, or the like can be used for the liquid crystal layer 776. At this time, monochrome image display may be performed without the coloring film 736, or color display may be performed using the coloring film 736.

As a method for driving the liquid crystal element, a time-division display method (also referred to as a field-sequential driving method) in which color display is performed on the basis of a successive additive color mixing method may be employed. In that case, a structure in which the coloring film 736 is not provided may be employed. In the case where the time-division display method is employed, advantages such as the aperture ratio of each pixel or the resolution being increased can be obtained because subpixels that emit light of, for example, R (red), G (green), and B (blue), need not be provided.

### <Display Device Using Light-Emitting Element>

The display device 700 illustrated in FIG. 15 includes a light-emitting element 782. The light-emitting element 782 includes the conductive layer 772, an EL layer 786, and a conductive film 788. The EL layer 786 contains a light-emitting material such as an organic compound or an inorganic compound.

As the light-emitting material, a fluorescent material, a phosphorescent material, a thermally activated delayed fluorescence (TADF) material, an inorganic compound (e.g., a quantum dot material), or the like can be used.

In the display device 700 illustrated in FIG. 15, an insulating film 730 covering part of the conductive layer 772 is provided over the planarization insulating film 770. Here, the light-emitting element 782 is a top-emission light-emitting element, which includes the conductive film 788 with a light-transmitting property. Note that the light-emitting element 782 may have a bottom-emission structure in which light is emitted to the conductive layer 772 side, or a dual-emission structure in which light is emitted to both the conductive layer 772 side and the conductive film 788 side.

The coloring film 736 is provided to overlap with the light-emitting element 782. The light-blocking film 738 is provided to overlap with the insulating film 730 and be in the lead wiring portion 711, and the source driver circuit portion 704. The coloring film 736 and the light-blocking film 738 are covered with the insulating film 734. A space between the light-emitting element 782 and the insulating film 734 is filled with a sealing film 732. Note that a structure in which the coloring film 736 is not provided may be employed when the EL layer 786 is formed into an island shape for each pixel or into a stripe shape for each pixel column, i.e., the EL layer 786 is formed by a side by side method.

FIG. 16 illustrates a structure of a display device suitably applicable to a flexible display. FIG. 16 is a cross-sectional view taken along the dashed-dotted line S-T in the display device 700A in FIG. 12B.

The display device 700A in FIG. 16 has a structure in which a support substrate 745, a bonding layer 742, the resin layer 743, and an insulating layer 744 are stacked instead of the first substrate 701 in FIG. 15. The transistor 750, the capacitor 790, and the like are provided over the insulating layer 744 over the resin layer 743.

The support substrate 745 includes an organic resin, glass, or the like and is thin enough to have flexibility. The resin layer 743 is a layer containing an organic resin such as polyimide or acrylic. The insulating layer 744 includes an inorganic insulating film of silicon oxide, silicon oxynitride, silicon nitride, or the like. The resin layer 743 and the support substrate 745 are bonded to each other with the adhesive layer 742. The resin layer 743 is preferably thinner than the support substrate 745.

The display device 700A in FIG. 16 includes a protective layer 740 instead of the second substrate 705 in FIG. 15. The protective layer 740 is bonded to the sealing film 732. A glass substrate, a resin film, or the like can be used as the protective layer 740. Alternatively, as the protective layer 740, an optical member such as a polarizing plate or a scattering plate, an input device such as a touch sensor panel, or a structure in which two or more of the above are stacked may be employed.

The EL layer 786 included in the light-emitting element 782 is provided over the insulating film 730 and the conductive layer 772 in an island shape. The EL layer 786 is formed separately such that the subpixels have the respective emission colors, whereby color display can be achieved without the coloring film 736. A protective layer 741 is provided to cover the light-emitting element 782. The protective layer 741 has a function of preventing diffusion of impurities such as water into the light-emitting element 782. The protective layer 741 is preferably formed using an inorganic insulating film. The protective layer 741 further preferably has a stacked-layer structure including one or more inorganic insulating films and one or more organic insulating films.

FIG. 16 illustrates the region P2 that can be bent. The region P2 includes a portion where the support substrate 745, the bonding layer 742, and the inorganic insulating film such as the insulating layer 744 are not provided. In the region P2, a resin layer 746 is provided to cover the wiring 760. When a structure is employed in which an inorganic insulating film is not provided if possible in the region P2 that can be bent and only a conductive layer containing a metal or an alloy and a layer containing an organic material are stacked, generation of cracks caused at bending can be prevented. When the support substrate 745 is not provided in the region P2, part of the display device 700A can be bent with an extremely small radius of curvature.

<Structure Example of Display Device Provided with Input Device>

An input device may be provided in the display device 700 or the display device 700A illustrated in FIG. 13 to FIG. 16. An example of the input device includes a touch sensor.

A variety of types such as a capacitive type, a resistive type, a surface acoustic wave type, an infrared type, an optical type, and a pressure-sensitive type can be used as the sensor type, for example. Alternatively, two or more of these types may be combined and used.

Examples of the touch panel structure include a so-called in-cell touch panel in which an input device is provided between a pair of substrates, a so-called on-cell touch panel in which an input device is formed over the display device 700, and a so-called out-cell touch panel in which an input device is attached to the display device 700.

At least part of the structure examples, the drawings corresponding thereto, and the like exemplified in this embodiment can be implemented in combination with the other structure examples, the other drawings, and the like as appropriate.

At least part of this embodiment can be implemented in combination with the other embodiments described in this specification as appropriate.

### Embodiment 3

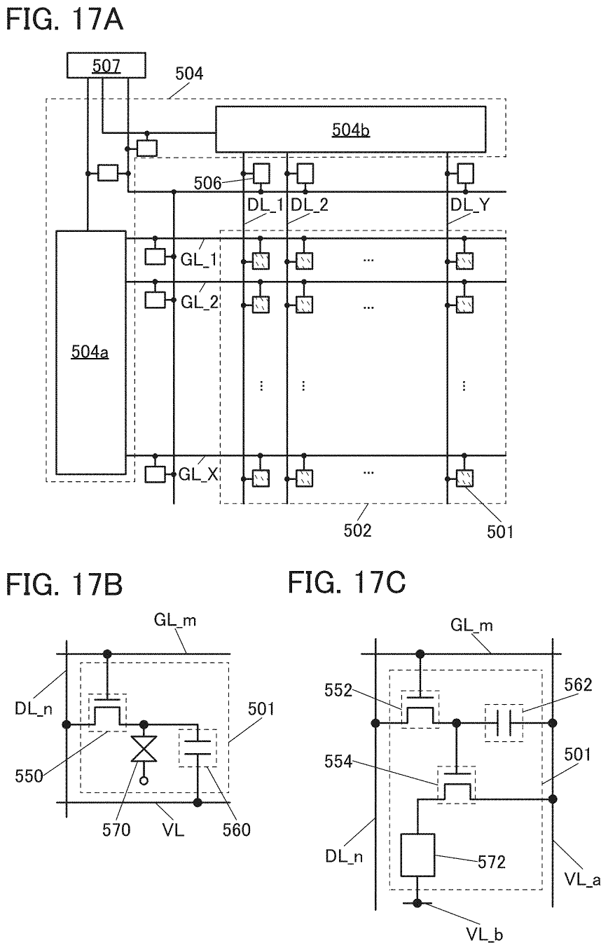

In this embodiment, a display device that includes the semiconductor device of one embodiment of the present invention will be described with reference to FIG. 17.

A display device illustrated in FIG. 17A includes a pixel portion 502, a driver circuit portion 504, protection circuits 506, and a terminal portion 507. Note that a structure in which the protection circuits 506 are not provided may be employed.

The transistor of one embodiment of the present invention can be used as transistors included in the pixel portion 502 and the driver circuit portion 504. The transistor of one embodiment of the present invention may also be used in the protection circuits 506.

The pixel portion 502 includes a plurality of pixel circuits 501 that drive a plurality of display elements arranged in X rows and Y columns (X and Y each independently represent a natural number of 2 or more).

The driver circuit portion 504 includes driver circuits such as a gate driver 504a that outputs a scanning signal to a gate line GL_1 to a gate line GL_X and a source driver 504b that supplies a data signal to a data line DL_1 to a data line DL_Y. The gate driver 504a includes at least a shift register. The source driver 504b is formed using a plurality of analog switches, for example. Alternatively, the source driver 504b may be formed using a shift register or the like.

The terminal portion 507 refers to a portion provided with terminals for inputting power, control signals, image signals, and the like to the display device from external circuits.

The protection circuit 506 is a circuit that, when a potential out of a certain range is applied to a wiring to which the protection circuit 506 is connected, establishes continuity between the wiring and another wiring. The protection circuit 506 illustrated in FIG. 17A is connected to a variety of wirings such as the gate lines GL that are wirings between the gate driver 504a and the pixel circuits 501 and the data lines DL that are wirings between the source driver 504b and the pixel circuits 501, for example.

The gate driver 504a and the source driver 504b may be provided over a substrate over which the pixel portion 502 is provided, or a substrate where a gate driver circuit or a source driver circuit is separately formed (e.g., a driver circuit board formed using a single crystal semiconductor film or a polycrystalline semiconductor film) may be implemented on the substrate over which the pixel portion 502 is provided by COG or TAB (Tape Automated Bonding).

The plurality of pixel circuits 501 illustrated in FIG. 17A can have a structure illustrated in FIG. 17B or FIG. 17C, for example.

The pixel circuit 501 illustrated in FIG. 17B includes a liquid crystal element 570, a transistor 550, and a capacitor 560. The data line DL_n, the gate line GL_m, a potential supply line VL, and the like are connected to the pixel circuit 501.

The potential of one of a pair of electrodes of the liquid crystal element 570 is set appropriately in accordance with the specifications of the pixel circuit 501. The alignment state of the liquid crystal element 570 is set depending on written data. Note that a common potential may be supplied to one of the pair of electrodes of the liquid crystal element 570 included in each of the plurality of pixel circuits 501. Alternatively, a potential supplied to one of the pair of electrodes of the liquid crystal element 570 of the pixel circuit 501 may differ between rows.

The pixel circuit 501 shown in FIG. 17C includes a transistor 552, a transistor 554, a capacitor 562, and a light-emitting element 572. The data line DL_n, the gate line GL_m, a potential supply line VL_a, a potential supply line VL_b, and the like are connected to the pixel circuit 501.

Note that a high power supply potential VDD is supplied to one of the potential supply line VL_a and the potential supply line VL_b, and a low power supply potential VSS is supplied to the other. Current flowing through the light-emitting element 572 is controlled in accordance with a potential supplied to a gate of the transistor 554, whereby the luminance of light emitted from the light-emitting element 572 is controlled.

At least part of the structure examples, the drawings corresponding thereto, and the like exemplified in this embodiment can be implemented in combination with the other structure examples, the other drawings, and the like as appropriate.

At least part of this embodiment can be implemented in combination with the other embodiments described in this specification as appropriate.

### Embodiment 4

A pixel circuit including a memory for correcting gray levels displayed by pixels and a display device including the pixel circuit will be described below. The transistor described in Embodiment 1 can be used as a transistor used in the pixel circuit described below.

### <Circuit Configuration>

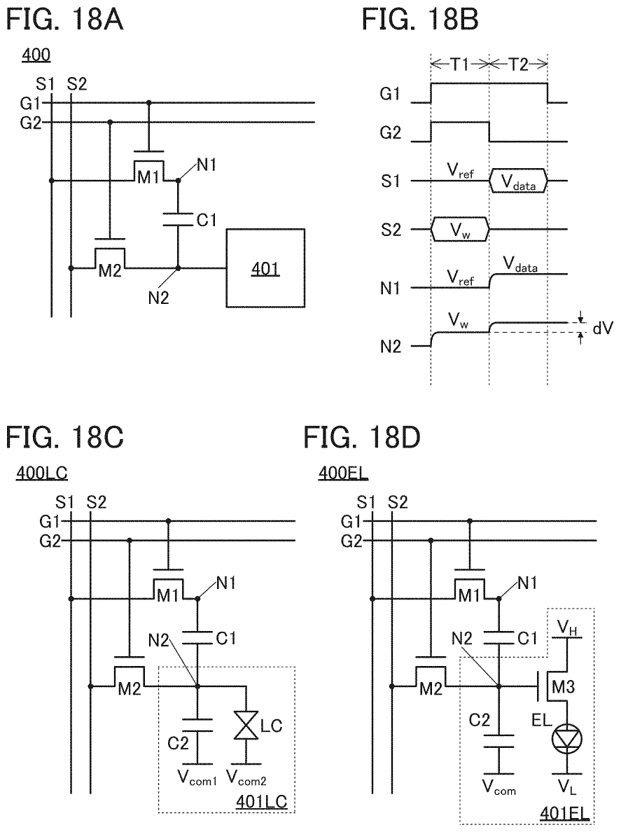

FIG. 18A is a circuit diagram of a pixel circuit 400. The pixel circuit 400 includes a transistor M1, a transistor M2, a capacitor C1, and a circuit 401. A wiring S1, a wiring S2, a wiring G1, and a wiring G2 are connected to the pixel circuit 400.

In the transistor M1, a gate is connected to the wiring G1, one of a source and a drain is connected to the wiring S1, and the other is connected to one electrode of the capacitor C1. In the transistor M2, a gate is connected to the wiring G2, one of a source and a drain is connected to the wiring S2, and the other is connected to the other electrode of the capacitor C1 and the circuit 401.

The circuit 401 is a circuit including at least one display element. Any of a variety of elements can be used as the display element, and typically, a light-emitting element such as an organic EL element or an LED element, a liquid crystal element, a MEMS (Micro Electro Mechanical Systems) element, or the like can be used.

A node connecting the transistor M1 and the capacitor C1 is denoted as a node N1, and a node connecting the transistor M2 and the circuit 401 is denoted as a node N2.

In the pixel circuit 400, the potential of the node N1 can be retained when the transistor M1 is turned off. The potential of the node N2 can be retained when the transistor M2 is turned off. When a predetermined potential is written to the node N1 through the transistor M1 with the transistor M2 being in an off state, the potential of the node N2 can be changed in accordance with displacement of the potential of the node N1 owing to capacitive coupling through the capacitor C1.

Here, the transistor using an oxide semiconductor, which is described in Embodiment 1, can be used as one or both of the transistor M1 and the transistor M2. Accordingly, owing to an extremely low off-state current, the potential of the node N1 or the node N2 can be retained for a long time. Note that in the case where the period in which the potential of each node is retained is short (specifically, the case where the frame frequency is higher than or equal to 30 Hz, for example), a transistor using a semiconductor such as silicon may be used.

### <Driving Method Example>

Next, an example of a method for operating the pixel circuit 400 is described with reference to FIG. 18B. FIG. 18B is a timing chart of the operation of the pixel circuit 400. Note that for simplification of description, the influence of various kinds of resistance such as wiring resistance, parasitic capacitance of a transistor, a wiring, or the like, the threshold voltage of the transistor, and the like is not taken into account here.

In the operation shown in FIG. 18B, one frame period is divided into a period T1 and a period T2. The period T1 is a period in which a potential is written to the node N2, and the period T2 is a period in which a potential is written to the node N1.

### [Period T1]

In the period T1, a potential for turning on the transistor is supplied to both the wiring G1 and the wiring G2. In addition, a potential V_{ref} that is a fixed potential is supplied to the wiring S1, and a first data potential V_{w} is supplied to the wiring S2.

The potential V_{ref} is supplied from the wiring S1 to the node N1 through the transistor M1. The first data potential V_{w} is supplied to the node N2 through the transistor M2. Accordingly, a potential difference V_{w}−V_{ref} is retained in the capacitor C1.

### [Period T2]

Next, in the period T2, a potential for turning on the transistor M1 is supplied to the wiring G1, and a potential for turning off the transistor M2 is supplied to the wiring G2. A second data potential V_{data} is supplied to the wiring S1. The wiring S2 may be supplied with a predetermined constant potential or brought into a floating state.

The second data potential V_{data} is supplied to the node N1 through the transistor M1. At this time, capacitive coupling due to the capacitor C1 changes the potential of the node N2 in accordance with the second data potential V_{data} by a potential dV. That is, a potential that is the sum of the first data potential V_{w} and the potential dV is input to the circuit 401. Note that although the potential dV is shown as a positive value in FIG. 18B, the potential dV may be a negative value. That is, the second potential V_{data} may be lower than the potential V_{ref}.

Here, the potential dV is roughly determined by the capacitance of the capacitor C1 and the capacitance of the circuit 401. When the capacitance of the capacitor C1 is sufficiently larger than the capacitance of the circuit 401, the potential dV is a potential close to the second data potential V_{data}.

In the above manner, the pixel circuit 400 can generate a potential to be supplied to the circuit 401 including the display element, by combining two kinds of data signals; hence, a gray level can be corrected in the pixel circuit 400.

The pixel circuit 400 can also generate a potential exceeding the maximum potential that can be supplied by a source driver connected to the wiring S1 and the wiring S2. For example, in the case where a light-emitting element is used, high-dynamic range (HDR) display or the like can be performed. In the case where a liquid crystal element is used, overdriving or the like can be achieved.

### <Application Example>

### [Example Using Liquid Crystal Element]

A pixel circuit 400LC illustrated in FIG. 18C includes a circuit 401LC. The circuit 401LC includes a liquid crystal element LC and a capacitor C2.

In the liquid crystal element LC, one electrode is connected to the node N2 and one electrode of the capacitor C2, and the other electrode is connected to a wiring supplied with a potential V_{com2}. The other electrode of the capacitor C2 is connected to a wiring supplied with a potential V_{com1}.

The capacitor C2 functions as a storage capacitor. Note that the capacitor C2 can be omitted when not needed.

In the pixel circuit 400LC, a high voltage can be supplied to the liquid crystal element LC; thus, high-speed display can be performed by overdriving or a liquid crystal material with a high driving voltage can be employed, for example. Moreover, by supply of a correction signal to the wiring S1 or the wiring S2, a gray level can be corrected in accordance with the operating temperature, the deterioration state of the liquid crystal element LC, or the like.

### [Example Using Light-Emitting Element]

A pixel circuit 400EL illustrated in FIG. 18D includes a circuit 401EL. The circuit 401EL includes a light-emitting element EL, a transistor M3, and the capacitor C2.

In the transistor M3, a gate is connected to the node N2 and one electrode of the capacitor C2, one of a source and a drain is connected to a wiring supplied with a potential V_{H}, and the other is connected to one electrode of the light-emitting element EL. The other electrode of the capacitor C2 is connected to a wiring supplied with a potential V_{com}. The other electrode of the light-emitting element EL is connected to a wiring supplied with a potential V_{L}.

The transistor M3 has a function of controlling a current to be supplied to the light-emitting element EL. The capacitor C2 functions as a storage capacitor. The capacitor C2 can be omitted when not needed.

Note that although the structure in which the anode side of the light-emitting element EL is connected to the transistor M3 is described here, the transistor M3 may be connected to the cathode side. In that case, the values of the potential V_{H} and the potential V_{L} can be appropriately changed.

In the pixel circuit 400EL, a large amount of current can flow through the light-emitting element EL when a high potential is applied to the gate of the transistor M3, which enables HDR display, for example. A variation in the electrical characteristics of the transistor M3 and the light-emitting element EL can be corrected by supply of a correction signal to the wiring S1 or the wiring S2.

Note that the structure is not limited to the circuits illustrated in FIG. 18C and FIG. 18D, and a structure to which a transistor, a capacitor, or the like is further added may be employed.

At least part of this embodiment can be implemented in combination with the other embodiments described in this specification as appropriate.

### Embodiment 5

In this embodiment, a display module that can be fabricated using one embodiment of the present invention is described.

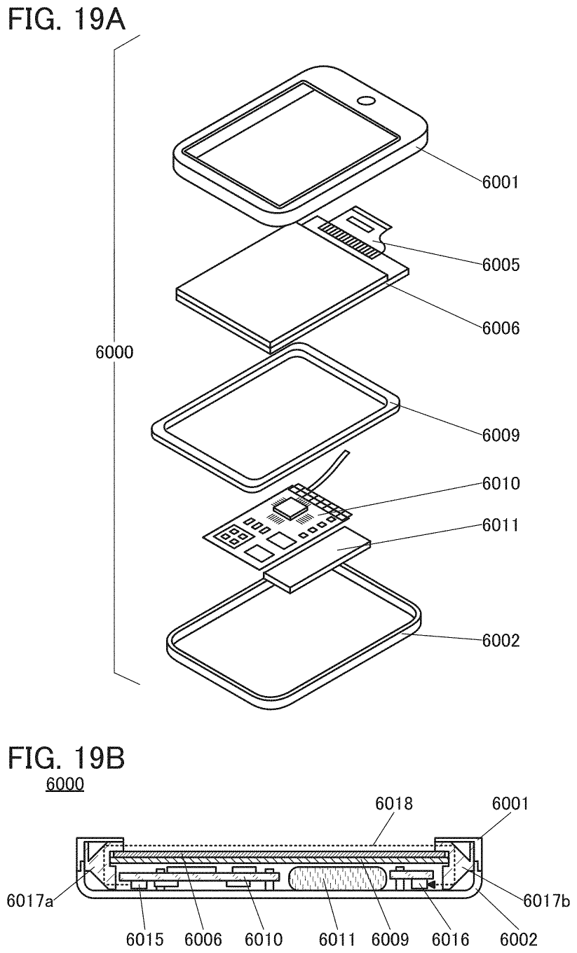

In a display module 6000 illustrated in FIG. 19A, a display device 6006 to which an FPC 6005 is connected, a frame 6009, a printed circuit board 6010, and a battery 6011 are provided between an upper cover 6001 and a lower cover 6002.

A display device fabricated using one embodiment of the present invention can be used as the display device 6006, for example. With the display device 6006, a display module with extremely low-power consumption can be achieved.

The shape and size of the upper cover 6001 and the lower cover 6002 can be changed as appropriate in accordance with the size of the display device 6006.

The display device 6006 may have a function of a touch panel.

The frame 6009 may have a function of protecting the display device 6006, a function of blocking electromagnetic waves generated by the operation of the printed circuit board 6010, a function of a heat dissipation plate, or the like.

The printed circuit board 6010 includes a power supply circuit, a signal processing circuit for outputting a video signal and a clock signal, a battery control circuit, and the like.

FIG. 19B is a schematic cross-sectional view of the display module 6000 having an optical touch sensor.

The display module 6000 includes a light-emitting portion 6015 and a light-receiving portion 6016 that are provided on the printed circuit board 6010. Furthermore, a pair of light guide portions (a light guide portion 6017a and a light guide portion 6017b) are provided in regions surrounded by the upper cover 6001 and the lower cover 6002.

The display device 6006 overlaps with the printed circuit board 6010 and the battery 6011 with the frame 6009 therebetween. The display device 6006 and the frame 6009 are fixed to the light guide portion 6017a and the light guide portion 6017b.

Light 6018 emitted from the light-emitting portion 6015 travels over the display device 6006 through the light guide portion 6017a and reaches the light-receiving portion 6016 through the light guide portion 6017b. For example, blocking of the light 6018 by a sensing target such as a finger or a stylus enables detection of touch operation.

A plurality of light-emitting portions 6015 are provided along two adjacent sides of the display device 6006, for example. A plurality of light-receiving portions 6016 are provided at the positions on the opposite side of the light-emitting portions 6015. Accordingly, information about the position of touch operation can be obtained.

As the light-emitting portion 6015, a light source such as an LED element can be used, for example, and it is particularly preferable to use a light source emitting infrared rays. As the light-receiving portion 6016, a photoelectric element that receives light emitted from the light-emitting portion 6015 and converts it into an electrical signal can be used. A photodiode that can receive infrared rays can be suitably used.

With use of the light guide portion 6017a and the light guide portion 6017b which transmit the light 6018, the light-emitting portion 6015 and the light-receiving portion 6016 can be placed under the display device 6006, and a malfunction of the touch sensor due to external light reaching the light-receiving portion 6016 can be suppressed. Particularly when a resin that absorbs visible light and transmits infrared rays is used, a malfunction of the touch sensor can be suppressed more effectively.

At least part of this embodiment can be implemented in combination with the other embodiments described in this specification as appropriate.

### Embodiment 6

In this embodiment, examples of an electronic device for which the display device of one embodiment of the present invention can be used will be described.

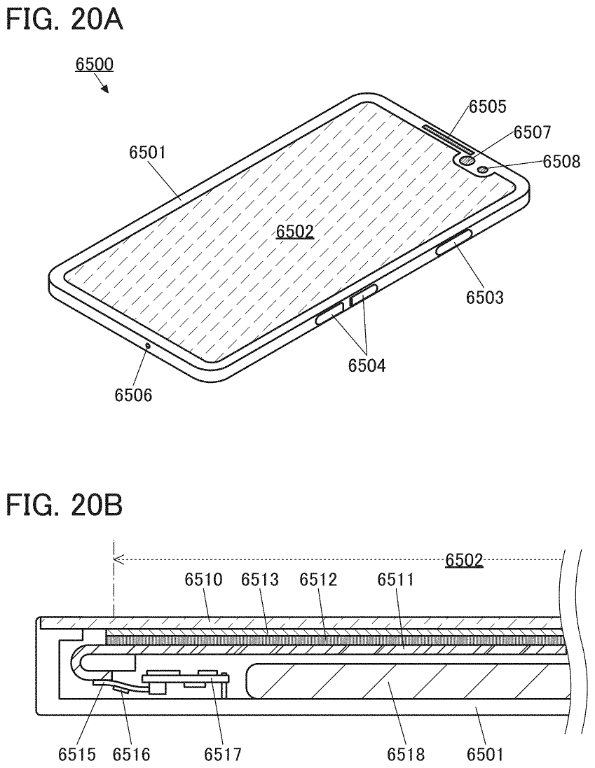

An electronic device 6500 illustrated in FIG. 20A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display device of one embodiment of the present invention can be used in the display portion 6502.

FIG. 20B is a schematic cross-sectional view including an end portion of the housing 6501 on the microphone 6506 side.

A protective member 6510 having a light-transmitting property is provided on the display surface side of the housing 6501, and a display panel 6511, an optical member 6512, a touch sensor panel 6513, a printed circuit board 6517, a battery 6518, and the like are provided in a space surrounded by the housing 6501 and the protective member 6510.

The display panel 6511, the optical member 6512, and the touch sensor panel 6513 are fixed to the protective member 6510 with a bonding layer not illustrated.

Part of the display panel 6511 is bent in a region outside the display portion 6502. An FPC 6515 is connected to the bent part. An IC 6516 is mounted on the FPC 6515. The FPC 6515 is connected to a terminal provided for the printed circuit board 6517.

A flexible display panel of one embodiment of the present invention can be used as the display panel 6511. Thus, an extremely lightweight electronic device can be achieved. Furthermore, since the display panel 6511 is extremely thin, the battery 6518 with a high capacity can be provided without an increase in the thickness of the electronic device. Moreover, part of the display panel 6511 is bent to provide a connection portion with the FPC 6515 on the back side of the pixel portion, whereby an electronic device with a narrow bezel can be obtained.

At least part of this embodiment can be implemented in combination with the other embodiments described in this specification as appropriate.

### Embodiment 7

In this embodiment, electronic devices each including a display device fabricated using one embodiment of the present invention will be described.

Electronic devices exemplified below each include a display device of one embodiment of the present invention in a display portion. Thus, the electronic devices achieve high resolution. In addition, the electronic devices can each achieve both high resolution and a large screen.

A display portion in an electronic device of one embodiment of the present invention can display a video with a resolution of, for example, full high definition, 4K2K, 8K4K, 16K8K, or higher.

Examples of the electronic devices include a digital camera, a digital video camera, a digital photo frame, a cellular phone, a portable game machine, a portable information terminal, and an audio reproducing device, in addition to electronic devices with comparatively large screens, such as a television device, a notebook personal computer, a monitor device, digital signage, a pachinko machine, and a game machine.

An electronic device using one embodiment of the present invention can be incorporated along a flat surface or a curved surface of an inside wall or an outside wall of a house or a building, an interior or an exterior of a car, or the like.

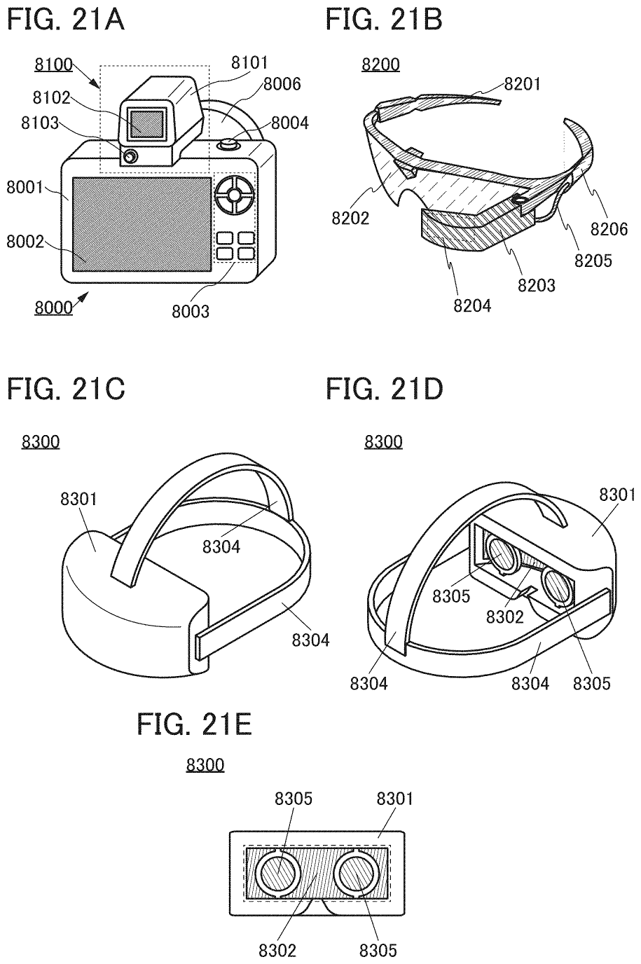

FIG. 21A is a diagram illustrating appearance of a camera 8000 to which a finder 8100 is attached.

The camera 8000 includes a housing 8001, a display portion 8002, operation buttons 8003, a shutter button 8004, and the like. In addition, a detachable lens 8006 is attached to the camera 8000.

Note that the lens 8006 and the housing may be integrated with each other in the camera 8000.

The camera 8000 can take images by the press of the shutter button 8004 or touch on the display portion 8002 serving as a touch panel.

The housing 8001 includes a mount including an electrode, so that the finder 8100, a stroboscope, or the like can be connected to the housing.

The finder 8100 includes a housing 8101, a display portion 8102, a button 8103, and the like.

The housing 8101 is attached to the camera 8000 with the mount engaging with a mount of the camera 8000. In the finder 8100, a video or the like received from the camera 8000 can be displayed on the display portion 8102.

The button 8103 has a function of a power button or the like.

The display device of one embodiment of the present invention can be used for the display portion 8002 of the camera 8000 and the display portion 8102 of the finder 8100. Note that a finder may be incorporated in the camera 8000.

FIG. 21B is a diagram illustrating appearance of a head-mounted display 8200.

The head-mounted display 8200 includes a mounting portion 8201, a lens 8202, a main body 8203, a display portion 8204, a cable 8205, and the like. In addition, a battery 8206 is incorporated in the mounting portion 8201.

The cable 8205 supplies power from the battery 8206 to the main body 8203. The main body 8203 includes a wireless receiver or the like and can display received video information on the display portion 8204. In addition, the main body 8203 is provided with a camera, and data on the movement of the user's eyeball and eyelid can be used as an input means.

The mounting portion 8201 may be provided with a plurality of electrodes capable of sensing current flowing in response to the movement of the user's eyeball in a position in contact with the user to have a function of recognizing the user's sight line. Furthermore, the mounting portion 8201 may have a function of monitoring the user's pulse with use of current flowing through the electrodes. Moreover, the mounting portion 8201 may include a variety of sensors such as a temperature sensor, a pressure sensor, and an acceleration sensor to have a function of displaying the user's biological information on the display portion 8204 or a function of changing a video displayed on the display portion 8204 in accordance with the movement of the user's head.

The display device of one embodiment of the present invention can be used for the display portion 8204.

FIG. 21C, FIG. 21D, and FIG. 21E are diagrams illustrating appearance of a head-mounted display 8300. The head-mounted display 8300 includes a housing 8301, a display portion 8302, band-shaped fixing units 8304, and a pair of lenses 8305.

A user can see display on the display portion 8302 through the lenses 8305. Note that the display portion 8302 is preferably curved and placed because the user can feel a high realistic sensation. In addition, when another image displayed in a different region of the display portion 8302 is viewed through the lenses 8305, 3D display using parallax or the like can also be performed. Note that the structure is not limited to that in which one display portion 8302 is provided, and two display portions 8302 may be provided so that one display portion is provided for one eye of the user.

Note that the display device of one embodiment of the present invention can be used in the display portion 8302. The display device including the semiconductor device of one embodiment of the present invention has an extremely high resolution; thus, even when a video is magnified by the lenses 8305 as in FIG. 21E, the user does not perceive pixels, and a more realistic video can be displayed.

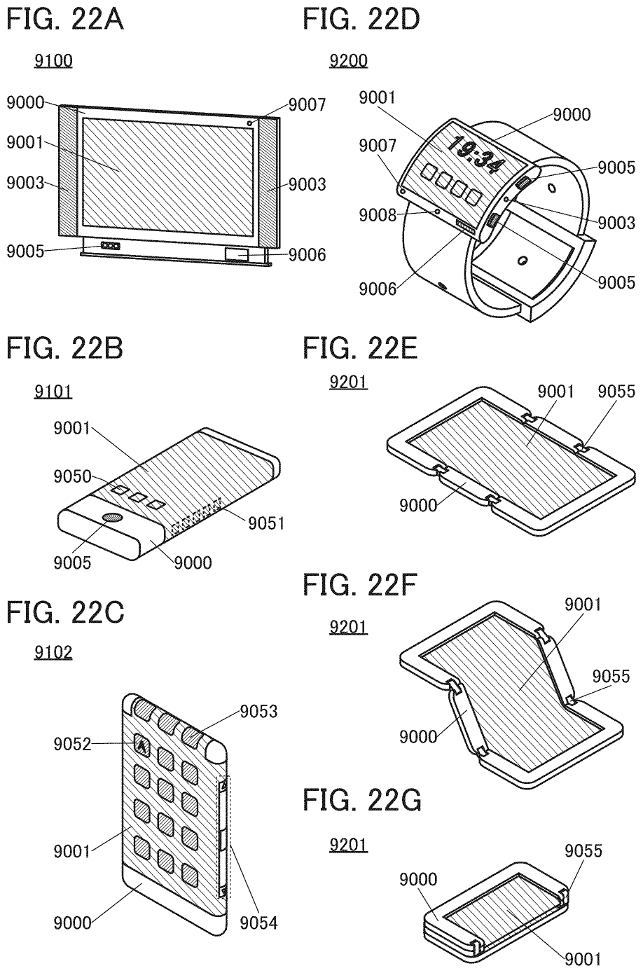

Electronic devices illustrated in FIG. 22A to FIG. 22G include a housing 9000, a display portion 9001, a speaker 9003, an operation key 9005 (including a power switch or an operation switch), a connection terminal 9006, a sensor 9007 (a sensor having a function of measuring force, displacement, a position, speed, acceleration, angular velocity, rotational frequency, distance, light, liquid, magnetism, temperature, a chemical substance, sound, time, hardness, an electric field, current, voltage, power, radiation, flow rate, humidity, a gradient, oscillation, an odor, or infrared rays), a microphone 9008, and the like.

The electronic devices illustrated in FIG. 22A to FIG. 22G have a variety of functions. For example, the electronic devices can have a function of displaying a variety of information (a still image, a moving image, a text image, and the like) on the display portion, a touch panel function, a function of displaying a calendar, date, time, and the like, a function of controlling processing with a variety of software (programs), a wireless communication function, a function of reading out and processing a program or data stored in a recording medium, and the like. Note that the functions of the electronic devices are not limited thereto, and the electronic devices can have a variety of functions. The electronic devices may include a plurality of display portions. In addition, the electronic devices may each include a camera or the like and have a function of taking a still image or a moving image and storing the taken image in a recording medium (an external recording medium or a recording medium incorporated in the camera), a function of displaying the taken image on the display portion, or the like.

The details of the electronic devices illustrated in FIG. 22A to FIG. 22G are described below.

FIG. 22A is a perspective view illustrating a television device 9100. The display portion 9001 having a large screen size of, for example, 50 inches or more, or 100 inches or more can be incorporated in the television device 9100.

FIG. 22B is a perspective view illustrating a portable information terminal 9101. For example, the portable information terminal 9101 can be used as a smartphone. Note that the portable information terminal 9101 may be provided with the speaker 9003, the connection terminal 9006, the sensor 9007, or the like. The portable information terminal 9101 can display text and image information on its plurality of surfaces. FIG. 22B illustrates an example in which three icons 9050 are displayed. Furthermore, information 9051 indicated by dashed rectangles can be displayed on another surface of the display portion 9001. Examples of the information 9051 include notification of reception of an e-mail, SNS, or an incoming call, the title and sender of an e-mail, SNS, or the like, the date, the time, remaining battery, and the reception strength of an antenna. Alternatively, the icon 9050 or the like may be displayed in a position where the information 9051 is displayed.

FIG. 22C is a perspective view illustrating a portable information terminal 9102. The portable information terminal 9102 has a function of displaying information on three or more surfaces of the display portion 9001. Here, an example in which information 9052, information 9053, and information 9054 are displayed on different surfaces is illustrated. For example, the user can check the information 9053 displayed in a position that can be observed from above the portable information terminal 9102, with the portable information terminal 9102 put in a breast pocket of his/her clothes. The user can see the display without taking out the portable information terminal 9102 from the pocket and decide whether to answer a call, for example.

FIG. 22D is a perspective view illustrating a watch-type portable information terminal 9200. For example, the portable information terminal 9200 can be used as a smart watch. In addition, a display surface of the display portion 9001 is curved and provided, and display can be performed along the curved display surface. Furthermore, intercommunication between the portable information terminal 9200 and, for example, a headset capable of wireless communication enables hands-free calling. Moreover, with the connection terminal 9006, the portable information terminal 9200 can also perform mutual data transmission with another information terminal and charging. Note that charging operation may be performed by wireless power feeding.

FIG. 22E, FIG. 21F, and FIG. 21G are perspective views illustrating a foldable portable information terminal 9201. In addition, FIG. 22E is a perspective view of an unfolded state of the portable information terminal 9201, FIG. 22G is a perspective view of a folded state thereof, and FIG. 22F is a perspective view of a state in the middle of change from one of FIG. 22E and FIG. 22G to the other. The portable information terminal 9201 is highly portable in the folded state and is highly browsable in the unfolded state because of a seamless large display region. The display portion 9001 of the portable information terminal 9201 is supported by three housings 9000 joined with hinges 9055. For example, the display portion 9001 can be bent with a radius of curvature greater than or equal to 1 mm and less than or equal to 150 mm.

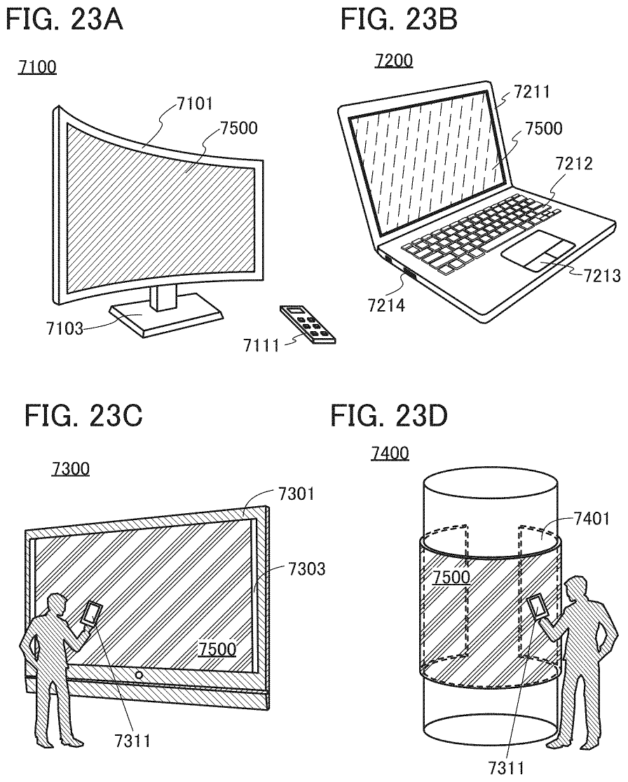

FIG. 23A illustrates an example of a television device. In a television device 7100, a display portion 7500 is incorporated in a housing 7101. Here, a structure in which the housing 7101 is supported by a stand 7103 is illustrated.

Operation of the television device 7100 illustrated in FIG. 23A can be performed with an operation switch provided in the housing 7101 or a separate remote controller 7111. Alternatively, a touch panel may be used for the display portion 7500, and the television device 7100 may be operated by touch on the touch panel. The remote controller 7111 may include a display portion in addition to operation buttons.

Note that the television device 7100 may include a television receiver and a communication device for network connection.

FIG. 23B illustrates a notebook personal computer 7200. The notebook personal computer 7200 includes a housing 7211, a keyboard 7212, a pointing device 7213, an external connection port 7214, and the like. The display portion 7500 is incorporated in the housing 7211.

FIG. 23C and FIG. 23D illustrate examples of digital signage.

Digital signage 7300 illustrated in FIG. 23C includes a housing 7301, the display portion 7500, a speaker 7303, and the like. Furthermore, the digital signage can include an LED lamp, operation keys (including a power switch or an operation switch), a connection terminal, a variety of sensors, a microphone, and the like.

FIG. 23D is digital signage 7400 attached to a cylindrical pillar 7401. The digital signage 7400 includes the display portion 7500 provided along a curved surface of the pillar 7401.

The larger display portion 7500 can increase the amount of information that can be provided at a time and attracts more attention, so that the effectiveness of the advertisement can be increased, for example.

A touch panel is preferably used for the display portion 7500 so that the user can operate the digital signage. Thus, the digital signage can be used not only for advertising but also for providing information that the user needs, such as route information, traffic information, and guidance information on a commercial facility.

As illustrated in FIG. 23C and FIG. 23D, it is preferable that the digital signage 7300 or the digital signage 7400 can work with an information terminal 7311 such as a user's smartphone through wireless communication. For example, information of an advertisement displayed on the display portion 7500 can be displayed on a screen of the information terminal 7311, or display on the display portion 7500 can be switched by operation of the information terminal 7311.

It is possible to make the digital signage 7300 or the digital signage 7400 execute a game with use of the information terminal 7311 as an operation means (controller). Thus, an unspecified number of users can join in and enjoy the game concurrently.

The display device of one embodiment of the present invention can be used for the display portion 7500 in FIG. 23A to FIG. 23D.

The electronic devices of this embodiment each include a display portion; however, one embodiment of the present invention can also be used in an electronic device without a display portion.

At least part of this embodiment can be implemented in combination with the other embodiments described in this specification as appropriate.

### Example 1

In this example, the etching rate of a material that can be used for the metal oxide layer 114 was evaluated.

For the evaluation, samples (sample A1 to sample A4) in each of which a metal oxide film was formed over a glass substrate were used.

The metal oxide film was deposited by a sputtering method using an In—Ga—Zn oxide target (In:Ga:Zn=1:1:1 [atomic ratio]). The substrate temperature in the deposition was 100° C., and an oxygen gas (oxygen flow rate ratio: 100%) was used as a deposition gas. Here, four samples (sample A1 to sample A4) whose metal oxide films were deposited with different power supplies and pressures were fabricated.

For the sample A1, the power supply was set to 2.5 kW (AC), and the pressure was set to 0.3 Pa. For the sample A2, the power supply was set to 2.5 kW (AC), and the pressure was set to 0.6 Pa. For the sample A3, the power supply was set to 4.5 kW (AC), and the pressure was set to 0.3 Pa. For the sample A4, the power supply was set to 4.5 kW (AC), and the pressure was set to 0.6 Pa.

The etching rate was measured by wet etching. As an etchant, a mixed solution of an oxalic acid (lower than or equal to 5%), an additive agent (undisclosed concentration), and water (higher than or equal to 95%) was used. The etchant temperature at the time of etching was 45° C. The etching rate was calculated from the film thickness obtained by optical interference type thickness measurement. Note that the etching rate described in this example refers to the etching rate of the metal oxide film in the thickness direction.

The etching rate (ER) of each sample is shown in Table 1. Table 1 also shows the deposition rate (DR) of the metal oxide film.

TABLE 1

| | | | ER | DR |
|---|---|---|---|---|
| | Power | Pressure | [nm/min.] | [nm/min.] |
| sample A1 | 2.5 kW | 0.3 Pa | 14.0 | 10.5 |
| sample A2 | | 0.6 Pa | 18.6 | 10.7 |
| sample A3 | 4.5 kW | 0.3 Pa | 11.9 | 17.7 |
| sample A4 | | 0.6 Pa | 15.1 | 18.2 |

As shown in Table 1, the tendency in which the etching rate of the metal oxide film is lowered by an increase in the power supply (Power) at the time of depositing the metal oxide film was observed. In addition, the tendency in which the etching rate of the metal oxide film is lowered by a reduction in the pressure (Pressure) at the time of depositing the metal oxide was observed. An increase in power supply or a reduction in pressure of the metal oxide film conceivably causes an increase in crystallinity of the metal oxide film, resulting in lowering of the etching rate. Note that the tendency in which the etching rate is increased by an increase in power supply at the time of depositing the metal oxide film can be observed. A large difference in etching rates depending on the pressure at the time of depositing the metal oxide film was not observed.

### Example 2

In this example, samples (sample B1 to sample B4) each corresponding to the transistor 100 illustrated in FIG. 1 were fabricated, and cross-sectional shapes thereof were evaluated.

For the evaluation, samples in each of which an insulating layer, a metal oxide layer, and a conductive layer were formed over a glass substrate were used.

### <Sample Fabrication>

First, a 150-nm-thick insulating layer was formed over a glass substrate. As the insulating layer, a first silicon oxynitride film with a thickness approximately 5 nm, a second silicon oxynitride film with a thickness approximately 140 nm, and a third silicon oxynitride film with a thickness approximately 5 nm were each deposited by a plasma CVD method.

The first silicon oxynitride film was deposited under the conditions where the flow rates of a silane gas and a dinitrogen monoxide gas were 24 sccm and 18000 sccm, respectively, the pressure was 200 Pa, the deposition power was 130 W, and the substrate temperature was 350° C.

The second silicon oxynitride film was deposited under the conditions where the flow rates of a silane gas and a dinitrogen monoxide gas were 200 sccm and 4000 sccm, respectively, the pressure was 300 Pa, the deposition power was 750 W, and the substrate temperature was 350° C.

The third silicon oxynitride film was deposited under the conditions where the flow rates of a silane gas and a dinitrogen monoxide gas were 20 sccm and 3000 sccm, respectively, the pressure was 40 Pa, the deposition power was 500 W, and the substrate temperature was 350° C.

Next, an approximately 20-nm-thick metal oxide film was deposited over the insulating layer by a sputtering method. The metal oxide film was deposited by a sputtering method using an In—Ga—Zn oxide target (In:Ga:Zn=1:1:1 [atomic ratio]). The substrate temperature in the deposition was 100° C., and an oxygen gas (oxygen flow rate ratio: 100%) was used as a deposition gas. Here, four samples (sample B1 to sample B4) whose metal oxide films were deposited with different power supplies and pressures were fabricated.

For the sample B1, the power supply was set to 2.5 kW (AC), and the pressure was set to 0.3 Pa. For the sample B2, the power supply was set to 2.5 kW (AC), and the pressure was set to 0.6 Pa. For the sample B3, the power supply was set to 4.5 kW (AC), and the pressure was set to 0.3 Pa. For the sample B4, the power supply was set to 4.5 kW (AC), and the pressure was set to 0.6 Pa.

Subsequently, heat treatment was performed at 350° C. in an atmosphere containing nitrogen for one hour.

Next, a conductive film was formed over the metal oxide film. As the conductive film, an approximately 100-nm-thick molybdenum film was deposited by a sputtering method.

Then, a resist pattern was formed over the conductive film.

After that, the conductive film was etched using the resist pattern as a mask to obtain the conductive layer. A dry etching method was used for the etching, and a SF₆ gas was used as an etching gas.

Next, the metal oxide film was etched to obtain a metal oxide layer. A wet etching method was used for the etching. For the etchant used here, the description in Example 1 can be referred to; thus, the detailed description is omitted. Note that the etching treatment time in each of the sample B1 to the sample B4 was 75 seconds.

### <Cross-Sectional Observation of Sample>

Next, sample B1 to sample B4 were thinned by focused ion beam (FIB) and cross sections were observed with a scanning transmission electron microscope (by STEM: Scanning Transmission Electron Microscopy).

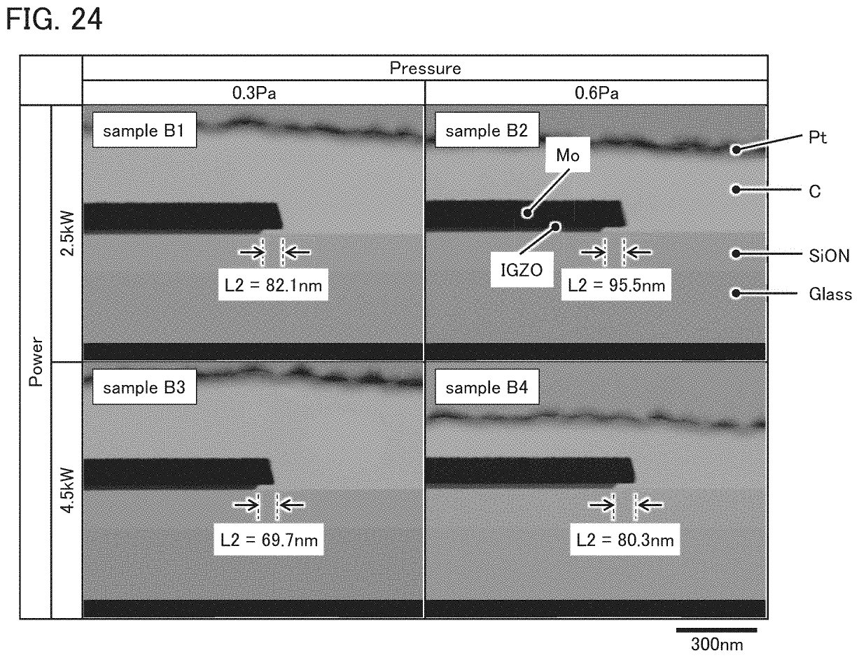

Cross-sectional STEM images of the sample B1 to the sample B4 are shown in FIG. 24. FIG. 24 is transmission electron images (TE images) at a magnification of 100000 times, with descriptions of the power supply (Power) at the time of depositing the metal oxide layer in the vertical direction and the pressure (Pressure) at the time of depositing the metal oxide layer in the horizontal direction. In FIG. 24, a glass substrate is denoted by Glass; an insulating layer, SiON; a metal oxide layer, IGZO; a conductive layer, Mo; platinum coating used for an antistatic film for cross-sectional observation, Pt; and carbon coating used for a protective film, C. Furthermore, FIG. 24 also shows a value of a width L2 that is a difference between a position of the end portion of the conductive layer (Mo) and a position of the end portion of the metal oxide layer (IGZO).

As shown in FIG. 24, it was found that the end portion of the metal oxide layer (IGZO) was located on the inner side than the end portion of the conductive layer (Mo) in each of the samples. Furthermore, the tendency in which the width L2 becomes small by an increase in the power supply at the time of depositing the metal oxide film can be observed. The tendency in which the width L2 becomes small by a reduction in the pressure at the time of depositing the metal oxide film can be observed. Note that it was also found that the width L2 has approximately linear correlation with the etching rate of the metal oxide film described in Example 1.

As described above, the width L2 can be controlled by varying the deposition conditions of the metal oxide.

### Example 3

In this example, samples (sample C1 to sample C3) corresponding to the transistor 100A illustrated in FIG. 5 were fabricated, and electrical characteristics and cross-sectional shapes thereof were evaluated.

### <Sample Fabrication>

For the structure of the fabricated transistors, the structure of the transistor 100A shown in Embodiment 1 can be employed.

First, an approximately 100-nm-thick tungsten film was formed over a glass substrate by a sputtering method and processed to obtain a first gate electrode. Then, as a first gate insulating layer, a first silicon nitride film with a thickness approximately 240 nm, a second silicon nitride film with a thickness approximately 60 nm, and a silicon oxynitride film with a thickness approximately 3 nm were deposited by a plasma CVD method and stacked.

The first silicon nitride film was deposited under the conditions where the flow rates of a silane gas, a nitrogen gas, and an ammonia gas were 290 sccm, 2000 sccm, and 2000 sccm, respectively, the pressure was 200 Pa, the deposition power was 3000 W, and the substrate temperature was 350° C.

The second silicon nitride film was deposited under the conditions where the flow rates of a silane gas, a nitrogen gas, and an ammonia gas were 200 sccm, 2000 sccm, and 100 sccm, respectively, the pressure was 100 Pa, the deposition power was 2000 W, and the substrate temperature was 350° C.

The silicon oxynitride film was deposited under the conditions where the flow rates of a silane gas and a dinitrogen monoxide gas were 20 sccm and 3000 sccm, respectively, the pressure was 40 Pa, the deposition power was 3000 W, and the substrate temperature was 350° C.

Next, a 40-nm-thick metal oxide film was formed over the first gate insulating layer and processed to obtain a semiconductor layer. The metal oxide film was deposited by a sputtering method using an In—Ga—Zn oxide target (In:Ga:Zn=1:1:1 [atomic ratio]). The substrate temperature in the deposition was 100° C. A mixed gas of an oxygen gas and an argon gas was used as a deposition gas, and the oxygen flow rate ratio was 50%. The power supply was set to 2.5 kW (AC), and the pressure was set to 0.6 Pa.

After the semiconductor layer was formed, heat treatment was performed at 350° C. in a nitrogen gas atmosphere for one hour. After that, another heat treatment was performed at 350° C. in a mixed gas atmosphere of a nitrogen gas and an oxygen gas for one hour.

Next, as a second gate insulating layer, a first silicon oxynitride film with a thickness approximately 5 nm, a second silicon oxynitride film with a thickness approximately 140 nm, and a third silicon oxynitride film with a thickness approximately 5 nm were each deposited by a plasma CVD method.

The first silicon oxynitride film was deposited under the conditions where the flow rates of a silane gas and a dinitrogen monoxide gas were 24 sccm and 18000 sccm, respectively, the pressure was 200 Pa, the deposition power was 130 W, and the substrate temperature was 350° C.

The second silicon oxynitride film was deposited under the conditions where the flow rates of a silane gas and a dinitrogen monoxide gas were 200 sccm and 4000 sccm, respectively, the pressure was 300 Pa, the deposition power was 750 W, and the substrate temperature was 350° C.

The third silicon oxynitride film was deposited under the conditions where the flow rates of a silane gas and a dinitrogen monoxide gas were 20 sccm and 3000 sccm, respectively; the pressure was 40 Pa; the deposition power was 500 W; and the substrate temperature was 350° C.

Next, a metal oxide film was formed over the second gate insulating layer by a sputtering method. The metal oxide film was deposited by a sputtering method using an In—Ga—Zn oxide target (In:Ga:Zn=1:1:1 [atomic ratio]). The substrate temperature in the deposition was 100° C. An oxygen gas (oxygen flow rate ratio: 100%) was used as a deposition gas. The power supply was set to 4.5 kW (AC), and the pressure was set to 0.3 Pa. Here, three samples (sample C1 to sample C3) whose metal oxide films were formed to have different thicknesses were fabricated.

For the sample C1, the thickness of the metal oxide film was set to 20 nm. For the sample C2, the thickness of the metal oxide film was set to 30 nm. For the sample C3, the thickness of the metal oxide film was set to 40 nm.

After that, heat treatment was performed in an atmosphere containing nitrogen at 350° C. for one hour.

Next, as a conductive film, a molybdenum film with a thickness approximately 100 nm was formed over the metal oxide film by a sputtering method.

Then, a resist pattern was formed over the conductive film.

Subsequently, the conductive film was etched using the resist pattern as a mask to obtain a conductive layer. A dry etching method was used for the etching, and a SF₆ gas was used as an etching gas.

Subsequently, the metal oxide film was etched to obtain a metal oxide layer. A wet etching method was used for the etching. For an etchant used here, the description in Example 1 can be referred to; thus, the detailed description is omitted. Note that the etching treatment time in each of the sample C1 to the sample C3 was 75 seconds.

Next, boron was added as an impurity element with use of the conductive layer as a mask. A plasma ion doping apparatus was used for addition of the impurity. A B₂H₆ gas was used as a gas for supplying boron.

Next, a silicon oxynitride film with a thickness approximately 300 nm was formed by a plasma CVD method as a protective insulating layer covering the transistor.

The protective insulating layer was deposited under the conditions where the flow rates of a silane gas and a nitrogen gases were 290 sccm and 4000 sccm, respectively, the pressure was 133 Pa, the deposition power was 1000 W, and the substrate temperature was 350° C.

Next, an opening was formed in part of the protective insulating layer and part of the second gate insulating layer by etching, and a molybdenum film was deposited by a sputtering method and then processed to obtain a source electrode and a drain electrode. After that, an approximately 1.5-μm-thick acrylic resin film was formed as a planarization layer, and heat treatment was performed at a temperature of 250° C. in a nitrogen atmosphere for one hour.

Through the above steps, the sample C1 to the sample C3 each including a transistor formed over the glass substrate were obtained.

### <Cross-Sectional Observation of Sample>

Next, the sample C1 to the sample C3 fabricated as the above were thinned by focused ion beam (FIB) and, cross sections thereof were observed with a scanning transmission electron microscope (STEM).

<I_{d}-V_{g} Characteristics of Transistor>

Next, I_{d}-V_{g} characteristics of the fabricated transistors were measured.

For measuring the I_{d}-V_{g} characteristics of the transistors, a voltage applied to the gate electrode (hereinafter also referred to as a gate voltage (V_{g})) was applied from ˜15 V to +20 V in increments of 0.25 V. Moreover, a voltage applied to the source electrode (hereinafter also referred to as a source voltage (Vₛ)) was 0 V (comm), and a voltage applied to the drain electrode (hereinafter also referred to as a drain voltage (V_{d})) was 0.1 V and 10 V.

### <Reliability of Transistor>

Next, gate bias stress tests (GBTs) were performed on the transistors as reliability evaluation.

Here, the gate bias stress test (GBT) is one of indicators for evaluating reliability of transistors, in which a variation in characteristics of transistors is evaluated while a state of applying an electric field to a gate is maintained. Among the gate bias stress tests (GBTs), a test in which a state where a positive potential relative to a source potential and a drain potential is supplied to a gate is maintained at high temperatures is referred to as a positive bias temperature stress (PBTS) test, and a test in which a state where a negative potential is supplied to a gate is maintained at high temperatures is referred to as a negative bias temperature stress (NBTS) test. The PBTS test and the NBTS test conducted in a state where irradiation with light such as white LED light is performed are respectively referred to as a positive bias temperature illumination stress (PBTIS) test and a negative bias temperature illumination stress (NBTIS) test.

In particular, in an n-channel transistor using an oxide semiconductor, a positive potential is applied to a gate in putting the transistor in an on state (a state where a current flows); thus, the amount of change in threshold voltage in the PBTS test is one important item to be focused on as an indicator of the reliability of the transistor.

In this example, the PBTS test and the NBTIS test are shown. In each of the PBTS test and the NBTIS test, a substrate over which a transistor was formed was held at 60° C., a voltage of 0 V was applied to a source and a drain of the transistor, and a voltage of 20 V or −20 V was applied to a gate; this state was held for one hour. Note that for light irradiation in the NBTIS test, white LED light with approximately 10000 lx was used.

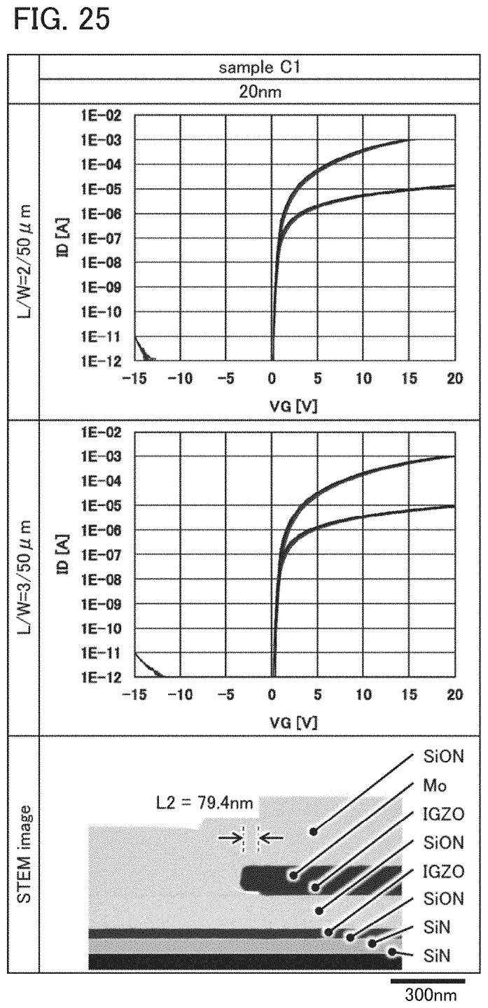

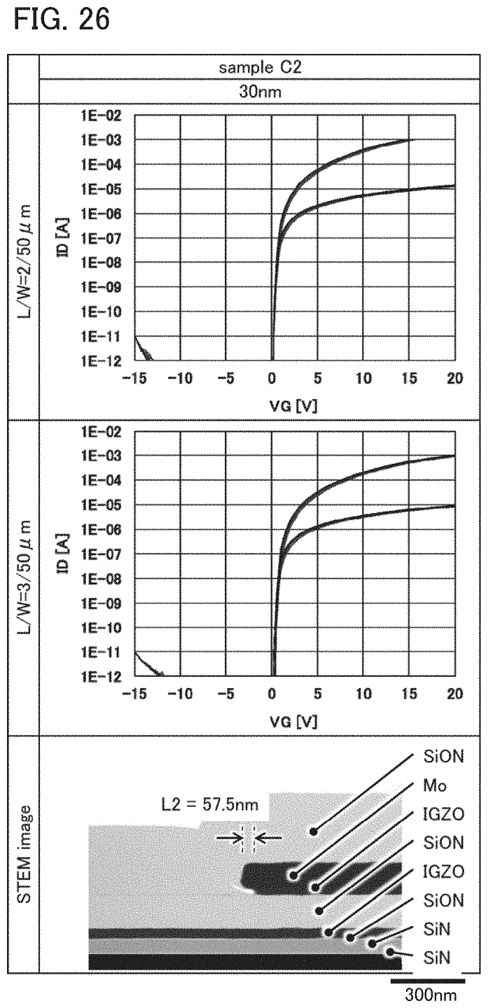

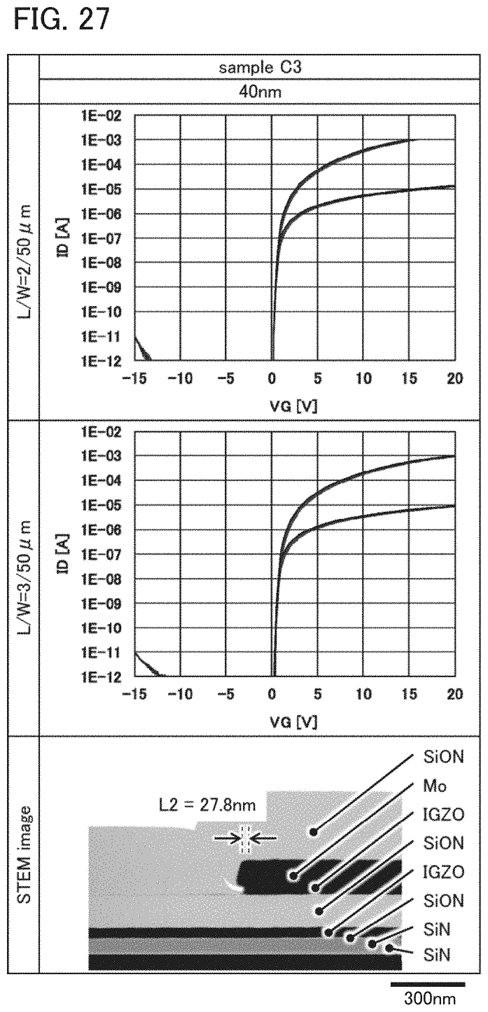

FIG. 25 shows I_{d}-V_{g} characteristics and a cross-sectional STEM image of the transistor of the sample C1. FIG. 26 shows I_{d}-V_{g} characteristics and a cross-sectional STEM image of the transistor of the sample C2. FIG. 27 shows I_{d}-V_{g} characteristics and a cross-sectional STEM image of the transistor of the sample C3. In each of FIG. 25 to FIG. 27, graphs of the I_{d}-V_{g} characteristics of the transistors with different channel lengths are arranged in the vertical direction; two kinds of transistors having channel lengths of 2 μm and 3 μm and a channel width of 50 μm are shown. In each graph of the I_{d}-V_{g} characteristics in FIG. 25 to FIG. 27, the horizontal axis represents a gate voltage (V_{g}) and the vertical axis represents a drain current (I_{d}). For each sample, 10 transistors were subjected to measurement of I_{d}-V_{g} characteristics, and results of the I_{d}-V_{g} characteristics of the 10 transistors, which are superimposed, are shown in FIG. 25 to FIG. 27. At the bottom row in each of FIG. 25 to FIG. 27, the cross-sectional STEM image is shown. In each STEM image, a silicon nitride layer is denoted by SiN; a silicon oxynitride layer, SiON; a metal oxide layer, IGZO; and a conductive layer, Mo. In addition, there is a description of a value of a width L2 that is a difference between a position of an end portion of the conductive layer (Mo) and a position of an end portion of the metal oxide layer (IGZO).

As shown in FIG. 25 to FIG. 27, the tendency in which the width L2 becomes small by making the metal oxide layer thick was observed. In other words, the width L2 can be controlled by changing the thickness of the metal oxide.

It was confirmed that favorable electrical characteristics can be obtained in each sample as shown in FIG. 25 to FIG. 27.

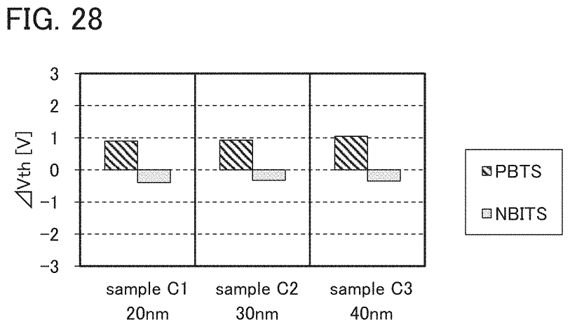

FIG. 28 shows the amount of change in threshold voltage (ΔVₜₕ), in the sample C1 to the sample C3, between before and after each of the PBTS test and the NBTIS test. In FIG. 28, the horizontal axis represents the thickness of a metal oxide layer and the vertical axis represents the amount of change in the threshold voltage (ΔVₜₕ).

As shown in FIG. 28, it was confirmed that the amount of change in the threshold voltage (ΔVₜₕ) was small in each sample, resulting in favorable reliability. In addition, there was no difference in the amount of change in the threshold voltage (ΔVₜₕ) depending on the thickness of the metal oxide layer.

### Example 4

In this example, resistance of the metal oxide film was evaluated.

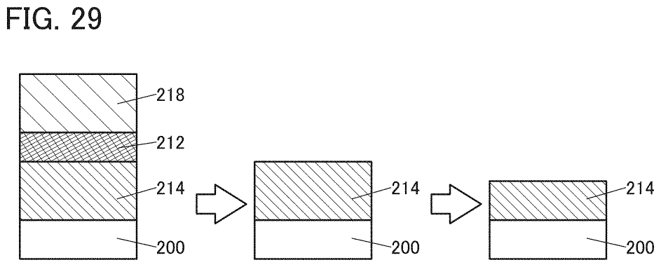

For the evaluation, a sample (sample D) in which a metal oxide film was formed over a glass substrate was used. FIG. 29 shows a cross-sectional structure of the sample D.

### <Sample Fabrication>

First, a 100-nm-thick metal oxide film 214 was formed over a glass substrate 200. The metal oxide film 214 was deposited by a sputtering method using an In—Ga—Zn oxide target (In:Ga:Zn=1:1:1 [atomic ratio]). The substrate temperature in the deposition was 100° C. An oxygen gas (oxygen flow rate ratio: 100%) was used as a deposition gas. The power supply was set to 4.5 kW (AC), and the pressure was set to 0.3 Pa.

After that, heat treatment was performed in an atmosphere containing nitrogen at 350° C. for one hour.

Next, a conductive film 212 was formed over the metal oxide film 214. As the conductive film 212, an approximately 50-nm-thick molybdenum film was deposited by a sputtering method.

Next, an insulating film 218 was formed over the conductive film 212. As the insulating film 218, an approximately 300-nm-thick silicon oxynitride film was deposited by a plasma CVD method. The insulating film 218 was deposited under the conditions where the flow rates of a silane gas and a dinitrogen monoxide gas were 290 sccm and 4000 sccm, respectively, the pressure was 133 Pa, the deposition power was 1000 W, and the substrate temperature was 350° C.

Subsequently, the insulating film 218 and the conductive film 212 were removed by a dry etching method. As an etching gas, a SF₆ gas was used.

Through the above process, the sample D was obtained.

### <Resistance Measurement>

In this example, the resistance of the metal oxide film 214 in the thickness direction was evaluated. Specifically, the thickness and the resistance of the metal oxide film 214 were measured. After that, the following are repeated: the surface side of the metal oxide film 214 was partly removed by etching to reduce the thickness; and the thickness and the resistance was measured again.

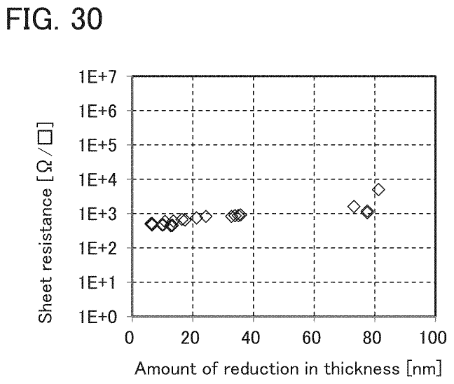

FIG. 30 shows the sheet resistance of the metal oxide film 214. In FIG. 30, the horizontal axis represents the amount of a reduction in the thickness of the metal oxide film 214, and the vertical axis represents the sheet resistance.

As shown in FIG. 30, it was found that the sheet resistance is as low as 1×10³ Ω/square or lower in a range from the surface to the depth approximately 80 nm of the metal oxide film 214. It was confirmed that the oxide film 214 functions as a conductive film even when the metal oxide film 214 has a large thickness as approximately 80 nm.

### Example 5

In this example, samples (sample E1 to sample E4) each corresponding to the transistor 100 illustrated in FIG. 1 were fabricated, and the cross-sectional shapes thereof were evaluated. Here, the film type and the deposition condition of an insulating layer corresponding to the insulating layer 118, which is a protective insulating layer, were varied.

For the evaluation, samples in each of which an insulating layer, a metal oxide layer, a conductive layer, and a protective insulating layer were formed over a glass substrate were used.

### <Sample Fabrication>

First, a 150-nm-thick insulating layer was formed over a glass substrate. As the insulating layer, a first silicon oxynitride film with a thickness approximately 5 nm, a second silicon oxynitride film with a thickness approximately 140 nm, and a third silicon oxynitride film with a thickness approximately 5 nm were deposited by a PECVD method.

The first silicon oxynitride film was deposited under the conditions where the flow rates of a silane gas and a dinitrogen monoxide gas were 24 sccm and 18000 sccm, respectively, the pressure was 200 Pa, the deposition power was 130 W, and the substrate temperature was 350° C.

The second silicon oxynitride film was deposited under the conditions where the flow rates of a silane gas and a dinitrogen monoxide gas were 200 sccm and 4000 sccm, respectively, the pressure was 300 Pa, the deposition power was 750 W, and the substrate temperature was 350° C.

The third silicon oxynitride film was deposited under the conditions where the flow rates of a silane gas and a dinitrogen monoxide gas were 20 sccm and 3000 sccm, respectively, the pressure was 40 Pa, the deposition power was 500 W, and the substrate temperature was 350° C.

Next, an approximately 20-nm-thick metal oxide film was formed over the insulating layer by a sputtering method. The metal oxide film was deposited by a sputtering method using an In—Ga—Zn oxide target (In:Ga:Zn=1:1:1 [atomic ratio]). The substrate temperature in the deposition was 100° C., and an oxygen gas (oxygen flow rate ratio: 100%) was used as a deposition gas. The power supply was set to 4.5 kW (AC), and the pressure was set to 0.3 Pa.

Subsequently, heat treatment was performed at 350° C. in an atmosphere containing nitrogen for one hour.

Next, a conductive film was formed over the metal oxide film. As the conductive film, an approximately 100-nm-thick molybdenum film was deposited by a sputtering method.

Next, a resist pattern was formed over the conductive film.

Then, the conductive film was etched using the resist pattern as a mask to obtain a conductive layer. A dry etching method was used for the etching, and a SF₆ gas was used as an etching gas.

Subsequently, the metal oxide film was etched to obtain a metal oxide layer. A wet etching method was used for the etching. For the etchant used here, the description in Example 1 can be referred to; thus, the detailed description is omitted. Note that the etching treatment time in each of the sample E1 to the sample E4 was 75 seconds.

Next, an approximately 300-nm-thick insulating film was formed as a protective insulating layer by a plasma CVD method. Here, four samples (sample E1 to sample E4) with different film types of a protective insulating layer and different deposition conditions thereof were fabricated.

In the sample E1, a silicon oxynitride film was formed as the protective insulating layer. The silicon oxynitride film was deposited under the conditions where the flow rates of a silane gas and a dinitrogen monoxide gas were 290 sccm and 4000 sccm, respectively, the pressure was 133 Pa, the deposition power was 1000 W, and the substrate temperature was 350° C.

In the sample E2, a silicon oxynitride film was formed as the protective insulating layer. The silicon oxynitride film was deposited under the conditions where the flow rates of a silane gas and a dinitrogen monoxide gas were 150 sccm and 1000 sccm, respectively, the pressure was 200 Pa, the deposition power was 2000 W, and the substrate temperature was 350° C.

In the sample E3, a silicon nitride oxide film was formed as the protective insulating layer. The silicon nitride oxide film was deposited under the conditions where the flow rates of a silane gas, a dinitrogen monoxide gas, a nitrogen gas, and an ammonia gas were 150 sccm, 1000 sccm, 5000 sccm, and 100 sccm, respectively, the pressure was 200 Pa, the deposition power was 2000 W, and the substrate temperature was 350° C.

In the sample E4, a silicon nitride film was formed as the protective insulating layer. The silicon nitride film was deposited under the conditions where the flow rates of a silane gas, a nitrogen gas, and an ammonia gas were 150 sccm, 5000 sccm, and 100 sccm, respectively, the pressure was 200 Pa, the deposition power was 2000 W, and the substrate temperature was 350° C.

Through the above process, the sample E1 to the sample E4 were obtained.

### <Cross-Sectional Observation of Sample>

Next, the sample E1 to the sample E4 were thinned by focused ion beam (FIB) and cross sections were observed with a scanning transmission electron microscope (by STEM: Scanning Transmission Electron Microscopy).

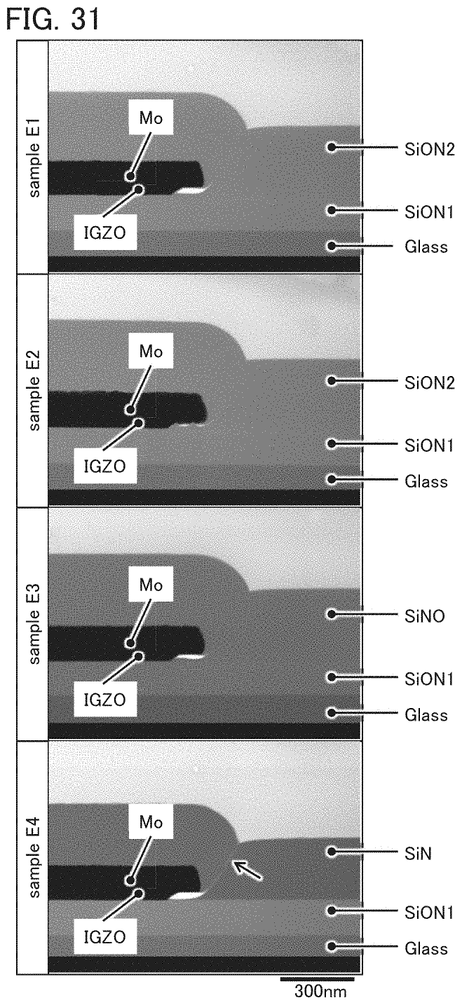

FIG. 31 shows cross-sectional STEM images of the sample E1 to the sample E4. FIG. 31 is transmission electron images (TE images) at a magnification of 100000 times. In FIG. 31, a glass substrate is denoted by Glass; an insulating layer, SiON1; a conductive layer, Mo; and a metal oxide layer, IGZO. In addition, as the protective insulating layer, a silicon oxynitride film is denoted by SiON2; a silicon nitride oxide film, SiNO; and a silicon nitride film, SiN.

In FIG. 31, a pale-color region observed between the conductive layer (Mo) and the metal oxide layer (IGZO) indicates a gap. From the sample E1 and the sample E2 each using silicon oxynitride as the protective insulating layer, it was found that the sample E2 has a smaller gap than the sample E1 and includes the protective insulating layer (SiON2) formed between the conductive layer (Mo) and the metal oxide layer (IGZO). It was found that the size of the gap between the conductive layer (Mo) and the metal oxide layer (IGZO) can be controlled by varying the deposition condition of the protective insulating layer.

The sample E3 using silicon nitride oxide as the protective insulating layer shows a tendency in which the gap was small as compared with the sample E1. It was found that the size of the gap between the conductive layer (Mo) and the metal oxide layer (IGZO) can be controlled by varying the film type of the protective insulating layer.

In the sample E4 using silicon nitride as the protective insulating layer, a void (an arrow in FIG. 31) was observed in the protective insulating layer.

### REFERENCE NUMERALS

C1: capacitor, C2: capacitor, DL_1: data line, G1: wiring, G2: wiring, GL_1: gate line, M1: transistor, M2: transistor, M3: transistor, N1: node, N2: node, P1: region, P2: region, S1: wiring, S2: wiring, T1: period, T2: period, 100: transistor, 100A: transistor, 100B: transistor, 100C: transistor, 102: substrate, 103: insulating layer, 103a: insulating layer, 103b: insulating layer, 103c: insulating layer, 103d: insulating layer, 103i: region, 106: conductive layer, 108: semiconductor layer, 108C: region, 108f: metal oxide film, 108L: region, 108N: region, 110: insulating layer, 110a: insulating layer, 110b: insulating layer, 110c: insulating layer, 110i: region, 112: conductive layer, 112f: conductive film, 114: metal oxide layer, 114f: metal oxide film, 115: resist mask, 116: insulating layer, 118: insulating layer, 120a: conductive layer, 120b: conductive layer, 130: gap, 140: impurity element, 141a: opening, 141b: opening, 142: opening, 150: insulating region, 200: glass substrate, 212: conductive film, 214: metal oxide film, 218: insulating film, 400: pixel circuit, 400EL: pixel circuit, 400LC: pixel circuit, 401: circuit, 401EL: circuit, 401LC: circuit, 501: pixel circuit, 502: pixel portion, 504: driver circuit portion, 504a: gate driver, 504b: source driver, 506: protective circuit, 507: terminal portion, 550: transistor, 552: transistor, 554: transistor, 560: capacitor, 562: capacitor, 570: liquid crystal element, 572: light-emitting element, 700: display device, 700A: display device, 700B: display device, 701: substrate, 702: pixel portion, 704: source driver circuit portion, 705: substrate, 706: gate driver circuit portion, 708: FPC terminal portion, 710: signal line, 711: wiring portion, 712: sealant, 716: FPC, 717: IC, 721: source driver IC, 722: gate driver circuit portion, 723: FPC, 724: printed circuit board, 730: insulating film, 732: sealing film, 734: insulating film 736: coloring film, 738: light-blocking film, 740: protective layer, 741: protective layer, 742: bonding layer, 743: resin layer, 744: insulating layer, 745: support substrate, 746: resin layer, 750: transistor, 752: transistor, 760: wiring, 770: planarization insulating film, 772: conductive layer, 773: insulating layer, 774: conductive layer, 775: liquid crystal element, 776: liquid crystal layer, 778: spacer, 780: anisotropic conductive film, 782: light-emitting element, 786: EL layer, 788: conductive film, 790: capacitor, 6000: display module, 6001: upper cover, 6002: lower cover, 6005: FPC, 6006: display device, 6009: frame, 6010: printed circuit board, 6011: battery, 6015: light-emitting portion, 6016: light-receiving portion, 6017a: light guide portion, 6017b: light guide portion, 6018: light, 6500: electronic device, 6501: housing, 6502: display portion, 6503: power button, 6504: button, 6505: speaker, 6506: microphone, 6507: camera, 6508: light source, 6510: protective member, 6511: display panel, 6512: optical member, 6513: touch sensor panel, 6515: FPC, 6516: IC, 6517: printed circuit board, 6518: battery, 7100: television device, 7101: housing, 7103: stand, 7111: remote controller, 7200: notebook personal computer, 7211: housing, 7212: keyboard, 7213: pointing device, 7214: external connection port, 7300: digital signage, 7301: housing, 7303: speaker, 7311: information terminal, 7400: digital signage, 7401: pillar, 7500: display portion, 8000: camera, 8001: housing, 8002: display portion, 8003: operation button, 8004: shutter button, 8006: lens, 8100: finder, 8101: housing, 8102: display portion, 8103: button, 8200: head-mounted display, 8201: mounting portion, 8202: lens, 8203: main body, 8204: display portion, 8205: cable, 8206: battery, 8300: head-mounted display, 8301: housing, 8302: display portion, 8304: fixing unit, 8305: lens, 9000: housing, 9001: display portion, 9003: speaker, 9005: operation key, 9006: connection terminal, 9007: sensor, 9008: microphone, 9050: icon, 9051: information, 9052: information, 9053: information, 9054: information, 9055: hinge, 9100: television device, 9101: portable information terminal, 9102: portable information terminal, 9200: portable information terminal, 9201: portable information terminal

1. A semiconductor device comprising:
a semiconductor layer;
a first insulating layer;
a metal oxide layer;
a conductive layer; and
an insulating region,
wherein the first insulating layer covers a top surface and a side surface of the semiconductor layer,
wherein the conductive layer is over the first insulating layer,
wherein the metal oxide layer is between the first insulating layer and the conductive layer,
wherein an end portion of the metal oxide layer is on an inner side than an end portion of the conductive layer,
wherein the insulating region is adjacent to the metal oxide layer and positioned between the first insulating layer and the conductive layer,
wherein the semiconductor layer comprises a first region, a pair of second regions, and a pair of third regions,
wherein the first region overlaps with the metal oxide layer and the conductive layer,
wherein the second regions are configured to put the first region therebetween and to overlap with the insulating region and the conductive layer,
wherein the third regions are configured to put the first region and the pair of second regions therebetween and not to overlap with the conductive layer,
wherein the third regions each comprise a portion having lower resistance than the first region, and
wherein the second regions each comprise a portion having higher resistance than the third regions.

2. The semiconductor device according to claim 1, wherein the insulating region has a relative dielectric constant different from a relative dielectric constant of the first insulating layer.

3. The semiconductor device according to claim 1, wherein the insulating region comprises a gap.

4. The semiconductor device according to claim 1, further comprising a second insulating layer,
wherein the second insulating layer is in contact with a top surface of the first insulating layer, and
wherein the insulating region comprises the second insulating layer.

5. The semiconductor device according to claim 4,
wherein the first insulating layer comprises an oxide or a nitride, and
wherein the second insulating layer comprises an oxide or a nitride.

6. The semiconductor device according to claim 4,
wherein the first insulating layer comprises silicon and oxygen, and
wherein the second insulating layer comprises silicon and oxygen.

7. The semiconductor device according to claim 4,
wherein the first insulating layer comprises silicon and oxygen, and
wherein the second insulating layer comprises silicon and nitrogen.

8. The semiconductor device according to claim 4, further comprising a third insulating layer,
wherein the third insulating layer is in contact with a top surface of the second insulating layer, and
wherein the third insulating layer comprises a nitride.

9. The semiconductor device according to claim 8, wherein the third insulating layer comprises silicon and nitrogen.

10. The semiconductor device according to claim 1,
wherein the third regions each comprise a first element, and
wherein the first element is one or more selected from boron, phosphorus, aluminum, and magnesium.

11. The semiconductor device according to claim 1,
wherein each of the semiconductor layer and the metal oxide layer comprises indium, and
wherein the semiconductor layer has an indium content percentage that is substantially equal to an indium content percentage of the metal oxide layer.

12. A method for manufacturing a semiconductor device comprising:
forming a semiconductor layer;
forming a first insulating layer over the semiconductor layer;
forming a first metal oxide layer over the first insulating layer;
forming a first conductive layer over the first metal oxide layer; and
etching the first metal oxide layer and the first conductive layer to form a second metal oxide layer, a second conductive layer, and an insulating region,
wherein an etching rate of the first metal oxide layer is higher than an etching rate of the first conductive layer, and
wherein an end portion of the second metal oxide layer is on an inner side than an end portion of the second conductive layer.

13. The method for manufacturing a semiconductor device according to claim 12, further comprising:
adding a first element to the semiconductor layer through the first insulating layer after etching the first metal oxide layer and the first conductive layer,
wherein the first element is one or more selected from boron, phosphorus, aluminum, and magnesium.

14. The method for manufacturing a semiconductor device according to claim 12, wherein the insulating region has a relative dielectric constant different from a relative dielectric constant of the first insulating layer.

15. The method for manufacturing a semiconductor device according to claim 12, wherein the insulating region comprises a gap.

16. The method for manufacturing a semiconductor device according to claim 12, further comprising:
forming a second insulating layer in contact with a top surface of the first insulating layer,
wherein the insulating region comprises the second insulating layer.

17. The method for manufacturing a semiconductor device according to claim 16, further comprising:
forming a third insulating layer in contact with a top surface of the second insulating layer,
wherein the third insulating layer comprises a nitride.
